(19) United States
(12) Patent Application Publication
(10) Pub. No.: US 2009/0021661 A1
(43) Pub. Date: Jan. 22, 2009

(54) THIN-FILM TRANSISTOR, THIN-FILM TRANSISTOR PRODUCING METHOD, AND DISPLAY APPARATUS

(76) Inventor: Shinzo Tsuboi, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/234,127

(22) Filed: Sep. 19, 2008

Related U.S. Application Data
(63) Continuation of application No. PCT/JP07/72771, filed on Nov. 26, 2007.

(30) Foreign Application Priority Data
Nov. 24, 2006 (JP) 2006-317284
Nov. 24, 2006 (JP) 2006-317285
Nov. 24, 2006 (JP) 2006-317286
Nov. 24, 2006 (JP) 2006-317287

(51) Int. Cl. G02F 1/136; H01L 21/336; H01L 29/04

(52) U.S. Cl. 349/43; 438/163; 257/66; 257/E21.411; 257/E29.004

(57) ABSTRACT

A thin-film transistor includes a semiconductor thin film provided on an insulating surface of a support substrate, a gate insulator provided on the semiconductor thin film, and a gate electrode layer formed on the semiconductor thin film with the gate insulator interposed therebetween. The semiconductor thin film includes a channel region disposed below the gate electrode layer, and source and drain regions disposed on both sides of the channel region. The source region has an impurity concentration profile in which an impurity concentration is lowered from an interface with the gate insulator toward an interface with the support substrate in a thickness direction of the semiconductor thin film. The impurity concentration near the support substrate is lower than the impurity concentration near the gate insulator by a factor of 100 or more in the impurity concentration profile of the source region.

### CROSS-REFERENCE TO RELATED APPLICATIONS

This is a Continuation Application of PCT Application No. PCT/JP2007/072771, filed Nov. 26, 2007, which was published under PCT Article 21(2) in Japanese.

This application is based upon and claims the benefit of priority from prior Japanese Patent Applications No. 2006-317284, filed Nov. 24, 2006; No. 2006-317285, filed Nov. 24, 2006; No. 2006-317286, filed Nov. 24, 2006; and No. 2006-317287, filed Nov. 24, 2006, the entire contents of all of which are incorporated herein by reference.

### BACKGROUND OF THE INVENTION

1. Field of the Invention

The present invention relates to a thin-film transistor incorporated in a liquid crystal display panel, a method of producing the thin-film transistor, and a display apparatus in which the thin-film transistor is used.

2. Description of the Related Art

A thin-film transistor (TFT) is a field effect transistor having a MOS (MIS) structure, which is formed on a semiconductor thin film deposited on an insulating substrate such as a glass substrate. A field effect transistor, formed in a semiconductor wafer bonded to the insulating substrate to constitute an SOI (Silicon On Insulator) structure substrate, is also dealt with as the thin-film transistor in this description.

In an active matrix type liquid crystal display panel, usually the thin-film transistor is used as a pixel switching element. Recently, an attempt has been made to integrate a drive circuit including the thin-film transistor into the liquid crystal display panel instead of a drive circuit including an IC chip. Therefore, researches for improving the current driving performance of the thin-film transistor have been actively made. For example, the current driving performance can significantly be improved when the thin-film transistor is formed in a single-crystal silicon grain film obtained by melt recrystallization of a polycrystalline silicon film. However, a source-drain breakdown voltage of the thin-film transistor formed in the single-crystal silicon grain film is remarkably degraded in comparison with the thin-film transistor formed in the polycrystalline silicon film, an off-current is increased, and a latch-up phenomenon is easily generated by a relatively small source-drain voltage.

In a channel region, the electric field intensity is usually increased near a drain end, a carrier generated in applying an electric field between both ends of the channel region is accelerated by the increased electric field intensity, and the semiconductor is ionized by an impact generated by collision of the carrier with the drain end. A small number of carriers generated by the impact ionization are accumulated in a silicon body constituting the channel region, which changes a threshold voltage to increase an off-current. The carrier accumulation facilitates generation of a single latch-up in which a current passed through the channel region as a parasitic bipolar phenomenon is self-continued while being uncontrollable by a gate, which results in a malfunction of the transistor.

In the field effect transistor, a Lightly-doped drain (LDD) structure is well known as a technique for improving the source-drain breakdown voltage. There is also known a retrograde well technique of controlling the threshold. In the retrograde well technique, an impurity concentration is set to a value near a surface on a gate insulator side, and a well in which an impurity concentration at a deep position far away from the neighborhood of the surface on the gate insulator side is set higher than that of the neighborhood of the surface is provided in the channel region in order to avoid the latch-up (for example, see Jpn. Pat. Appln. KOKAI Publication No. 6-163844).

However, in the thin-film transistor, in order to decrease a resistance, usually the source region and drain region have the high impurity concentrations on the gate insulator side while having the low impurity concentrations on the side of an underlying oxide film provided in the insulating substrate. Similarly, the channel region having an opposite conductive property to those of the source region and drain region has the high impurity concentration on the gate insulator side while having the low impurity concentration on the underlying oxide film side. When the above-described impurity concentration profile exists in a film thickness direction, that is, a depth direction of the silicon body used as the semiconductor thin film, the channel region and the drain region are adjacent to each other near the gate insulator while having the high impurity concentrations, which makes it difficult to obtain a sufficient source-drain breakdown voltage.

In the LDD structure, when a gate length is formed in the order of sub-micrometers, the source-drain breakdown voltage cannot sufficiently be increased. The retrograde well technique is insufficiently effective for the source-drain breakdown voltage when a thickness of the silicon body is restricted in the range of about 20 to 200 nm.

### BRIEF SUMMARY OF THE INVENTION

An object of the invention is to provide a thin-film transistor, a method of producing the thin-film transistor, and a display apparatus, in which a good source-drain breakdown voltage can be ensured on the semiconductor thin film.

According to one aspect of the invention, there is provided a thin-film transistor comprising: a semiconductor thin film which is provided on an insulating surface of a support substrate; a gate insulator which is provided on the semiconductor thin film; and a gate electrode layer which is formed on the semiconductor thin film with the gate insulator interposed therebetween, wherein the semiconductor thin film includes: a channel region which is disposed below the gate electrode layer and contains an impurity of a first conductivity type; and source and drain regions which are disposed on both sides of the channel region and contain an impurity of a second conductivity type opposite to the first conductivity type, the source region has an impurity concentration profile in which an impurity concentration is lowered from an interface with the gate insulator toward an interface with the support substrate in a thickness direction of the semiconductor thin film, and the impurity concentration near the support substrate is lower than the impurity concentration near the gate insulator by a factor of 100 or more in the impurity concentration profile of the source region.

According to one aspect of the invention, there is provided a method of producing a thin-film transistor comprising: providing a semiconductor thin film on an insulating surface of a support substrate; providing a gate insulator on the semiconductor thin film; forming a gate electrode layer on the semiconductor thin film with the gate insulator interposed therebetween; and providing, in the semiconductor thin film, a channel region which is disposed below the gate electrode layer and contains an impurity of a first conductivity type; and source and drain regions which are disposed on both sides of the channel region and contain an impurity of a second conductivity type opposite to the first conductivity type, wherein the source region has an impurity concentration profile in which an impurity concentration is lowered from an interface with the gate insulator toward an interface with the support substrate in a thickness direction of the semiconductor thin film.

According to one aspect of the invention, there is provided a display apparatus comprising: a liquid crystal display panel; and a drive circuit including a thin-film transistor disposed on the liquid crystal display panel, wherein the thin-film transistor includes: a semiconductor thin film which is provided on an insulating surface of a support substrate; a gate insulator which is provided on the semiconductor thin film; and a gate electrode layer which is formed on the semiconductor thin film with the gate insulator interposed therebetween, the semiconductor thin film includes: a channel region which is disposed below the gate electrode layer and contains an impurity of a first conductivity type; and source and drain regions which are disposed on both sides of the channel region and contain an impurity of a second conductivity type opposite to the first conductivity type, and the source region has an impurity concentration profile in which an impurity concentration is lowered from an interface with the gate insulator toward an interface with the support substrate in a thickness direction of the semiconductor thin film.

According to one aspect of the invention, there is provided a thin-film transistor comprising: a semiconductor thin film which is provided on an insulating surface of a support substrate; a gate insulator which is provided on the semiconductor thin film; and a gate electrode layer which is formed on the semiconductor thin film with the gate insulator interposed therebetween, wherein the semiconductor thin film includes: a channel region which is disposed below the gate electrode layer and contains an impurity of a first conductivity type; source and drain regions which are disposed on both sides of the channel region and contain an impurity of a second conductivity type opposite to the first conductivity type; and an LDD region which is disposed at least between the drain region and the channel region and contains an impurity of the second conductivity type, the source region has an impurity concentration profile in which an impurity concentration is lowered from an interface with the gate insulator toward an interface with the support substrate in a thickness direction of the semiconductor thin film, and the impurity concentration near the support substrate is lower than the impurity concentration near the gate insulator by a factor of 100 or more in the impurity concentration profile of the source region.

According to one aspect of the invention, there is provided a method of producing a thin-film transistor comprising: providing a semiconductor thin film on an insulating surface of a support substrate; providing a gate insulator on the semiconductor thin film; forming a gate electrode layer on the semiconductor thin film with the gate insulator interposed therebetween; and providing, in the semiconductor thin film, a channel region which is disposed below the gate electrode layer and contains an impurity of a first conductivity type, source and drain regions which are disposed on both sides of the channel region and contain an impurity of a second conductivity type opposite to the first conductivity type, and an LDD region which is disposed at least between the drain region and the channel region and contains an impurity of the second conductivity type, wherein the source region has an impurity concentration profile in which an impurity concentration is lowered from an interface with the gate insulator toward an interface with the support substrate in a thickness direction of the semiconductor thin film.

According to one aspect of the invention, there is provided a display apparatus comprising: a liquid crystal display panel; and a drive circuit including a thin-film transistor disposed on the liquid crystal display panel, wherein the thin-film transistor includes: a semiconductor thin film which is provided on an insulating surface of a support substrate; a gate insulator which is provided on the semiconductor thin film; and a gate electrode layer which is formed on the semiconductor thin film with the gate insulator interposed therebetween, the semiconductor thin film includes: a channel region which is disposed below the gate electrode layer and contains an impurity of a first conductivity type; source and drain regions which are disposed on both sides of the channel region and contain an impurity of a second conductivity type opposite to the first conductivity type; and an LDD region which is disposed at least between the drain region and the channel region and contains an impurity of the second conductivity type, the source region has an impurity concentration profile in which an impurity concentration is lowered from an interface with the gate insulator toward an interface with the support substrate in a thickness direction of the semiconductor thin film.

According to one aspect of the invention, there is provided a thin-film transistor comprising: a semiconductor thin film which is provided on an insulating surface of a support substrate; a gate insulator which is provided on the semiconductor thin film; and a gate electrode layer which is formed on the semiconductor thin film with the gate insulator interposed therebetween, wherein the semiconductor thin film includes: a channel region which is disposed below the gate electrode layer and contains an impurity of a first conductivity type; source and drain regions which are disposed on both sides of the channel region and contain an impurity of a second conductivity type opposite to the first conductivity type; and an LDD region which is disposed at least between the drain region and the channel region and contains an impurity of the second conductivity type, and the LDD region has an impurity concentration profile in which an impurity concentration is lowered from an interface with the gate insulator toward an interface with the support substrate in a thickness direction of the semiconductor thin film.

According to one aspect of the invention, there is provided a method of producing a thin-film transistor comprising: providing a semiconductor thin film on an insulating surface of a support substrate; providing a gate insulator on the semiconductor thin film; forming a gate electrode layer on the semiconductor thin film with the gate insulator interposed therebetween; and providing, in the semiconductor thin film, a channel region which is disposed below the gate electrode layer and contains an impurity of a first conductivity type, source and drain regions which are disposed on both sides of the channel region and contain an impurity of a second conductivity type opposite to the first conductivity type, and an LDD region which is disposed at least between the drain region and the channel region and contains an impurity of the second conductivity type, wherein the LDD region has an impurity concentration profile in which an impurity concentration is lowered from an interface with the gate insulator toward an interface with the support substrate in a thickness direction of the semiconductor thin film.

According to one aspect of the invention, there is provided a display apparatus comprising: a liquid crystal display panel; and a drive circuit including a thin-film transistor disposed on the liquid crystal display panel, wherein the thin-film transistor includes: a semiconductor thin film which is provided on an insulating surface of a support substrate; a gate insulator which is provided on the semiconductor thin film; and a gate electrode layer which is formed on the semiconductor thin film with the gate insulator interposed therebetween, the semiconductor thin film includes: a channel region which is disposed below the gate electrode layer and contains an impurity of a first conductivity type; source and drain regions which are disposed on both sides of the channel region and contain an impurity of a second conductivity type opposite to the first conductivity type; and an LDD region which is disposed at least between the drain region and the channel region and contains an impurity of the second conductivity type, and the LDD region has an impurity concentration profile in which an impurity concentration is lowered from an interface with the gate insulator toward an interface with the support substrate in a thickness direction of the semiconductor thin film.

According to one aspect of the invention, there is provided a thin-film transistor comprising: a semiconductor thin film which is provided on an insulating surface of a support substrate; a gate insulator which is provided on the semiconductor thin film; and a gate electrode layer which is formed on the semiconductor thin film with the gate insulator interposed therebetween, wherein the semiconductor thin film includes: a channel region which is disposed below the gate electrode layer and contains an impurity of a first conductivity type; source and drain regions which are disposed on both sides of the channel region and contain an impurity of a second conductivity type opposite to the first conductivity type; and an LDD region which is disposed at least between the drain region and the channel region and contains an impurity of the second conductivity type, the channel region has an impurity concentration profile in which an impurity concentration is increased from an interface with the gate insulator toward an interface with the support substrate in a thickness direction of the semiconductor thin film, and the source region and the LDD region have impurity concentration profiles in which impurity concentrations are lowered from the interface with the gate insulator toward the interface with the support substrate in the thickness direction of the semiconductor thin film.

According to one aspect of the invention, there is provided a method of producing a thin-film transistor comprising: providing a semiconductor thin film on an insulating surface of a support substrate; providing a gate insulator on the semiconductor thin film; forming a gate electrode layer on the semiconductor thin film with the gate insulator interposed therebetween; and providing, in the semiconductor thin film, a channel region which is disposed below the gate electrode layer and contains an impurity of a first conductivity type, source and drain regions which are disposed on both sides of the channel region and contain an impurity of a second conductivity type opposite to the first conductivity type, and an LDD region which is disposed at least between the drain region and the channel region and contains an impurity of the second conductivity type, wherein the channel region has an impurity concentration profile in which an impurity concentration is increased from an interface with the gate insulator toward an interface with the support substrate in a thickness direction of the semiconductor thin film, and the source region and the LDD region have impurity concentration profiles in which impurity concentrations are lowered from the interface with the gate insulator toward the interface with the support substrate in the thickness direction of the semiconductor thin film.

According to one aspect of the invention, there is provided a display apparatus comprising: a liquid crystal display panel; and a drive circuit including a thin-film transistor disposed on the liquid crystal display panel, wherein the thin-film transistor includes: a semiconductor thin film which is provided on an insulating surface of a support substrate; a gate insulator which is provided on the semiconductor thin film; and a gate electrode layer which is formed on the semiconductor thin film with the gate insulator interposed therebetween, the semiconductor thin film includes: a channel region which is disposed below the gate electrode layer and contains an impurity of a first conductivity type; source and drain regions which are disposed on both sides of the channel region and contain an impurity of a second conductivity type opposite to the first conductivity type; and an LDD region which is disposed at least between the drain region and the channel region and contains an impurity of the second conductivity type, the channel region has an impurity concentration profile in which an impurity concentration is increased from an interface with the gate insulator toward an interface with the support substrate in a thickness direction of the semiconductor thin film, and the source region and the LDD region have impurity concentration profiles in which impurity concentrations are lowered from the interface with the gate insulator toward the interface with the support substrate in the thickness direction of the semiconductor thin film.

In the thin-film transistor, the thin-film transistor producing method, and the display apparatus, a good source-drain breakdown voltage can be ensured on the semiconductor thin film.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a view for schematically explaining the invention, and shows impurity profiles of n⁺ source regions obtained in thin-film transistor samples A, B, and C whose phosphorous ion implantation acceleration voltages differ from one another.

FIG. 2 is a view showing source-drain breakdown voltages for the impurity profiles of the samples A, B, and C of FIG. 1.

FIG. 3 is a view showing the lateral electric field intensity along each channel of the samples A, B, and C of FIG. 1.

FIG. 4 is a view showing the lateral impact ionization intensity along each channel of the samples A, B, and C of FIG. 1.

FIG. 5 is a view showing results in which a minimum potential value is obtained as a function of drain voltage in each silicon body of the samples A, B, and C of FIG. 1.

FIG. 6 is a view showing hole density distributions obtained in the case where a drain voltage and a gate voltage are biased by 3.5 V and 0.5 V respectively in the samples A, B, and C of FIG. 1.

FIG. 7 is a view showing a sectional structure of a thin-film transistor having a single drain structure according to a first embodiment of the invention.

FIG. 8 is a view showing a state in which the thin-film transistor of FIG. 7 is disposed in a single-crystalline silicon grain.

FIG. 9 is a view showing a schematic circuit configuration of a liquid crystal display apparatus in which the thin-film transistor of FIG. 7 is used.

FIG. 10 is a view showing a schematic sectional structure of the liquid crystal display apparatus of FIG. 9.

FIG. 11 is a view showing an influence of boron ion implantation conditions on a channel region impurity profile of the thin-film transistor of FIG. 7.

FIG. 12 is a view showing gate voltage-drain current characteristics in the case where only Vth implantation is performed on a channel region of the thin-film transistor of FIG. 7.

FIG. 13 is a view showing gate voltage-drain current characteristics in the case where a combination of the Vth implantation and punch through stop (PTS) implantation is performed on the channel region of the thin-film transistor of FIG. 7.

FIG. 14 is a view showing gate voltage-drain current characteristics in the case where only the PTS implantation is performed on the channel region of the thin-film transistor of FIG. 7.

FIG. 15 is a view showing an influence of boron ion implantation conditions on dependence of a threshold voltage on the drain voltage of the thin-film transistor of FIG. 7.

FIG. 16 is a view showing a list of an influence of implantation conditions on maximum mobility, a swing value, a source-drain breakdown voltage, an on-current, and an off-current of the thin-film transistor of FIG. 7.

FIG. 17 is a view showing an influence of an acceleration voltage of phosphorus ion implantation on an impurity profile of an n⁺ region such as a source region and a drain region of the thin-film transistor of FIG. 7.

FIG. 18 is a view showing gate voltage-drain current characteristics in the case where n⁺ implantation is performed with the acceleration voltage of 35 KeV on the thin-film transistor of FIG. 7.

FIG. 19 is a view showing gate voltage-drain current characteristics in the case where the n⁺ implantation is performed with the acceleration voltage of 25 KeV on the thin-film transistor of FIG. 7.

FIG. 20 is a view showing gate voltage-drain current characteristics in the case where the n⁺ implantation is performed with the acceleration voltage of 15 KeV on the thin-film transistor of FIG. 7.

FIG. 21 is a view showing an influence of an acceleration voltage of phosphorus ion implantation on dependence of a threshold voltage of the thin-film transistor of FIG. 7 on the drain voltage.

FIG. 22 is a view showing a list of an influence of the acceleration voltage on the maximum mobility, swing value, source-drain breakdown voltage, on-current, and off-current of the thin-film transistor of FIG. 7.

FIG. 23 is a view showing an influence of an n⁺ implanting phosphorus dosage on the on-current of the thin-film transistor of FIG. 7.

FIG. 24 is a view showing an influence of the n⁺ implanting phosphorus dosage on the source-drain breakdown voltage of the thin-film transistor of FIG. 7.

FIG. 25 is a view showing a list of an influence of the n⁺ implanting phosphorus dosage and acceleration voltage on the maximum mobility, swing value, source-drain breakdown voltage, on-current, and off-current of the thin-film transistor of FIG. 7.

FIG. 26 is a view showing drain current-drain voltage characteristics obtained in the case where a distance D of 0.6 μm is applied to a shallow junction obtained at the n⁺ implanting acceleration voltage of 15 KeV in the thin-film transistor of FIG. 7.

FIG. 27 is a view showing drain current-drain voltage characteristics obtained in the case where the distance D of 2.0 μm is applied to the shallow junction obtained at the n⁺ implanting acceleration voltage of 15 KeV in the thin-film transistor of FIG. 7.

FIG. 28 is a view showing drain current-drain voltage characteristics obtained in the case where the distance D of 4.0 μm is applied to the shallow junction obtained at the n⁺ implanting acceleration voltage of 15 KeV in the thin-film transistor of FIG. 7.

FIG. 29 is a view showing drain current-drain voltage characteristics obtained in the case where the distance D of 7.0 μm is applied to the shallow junction obtained at the n⁺ implanting acceleration voltage of 15 KeV in the thin-film transistor of FIG. 7.

FIG. 30 is a view showing drain current-drain voltage characteristics obtained in the case where the distance D of 0.6 μm is applied to a moderate junction obtained at the n⁺ implanting acceleration voltage of 25 KeV in the thin-film transistor of FIG. 7.

FIG. 31 is a view showing drain current-drain voltage characteristics obtained in the case where the distance D of 2.0 μm is applied to the moderate junction obtained at the n⁺ implanting acceleration voltage of 25 KeV in the thin-film transistor of FIG. 7.

FIG. 32 is a view showing drain current-drain voltage characteristics obtained in the case where the distance D of 4.0 μm is applied to the moderate junction obtained at the n⁺ implanting acceleration voltage of 25 KeV in the thin-film transistor of FIG. 7.

FIG. 33 is a view showing drain current-drain voltage characteristics obtained in the case where the distance D of 7.0 μm is applied to the moderate junction obtained at the n⁺ implanting acceleration voltage of 25 KeV in the thin-film transistor of FIG. 7.

FIG. 34 is a view showing drain current-drain voltage characteristics obtained in the case where the distance D of 0.6 μm is applied to a deep junction obtained at the n⁺ implanting acceleration voltage of 35 KeV in the thin-film transistor of FIG. 7.

FIG. 35 is a view showing drain current-drain voltage characteristics obtained in the case where the distance D of 2.0 μm is applied to the deep junction obtained at the n⁺ implanting acceleration voltage of 35 KeV in the thin-film transistor of FIG. 7.

FIG. 36 is a view showing drain current-drain voltage characteristics obtained in the case where the distance D of 4.0 μm is applied to the deep junction obtained at the n⁺ implanting acceleration voltage of 35 KeV in the thin-film transistor of FIG. 7.

FIG. 37 is a view showing drain current-drain voltage characteristics obtained in the case where the distance D of 7.0 μm is applied to the deep junction obtained at the n⁺ implanting acceleration voltage of 35 KeV in the thin-film transistor of FIG. 7.

FIG. 38 is a view showing an influence of n⁺ implanting acceleration voltage and a gate length on the source-drain breakdown voltage in the thin-film transistor having the single drain structure of FIG. 7.

FIG. 39 is a view showing an influence of channel implantation conditions and the gate length on the source-drain breakdown voltage in the thin-film transistor having the single drain structure of FIG. 7.

FIG. 40 is a view showing an influence of the acceleration voltage of the phosphorus ion implantation on the impurity profile of the n⁺ region obtained in the case where a silicon body thickness Tsi of 50 nm is applied to the thin-film transistor of FIG. 7.

FIG. 41 is a view showing a sectional structure of a thin-film transistor having an LDD structure according to a second embodiment of the invention.

FIG. 42 is a view showing a state in which the thin-film transistor of FIG. 41 is disposed in a single-crystalline silicon grain.

FIG. 43 is a view showing a schematic circuit configuration of a liquid crystal display apparatus in which the thin-film transistor of FIG. 41 is used.

FIG. 44 is a view showing a schematic sectional structure of the liquid crystal display apparatus of FIG. 43.

FIG. 45 is a view showing an influence of boron ion implantation conditions on a channel region impurity profile of the thin-film transistor of FIG. 41.

FIG. 46 is a view showing gate voltage-drain current characteristics in the case where only Vth implantation is performed on a channel region of the thin-film transistor of FIG. 41.

FIG. 47 is a view showing gate voltage-drain current characteristics in the case where a combination of the Vth implantation and PTS implantation is performed on the channel region of the thin-film transistor of FIG. 41.

FIG. 48 is a view showing gate voltage-drain current characteristics in the case where only the PTS implantation is performed to the channel region of the thin-film transistor of FIG. 41.

FIG. 49 is a view showing an influence of boron ion implantation conditions on dependence of a threshold voltage on the drain voltage of the thin-film transistor of FIG. 41.

FIG. 50 is a view showing a list of an influence of ion implantation conditions on maximum mobility, a swing value, a source-drain breakdown voltage, an on-current, and an off-current of the thin-film transistor of FIG. 41.

FIG. 51 is a view showing an influence of ion implantation conditions of the channel region on a relationship between the source-drain breakdown voltage of the thin-film transistor of FIG. 41 and an LDD implanting phosphorus dosage.

FIG. 52 is a view showing an influence of ion implantation conditions of the channel region on a relationship between the on-current of the thin-film transistor of FIG. 41 and the LDD implanting phosphorus dosage.

FIG. 53 is a view showing an influence of ion implantation conditions of the channel region on a relationship between the on-current and the source-drain breakdown voltage of the thin-film transistor of FIG. 41.

FIG. 54 is a view showing an influence of an n⁺ implanting acceleration voltage on the relationship between the source-drain breakdown voltage of the thin-film transistor of FIG. 41 and the LDD implanting phosphorus dosage.

FIG. 55 is a view showing an influence of the n⁺ implanting acceleration voltage on the relationship between the on-current of the thin-film transistor of FIG. 41 and the LDD implanting phosphorus dosage.

FIG. 56 is a view showing an influence of the n⁺ implanting acceleration voltage on the relationship between the on-current of the thin-film transistor of FIG. 41 and the source-drain breakdown voltage.

FIG. 57 is a view showing an influence of the n⁺ implanting acceleration voltage on a relationship between the off-current of the thin-film transistor of FIG. 41 and the LDD implanting phosphorus dosage.

FIG. 58 is a view showing an influence of an n⁺ implanting phosphorus dosage on the relationship between the source-drain breakdown voltage of the thin-film transistor of FIG. 41 and the LDD implanting phosphorus dosage.

FIG. 59 is a view showing an influence of the n⁺ implanting phosphorus dosage on the relationship between the on-current of the thin-film transistor of FIG. 41 and the LDD implanting phosphorus dosage.

FIG. 60 is a view showing an influence of the n⁺ implanting phosphorus dosage on the relationship between the on-current of the thin-film transistor of FIG. 41 and the source-drain breakdown voltage.

FIG. 61 is a view showing an influence of the n⁺ implanting phosphorus dosage on the relationship between the off-current of the thin-film transistor of FIG. 41 and the LDD implanting phosphorus dosage.

FIG. 62 is a view showing an influence of the n⁺ implanting phosphorus dosage on the relationship between the threshold voltage and drain voltage of the thin-film transistor of FIG. 41.

FIG. 63 is a view showing an influence of an LDD implanting acceleration voltage on the relationship between the source-drain breakdown voltage of the thin-film transistor of FIG. 41 and the LDD implanting phosphorus dosage.

FIG. 64 is a view showing an influence of the LDD implanting acceleration voltage on the relationship between the on-current of the thin-film transistor of FIG. 41 and the LDD implanting phosphorus dosage.

FIG. 65 is a view showing an influence of the LDD implanting acceleration voltage on the relationship between the off-current of the thin-film transistor of FIG. 41 and the LDD implanting phosphorus dosage.

FIG. 66 is a view showing an influence of the LDD implanting acceleration voltage on the relationship between the on-current and source-drain breakdown voltage of the thin-film transistor of FIG. 41.

FIG. 67 is a view showing simulation results of dependence of the on-current on a distance from a contact portion of a drain electrode to an end of a drain region adjacent to an LDD region in the thin-film transistor of FIG. 41.

FIG. 68 is a view showing simulation results and experimental results of the dependence of the on-current on the distance from the contact portion of the drain electrode to the end of the drain region adjacent to the LDD region in the thin-film transistor of FIG. 41.

FIG. 69 is a view showing an influence of the n⁺ implanting acceleration voltage and the gate length on the source-drain breakdown voltage in the thin-film transistor having the LDD structure of FIG. 41.

FIG. 70 is a view showing an influence of the channel implantation conditions and the gate length on the source-drain breakdown voltage in the thin-film transistor having the LDD structure of FIG. 41.

FIG. 71 is a view showing an influence of the acceleration voltage of the phosphorus ion implantation on the impurity profile of the n⁺ region obtained in the case where the silicon body thickness Tsi of 50 nm is applied to the thin-film transistor of FIG. 41.

FIG. 72 is a view showing an influence of the n⁺ implanting acceleration voltage on the relationship between the source-drain breakdown voltage and the LDD implanting phosphorus dosage obtained in the case where the silicon body thickness Tsi of 50 nm is applied to the thin-film transistor of FIG. 41.

FIG. 73 is a view showing an influence of the n⁺ implanting acceleration voltage on the relationship between the on-current and the LDD implanting phosphorus dosage obtained in the case where the silicon body thickness Tsi of 50 nm is applied to the thin-film transistor of FIG. 41.

FIG. 74 is a view showing an influence of the n⁺ implanting acceleration voltage on the relationship between the on-current and the source-drain breakdown voltage obtained in the case where the silicon body thickness Tsi of 50 nm is applied to the thin-film transistor of FIG. 41.

FIG. 75 is a view showing an influence of the ion implantation conditions of the channel region on the relationship between the source-drain breakdown voltage and the LDD implanting phosphorus dosage obtained in the case where the silicon body thickness Tsi of 50 nm is applied to the thin-film transistor of FIG. 41.

FIG. 76 is a view showing an influence of the ion implantation conditions of the channel region on the relationship between the on-current and the LDD implanting phosphorus dosage obtained in the case where the silicon body thickness Tsi of 50 nm is applied to the thin-film transistor of FIG. 41.

FIG. 77 is a view showing an influence of the ion implantation conditions of the channel region on the relationship between the on-current and the source-drain breakdown voltage obtained in the case where the silicon body thickness Tsi of 50 nm is applied to the thin-film transistor of FIG. 41.

FIG. 78 is a view showing an influence of the LDD implanting acceleration voltage on the relationship between the source-drain breakdown voltage and the LDD implanting phosphorus dosage obtained in the case where the silicon body thickness Tsi of 50 nm is applied to the thin-film transistor of FIG. 41.

FIG. 79 is a view showing an influence of the LDD implanting acceleration voltage on the relationship between the on-current and the LDD implanting phosphorus dosage obtained in the case where the silicon body thickness Tsi of 50 nm is applied to the thin-film transistor of FIG. 41.

FIG. 80 is a view showing an influence of the LDD implanting acceleration voltage on the relationship between the off-current and the LDD implanting phosphorus dosage obtained in the case where the silicon body thickness Tsi of 50 nm is applied to the thin-film transistor of FIG. 41.

FIG. 81 is a view showing an influence of the LDD implanting acceleration voltage on the relationship between the on-current and the source-drain breakdown voltage obtained in the case where the silicon body thickness Tsi of 50 nm is applied to the thin-film transistor of FIG. 41.

FIG. 82 is a view showing a sectional structure of a first modification of the thin-film transistor of FIG. 41.

FIG. 83 is a view showing a sectional structure of a second modification of the thin-film transistor of FIG. 41.

FIG. 84 is a view showing a characteristic of a degradation mode of hot carrier stress degradation.

FIG. 85 is a view showing an influence of a body film thickness on a hot carrier reliability lifetime.

FIG. 86 is a view showing an influence of the body film thickness on a drain current degradation ratio caused by the hot carrier stress degradation in the case of a drain voltage Vd of 4.5 V.

FIG. 87 is a view showing an influence of the body film thickness on the drain current degradation ratio caused by the hot carrier stress degradation in the case of the drain voltage Vd of 4.0 V.

FIG. 88 is a view showing an influence of the body film thickness on a threshold shift caused by the hot carrier stress degradation in the case of the drain voltage Vd of 4.5 V.

FIG. 89 is a view showing an influence of the body film thickness on the threshold shift caused by the hot carrier stress degradation in the case of the drain voltage Vd of 4.0 V.

FIG. 90 is a view showing an influence of the body film thickness on the drain current degradation ratio caused by the hot carrier stress degradation in the case of the gate length L of 1.0 μm.

FIG. 91 is a view showing an influence of the body film thickness on the threshold shift caused by the hot carrier stress degradation in the case of the gate length L of 1.0 μm.

FIG. 92 is a view showing a body current example measured by a four-terminal method in the case of the body film thickness Tsi of 100 nm.

FIG. 93 is a view showing a body current example measured by the four-terminal method in the case of the body film thickness Tsi of 50 nm.

FIG. 94 is a view showing a relationship between the body film thickness and the body current in the case of the gate length L of 0.5 μm and the drain voltage Vd of 4.5 V.

FIG. 95 is a view showing a relationship between the body film thickness and the body current in the case of the gate length L of 0.5 μm and the drain voltage Vd of 4.0 V.

FIG. 96 is a view showing a relationship between the body film thickness and the body current in the case of the gate length L of 1.0 μm and the drain voltage Vd of 5.0 V.

FIG. 97 is a view showing a relationship between the body film thickness and the body current in the case of the gate length L of 1.0 μm and the drain voltage Vd of 4.0 V.

FIG. 98 is a view showing an influence of the body film thickness Tsi on electric field intensity at a drain end obtained in simulation.

FIG. 99 is a view showing an influence of the body film thickness on the drain current degradation ratio caused by the hot carrier stress degradation in the case where the body film thickness Tsi of 100 nm is obtained by PMELA.

FIG. 100 is a view showing an influence of the body film thickness on the drain current degradation ratio caused by the hot carrier stress degradation in the case where the body film thickness Tsi of 50 nm is obtained by PMELA.

FIG. 101 is a view showing results in which an influence of the body film thickness on the drain current degradation ratio caused by the hot carrier stress degradation is compared under the same stress conditions of the drain voltage Vd of 5.0 V and the gate voltage Vg of 2.1 V.

FIG. 102 is a view showing an influence of an n⁺ junction depth on the drain current degradation ratio caused by the hot carrier stress degradation.

FIG. 103 is a view showing an influence of the n⁺ junction depth on the maximum mutual conductance degradation ratio caused by the hot carrier stress degradation.

FIG. 104 is a view showing an influence of the n⁺ junction depth on the threshold shift caused by the hot carrier stress degradation.

### DETAILED DESCRIPTION OF THE INVENTION

The inventor has confirmed that, firstly, an impurity profile of a source region has an influence on a high-quality source-drain breakdown voltage BV in a short-channel thin-film transistor formed in a crystallization region where a polycrystalline silicon film is particularly melt-recrystallized as a high-quality semiconductor thin film. This is the result of detailed investigations obtained from simulations and experiments of dependence of the source-drain breakdown voltage BV on a junction depth of the source region and a physical mechanism of the thin-film transistor.

While the thicknesses of a silicon body and a gate insulator were set at 100 nm and 30 nm, respectively, the simulations were performed for the source-drain breakdown voltages of the coplanar-type n-channel thin-film transistors having a single drain structure and an LDD structure with gate lengths of 0.5 μm (a length of a gate electrode along a channel between the source region and the drain region). A length and a dosage of an n⁻ LDD region were fixed at 0.2 μm and 1×10¹³ (cm⁻²) as a compromise between the source-drain breakdown voltage BV and a driving current. All the computations were performed with SENTAURUS PROCESS and DESSES (manufactured by Synopsys, Inc.).

The plural thin-film transistors having the same dimensions as the simulated device were produced on an SOI (Semiconductor On Insulator) substrate (manufactured by Unibond). The gate insulator was deposited at 300° C. by plasma enhanced CVD using a source gas of TEOS and O₂. The impurity profile of an n⁺ source region was changed by changing an impurity ion implanting acceleration voltage. Activation of the implanted impurity was performed at 600° C. by furnace annealing. The source-drain breakdown voltage BV is defined as a drain voltage at a time the single transistor latch is started.

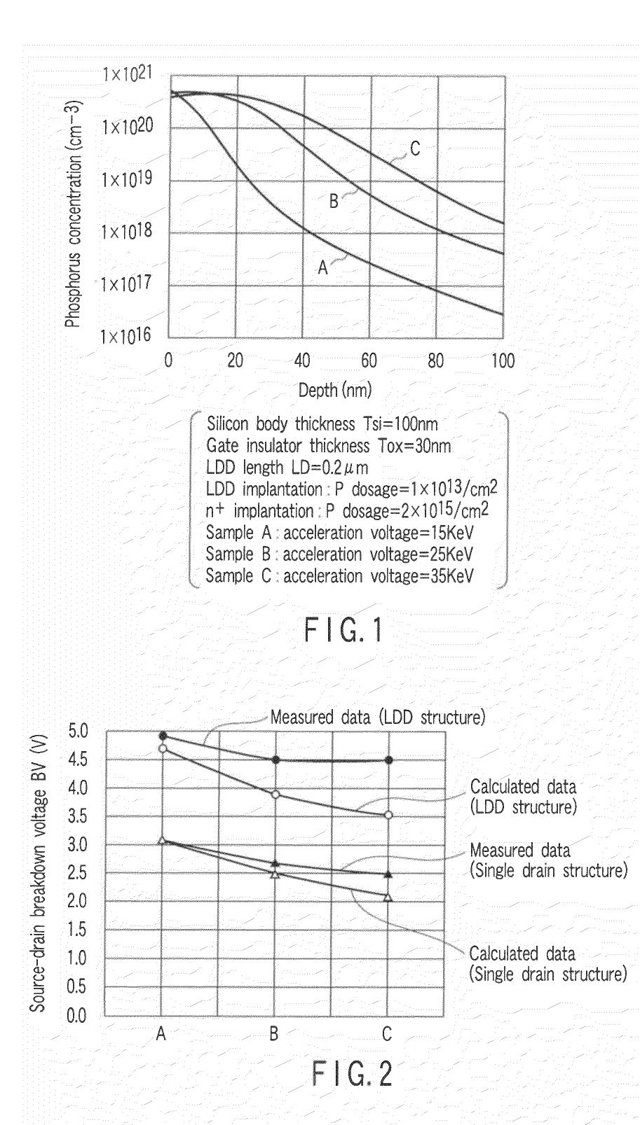

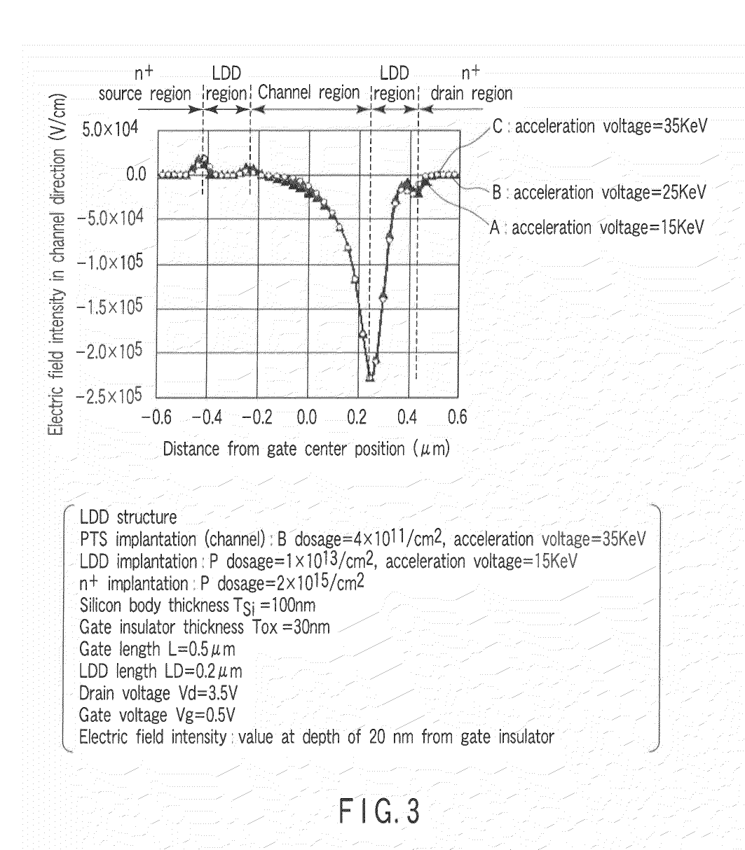

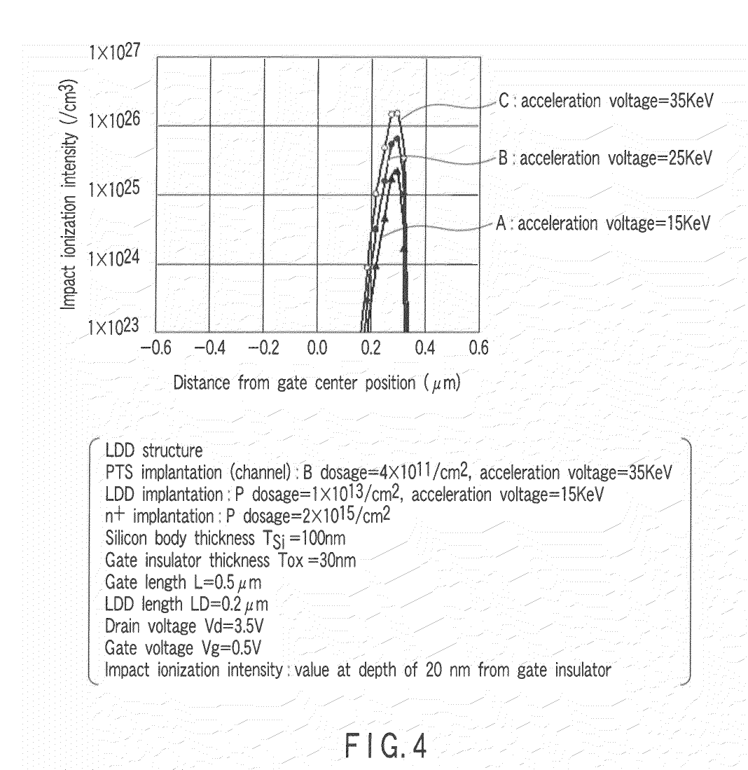

In a simulation stage, samples A, B, and C of the thin-film transistor having the gate length of L=0.5 μm were prepared while P (phosphorus) ions were ion-implanted as an n-type impurity in the n⁺ source region with an acceleration energy, that is, acceleration voltage of 15 KeV, 25 KeV, and 35 KeV, respectively. FIG. 1 shows impurity profiles of the n⁺ source regions obtained in the samples A, B, and C. The impurity profiles were obtained under the following measurement conditions: silicon body thickness Tsi=100 nm, gate insulator thickness Tox=30 nm, LDD length LD=0.2 μm, LDD implantation: P dosage=1×10¹³/cm², n⁺ implantation: P dosage=2×10¹⁵/cm², sample A: acceleration voltage=15 KeV, sample B: acceleration voltage=25 KeV, and sample C: acceleration voltage=35 KeV. At this point, the P dosage was fixed at 2×10¹⁵ (cm⁻²) (may not be more than 2×10¹⁵ (cm⁻²)). FIG. 2 shows the results of investigating the source-drain breakdown voltages BV for impurity profiles of the samples A, B, and C. Referring to FIG. 2, the source-drain breakdown voltage BV is increased in the LDD structure in which the LDD region is provided rather than in the single drain structure in which the n⁻ LDD region is not provided between the channel region and the drain region. Additionally, the source-drain breakdown voltage BV is obviously increased according to the decrease in junction depth of the n⁺ source region. FIG. 2 shows measured data of the source-drain breakdown voltages BV of the actually-produced samples A, B, and C along with computation values of the simulation result. It is confirmed that a similar tendency is obtained from the measured data. In order to consider physical factors of the phenomenon, lateral electric field intensity and impact ionization intensity along the channel were investigated when the drain voltage and gate voltage were set at 3.5 V and 0.5 V, respectively, in the samples A, B, and C having the LDD structure. FIG. 3 shows the lateral electric field intensity along each channel, and FIG. 4 shows the lateral impact ionization intensity along each channel. The results of FIGS. 3 and 4 were obtained under the following measurement conditions: PTS implantation (channel): B dosage=4×10¹¹/cm², acceleration voltage=35 KeV; LDD implantation: P dosage=1×10¹³/cm², acceleration voltage=15 KeV; n⁺ implantation: P dosage=2×10¹⁵/cm²; silicon body thickness Tsi=100 nm, gate insulator thickness Tox=30 nm, gate length L=0.5 μm, LDD length LD=0.2 μm, drain voltage Vd=3.5 V, gate voltage Vg=0.5 V, electric field intensity in channel direction: value at depth of 20 nm from gate insulator, and impact ionization intensity: value at depth of 20 nm from gate insulator. In comparison of the results of FIGS. 3 and 4, the samples A, B, and C are substantially identical in a peak value of the lateral electric field which is observed in the channel and LDD junction portion. However, when the sample C having the highest impurity concentration near the insulating support substrate with respect to the impurity concentration near the gate insulator is compared to the sample A having the lowest impurity concentration near the insulating support substrate with respect to the impurity concentration near the gate insulator regarding the peak value of the impact ionization intensity, the peak value is decreased by the transfer from the sample C to the sample A by a factor of about 10, that is, by 1/10. It is clear that the increase in source-drain breakdown voltage BV caused by the decrease in depth of the n⁺ source region is attributed to the impact ionization mainly decreased by a shallow junction structure. At this point, a question of why the impact ionization intensity is decreased by the shallow n⁺ source region is raised. It is considered that, because the impact ionization intensity is a function of the maximum electric field intensity and electron current density, an amount of electrons injected into the source junction is decreased when the junction becomes shallow. The electrons injected into the source junction are controlled by a body potential which determines a forward bias of the source-body junction.

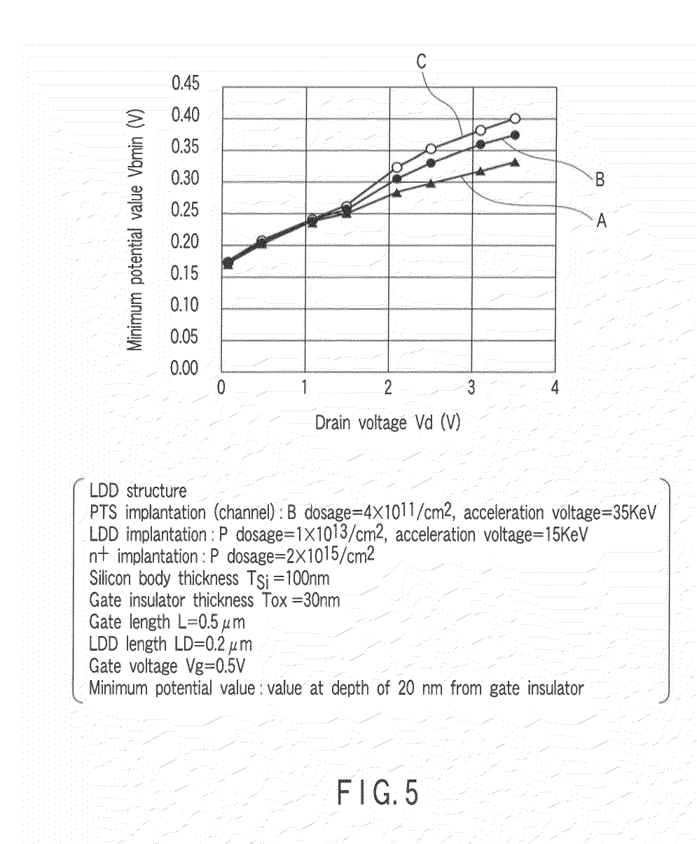

FIG. 5 shows results in which a minimum potential value (Vbmin) in the silicon body is obtained as a function of the drain voltage for the samples A, B, and C. The results of FIG. 5 were obtained under the following measurement conditions: PTS implantation (channel): B dosage=4×10¹¹/cm², acceleration voltage=35 KeV; LDD implantation: P dosage=1×10¹³/cm², acceleration voltage=15 KeV; n⁺ implantation: P dosage=2×10¹⁵/cm²; silicon body thickness Tsi=100 nm, gate insulator thickness Tox=30 nm, gate length L=0.5 μm, LDD length LD=0.2 μm, gate voltage Vg=0.5 V, and minimum potential value: value at depth of 20 nm from gate insulator. As can be seen from FIG. 5, the minimum potential value Vbmin is increased with increasing drain voltage because of an electrostatic effect. When the drain voltage is lower than 1.5 V, the samples A, B, and C have substantially the same minimum potential value Vbmin. In the case of the drain voltage of 1.5 V, the samples A, B, and C have the minimum potential value Vbmin of 0.25 V. The drain voltage of 1.5 V corresponds to the start of the impact ionization in the drain junction. With the drain voltage more than 1.5 V, the minimum potential value Vbmin is increased more steeply as the n⁺ source region becomes deeper. This means that, when the source-body junction is the deep n⁺ junction, a stronger forward bias is applied, and more electrons are injected into the body region. Accordingly, the impact ionization intensity is increased in the case of the deep n⁺ junction.

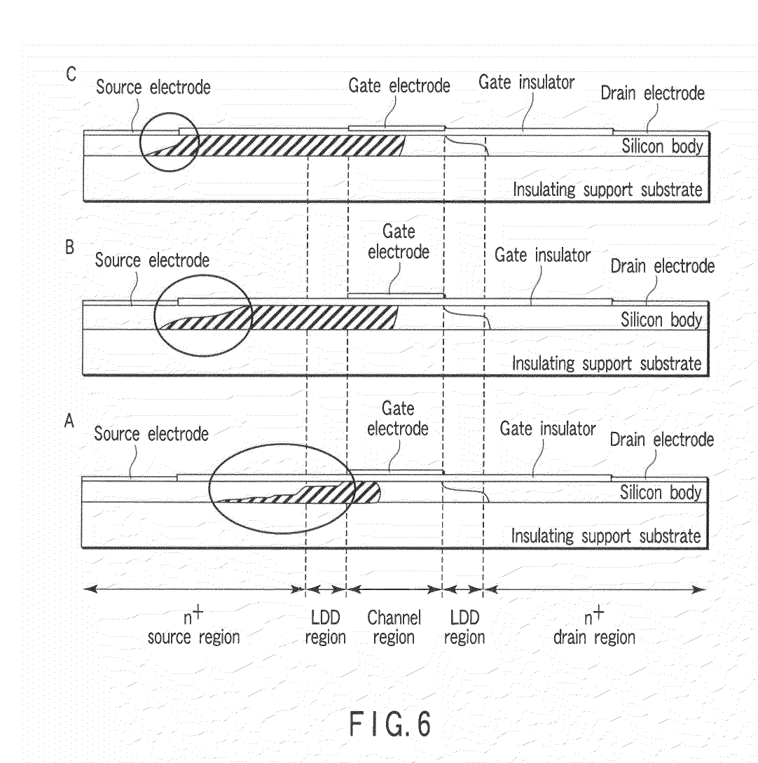

FIG. 6 shows the results of hole density distributions obtained in the samples A, B, and C in which the drain voltage and the gate voltage are biased by 3.5 V and 0.5 V, respectively. In FIG. 6, for example, the region where the hole density is more than 8×10¹⁴ (cm⁻³) is emphasized by diagonal lines. It is considered that a boundary (portion surrounded by a circle of FIG. 6) of the region emphasized by diagonal lines reflects an effective source-body junction length. Because excess holes invade into a lower portion of the n⁺ source region as the n⁺ junction depth is decreased, the effective source-body junction length is increased. This means that an effective area of the source-body junction is increased as the n⁺ depth is decreased. The forward bias Vbs between the source-body junctions is expressed by an equation (1):

$$\begin{matrix}[ Equation 1 ] & \\ Vbs = \frac{{nk}_{B} T}{q} \{ ln ( \frac{{I}_{hole} + {I}_{e}}{{A}_{0} {j}_{sr}} + 1 ) \} & ( 1 )\end{matrix}$$

where q is an elementary electric charge, k_{B} is a Boltzmann constant, T is an absolute temperature, n and jₛᵣ are respectively an n value and reverse saturation current density of the source-body junction, Iₕₒₗₑ and Iₑ are current components of the holes and electrons, and A₀ is an effective junction area. According to the equation (1), assuming that the total current is kept constant, Vbs is decreased when A₀ is increased. This mechanism brings about a difference in the dependence of the minimum potential value Vbmin on the drain voltage when the drain voltage Vd is more than 1.5 V.

Thus, the influence of the source junction depth on the source-drain breakdown voltage BV of the high-performance thin-film transistor was investigated, and it was found that the decrease in source junction depth substantially increases the source-drain breakdown voltage BV. The source-drain breakdown voltage BV is mainly improved by the constraint of the impact ionization. The rise of the body potential, which permits excess holes to invade into the lower portion of the n⁺ source region, can be constrained by decreasing the impact ionization.

An n-channel type thin-film transistor having a single drain structure according to a first embodiment of the invention will be described below with reference to the accompanying drawings. The thin-film transistor of the first embodiment is used to form a pixel switch and a drive circuit in which the high source-drain breakdown voltage is required, for example, in a display panel of an active matrix liquid crystal display apparatus.

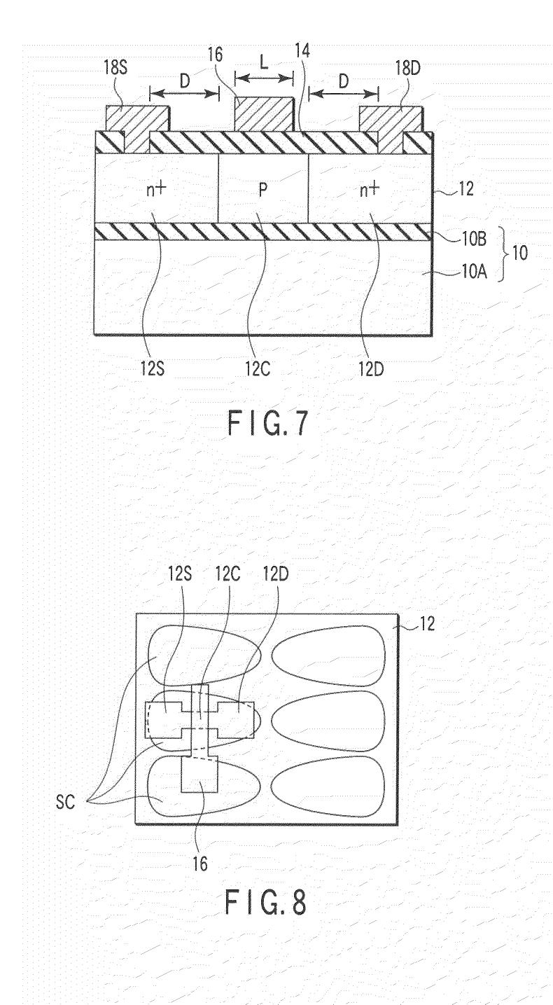

FIG. 7 shows a sectional structure of the n-channel type thin-film transistor having the single drain structure. The thin-film transistor includes an insulating support substrate 10, a semiconductor thin film 12, a gate insulator 14, and a gate electrode layer 16. The semiconductor thin film 12 has a thickness of about 30 to about 200 nm, and is disposed on an insulating surface of the insulating support substrate 10. The semiconductor thin film 12 is covered with the gate insulator 14 having a thickness of, for example, about 30 nm. The gate electrode layer 16 having a thickness of, for example, about 200 nm is formed on the semiconductor thin film 12 with the gate insulator 14 interposed therebetween. The semiconductor thin film 12 includes a channel region 12C, a source region 12S, and a drain region 12D. The channel region 12C is disposed below the gate electrode layer 16. The source region 12S and the drain region 12D are disposed on both sides of the channel region 12C. A source electrode 18S and a drain electrode 18D are connected to the source region 12S and the drain region 12D through a pair of contact holes made in the gate insulator 14. The channel region 12C is a region which is used to move a carrier such as the electron and the hole between the source region 12S and the drain region 12D, and the movement of the carrier is controlled by an electric field corresponding to a gate voltage applied to the gate electrode layer 16. Each of the source region 12S and the drain region 12D is an n⁺-type impurity region containing an n-type impurity such as phosphorus (P), and the channel region 12C is a p-type impurity region containing a p-type impurity such as boron (B). The gate electrode layer 16 has the gate length L not more than 1 μm, for example, 0.5 μm along the channel between the source region 12S and the drain region 12D. The gate electrode layer 16 is formed by a MoW metal film, for example. The gate insulator 14 is made of an oxide such as silicon dioxide (SiO₂), and electrically insulates the gate electrode layer 16 from the channel region 12C in order to make the thin-film transistor serve as the field effect transistor.

An insulating substrate 10A made of a material such as glass, fused quartz, sapphire, plastic, or polyimide can be used as the insulating support substrate 10. In the first embodiment, the glass substrate is used as the insulating substrate 10A, which is covered with an underlying insulating layer 10B constituting a ground of the semiconductor thin film 12. The semiconductor thin film 12 is formed by a single-crystal silicon grain film. An amorphous silicon film is deposited on the underlying insulating layer 10B, and the amorphous silicon film is melt-recrystallized to obtain the single-crystal silicon grain film by a phase-modulated excimer laser crystallization method. In the phase-modulated excimer laser crystallization method, the amorphous silicon film is irradiated with an excimer laser beam whose intensity is spatially modulated using a phase shifter which modulates a phase of an incident light beam to emit the light beam with a light intensity distribution having a reverse peak shape. In the phase-modulated excimer laser crystallization method, the excimer laser is set to the light intensity distribution on the semiconductor thin film 12 according to the phase shifter, and the excimer laser generates a temperature gradient in the semiconductor thin film 12 according to the light intensity distribution. The light intensity distribution includes continuous triangular light intensity distributions. The region irradiated with the excimer laser beam is melted in the semiconductor thin film 12. A crystal is grown in a period during which the excimer laser beam is interrupted. The temperature gradient promotes the growth of a single-crystal silicon grain SC from a lower temperature portion toward a higher temperature portion in a lateral direction parallel to the plain of the semiconductor thin film 12. As a result, as shown in FIG. 8, the single-crystal silicon grain SC is grown to a grain having a diameter of several micrometers in which at least one thin-film transistor can be accommodated. Desirably the thin-film transistor is formed such that electrons or holes are moved toward a crystal growth direction in which the single-crystal silicon grain SC is grown. FIG. 8 shows the shape of the single-crystal silicon grain SC. In the semiconductor thin film 12, MESA etching is performed during a production process such that only an island portion including the source region 12S, the drain region 12D, and the channel region 12C is left. The whole of the channel region 12C is disposed within the single-crystal silicon grain SC.

The semiconductor thin film 12 may directly be formed on the insulating substrate 10A while the underlying insulating layer 10B is not interposed therebetween. The semiconductor thin film 12 may be formed by a semiconductor wafer in which an SOI (Semiconductor On Insulator) structure substrate is formed by bonding the semiconductor wafer to the insulating substrate. The semiconductor thin film 12 may include a semiconductor such as silicon (Si) and silicon-germanium (SiGe). The threshold voltage of the thin-film transistor depends on the impurity concentration of the channel region 12C, and the current driving performance of the thin-film transistor depends on the gate length.

The channel region 12C has an impurity concentration profile in which the impurity concentration is increased from an interface with the gate insulator 14 toward an interface with the insulating support substrate 10 in a thickness direction of the semiconductor thin film 12. The source region 12S and the drain region 12D have impurity concentration profiles in which the impurity concentrations are decreased from the interface with the gate insulator 14 toward the interface with the insulating support substrate 10 in the thickness direction of the semiconductor thin film 12. In the impurity concentration profiles of the source region 12S and drain region 12D, desirably the impurity concentration near the insulating support substrate 10 is lower than the impurity concentration near the gate insulator 14 by a factor of 100 or more. However, an impurity concentration profile other than that described above may be provided for the channel region 12C and drain region 12D.

In the conventional n-channel type thin-film transistor in which the electron is used as the carrier, there is a problem that the thin-film transistor has a low source-drain breakdown voltage while high mobility characteristics can be obtained. On the other hand, in the n-channel transistor of the first embodiment of FIG. 7, the high breakdown voltage is realized by decreasing the impurity concentration near the insulating support substrate 10 by a factor of 100 or more with respect to the impurity concentration near the gate insulator 14 in the impurity concentration profiles of the source region 12S and drain region 12D.

For example, the impurity concentration profiles of the source region 12S and drain region 12D can be measured with a secondary ion mass spectrometer.

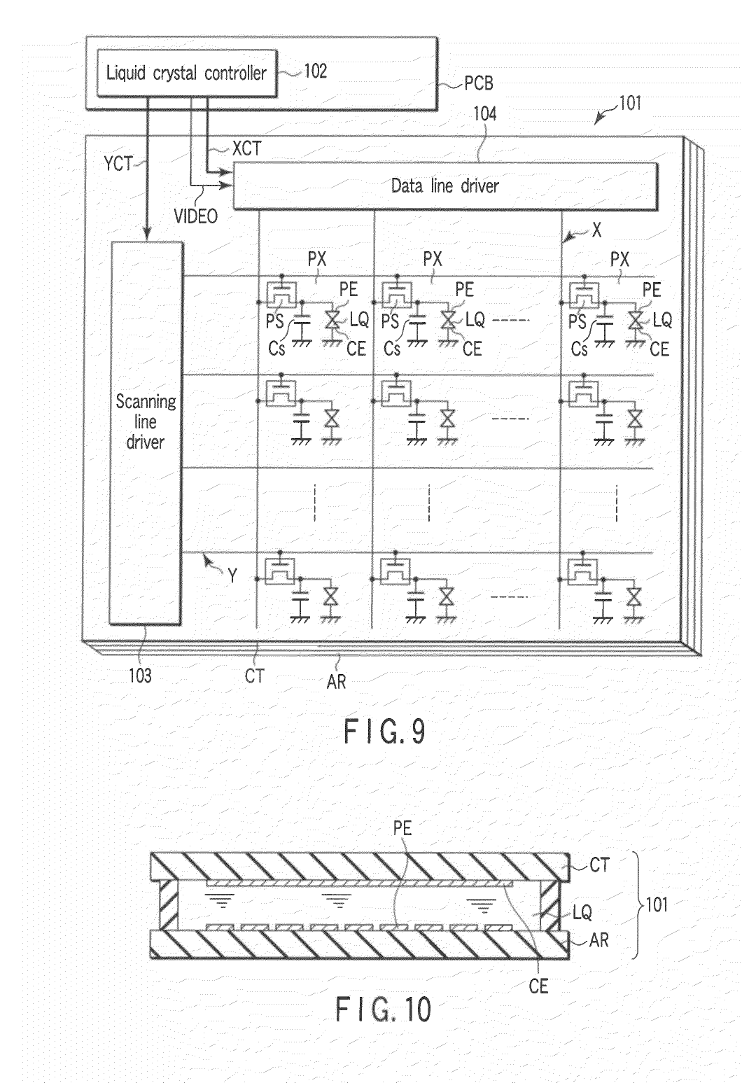

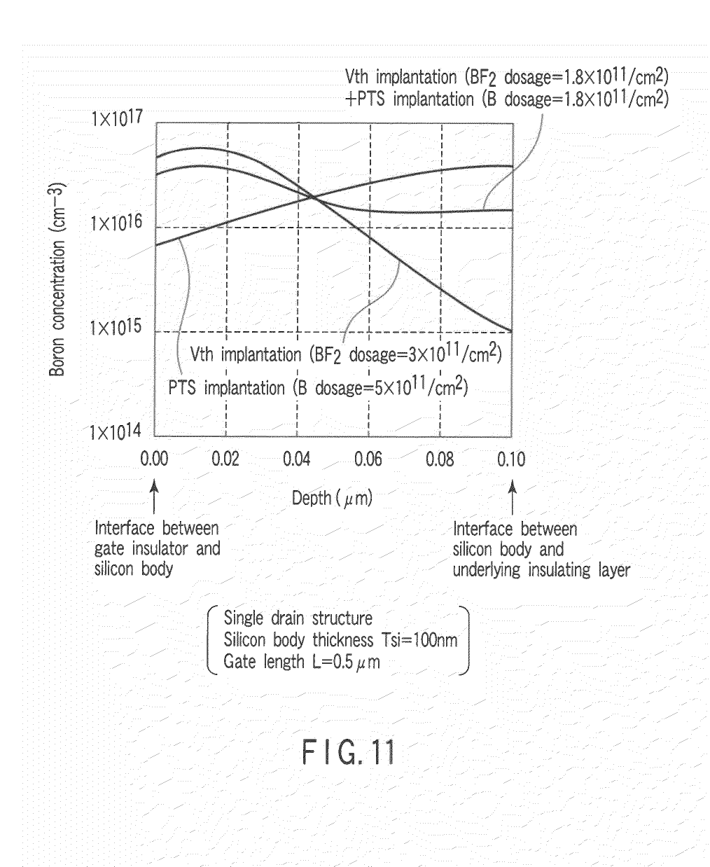

FIG. 9 shows a schematic circuit configuration of a liquid crystal display apparatus in which the thin-film transistor is used, and FIG. 10 shows a schematic sectional structure of the liquid crystal display apparatus.

The liquid crystal display apparatus includes a liquid crystal display panel 101 and a liquid crystal controller 102 which controls the liquid crystal display panel 101. The liquid crystal display panel 101 has a structure in which a liquid crystal layer LQ is retained between an array substrate AR and a counter substrate CT. The liquid crystal controller 102 is disposed on a drive circuit board PCB which is independent of the liquid crystal display panel 101.

The liquid crystal display panel 101 includes plural display pixels PX which are disposed in a matrix, plural scanning lines Y which are disposed along each row of the plural display pixels PX, plural data lines X which are disposed along each column of the plural display pixels PX, plural pixel switches PS, a scanning line driver 103 which drives the plural scanning lines Y, and a data line driver 104 which drives the plural data lines X. Each of the plural pixel switches PS is disposed near a crossing point of the data line X and the scanning line Y, takes in a data signal from one data line X in response to a gate pulse from one scanning line Y, and supplies the data signal to one display pixel PX. The plural scanning lines Y, the plural data lines X, the pixel switches PX, the scanning line driver 103, and the data line driver 104 are formed on the array substrate AR. Each of the display pixels PX includes one of plural pixel electrodes PE formed on the array substrate AR, a single common electrode CE, a part of the liquid crystal layer LQ, and an auxiliary capacitance Cs. The common electrode CE is formed on the counter electrode CT while facing the plural pixel electrodes PE, and is set at a common potential. The part of the liquid crystal layer LQ is located between the pixel electrode PE and the common electrode CE. The auxiliary capacitance Cs is formed on the array substrate AR, and is connected in parallel with a liquid crystal capacitance between the pixel electrode PE and the common electrode CE. The auxiliary capacitance Cs retains a voltage of the data signal supplied from the pixel switch PX, and applies the voltage of the data signal to the pixel electrode PE. A transmittance of the display pixel PX is controlled by a potential difference between the pixel electrode PE and the common electrode CE.

The liquid crystal controller 102 receives a digital video signal VIDEO and a synchronous signal which are supplied from the outside, and generates a vertical scanning control signal YCT and a horizontal scanning control signal XCT. The vertical scanning control signal YCT is supplied to the scanning line driver 103, and the horizontal scanning control signal XCT is supplied to the data line driver 104 along with the video signal VIDEO. The scanning line driver 103 is controlled by the vertical scanning control signal YCT, and sequentially supplies gate pulses to the plural scanning lines Y during one vertical scanning (frame) period. The gate pulse is supplied to each scanning line Y only during one horizontal scanning period (1H). The data line driver 104 is controlled by the horizontal scanning control signal XCT, and performs serial-parallel conversion and digital-analog conversion of the video signal VIDEO to supply one-row data signal to each of the plural data lines X. The video signal VIDEO is fed during the horizontal scanning period in which the one scanning line Y is driven by the gate pulse. Each of the pixel switch PS, the scanning line driver 103, and the data line driver 104 is formed with the thin-film transistor having the structure of FIG. 7.

The simulation results performed for the thin-film transistor having the single drain structure of FIG. 7 will be described below.

FIG. 11 shows an influence of boron (B) ion implantation conditions on the impurity profile of the channel region 12C. At this point, Vth implantation is an implantation method for performing the ion implantation of BF₂ to control the threshold voltage of the thin-film transistor. PTS (Punch Through Stop) implantation is an implantation method in which the ion implantation of B is performed to increase a concentration of a portion away from the interface with the gate insulator 14 in the thickness direction, that is, the depth direction of the semiconductor thin film 12, whereby a resistance of the portion is lowered to prevent accumulation of the impact ions. Different impurity profiles are obtained as shown in FIG. 11, when the simulations are performed for the case where only the Vth implantation is performed, the case where both the Vth implantation and the PTS implantation are performed, and the case where only the PTS implantation is performed. The results of FIG. 11 are obtained by the following measurement conditions: Vth implantation: BF₂ dosage=3×10¹¹/cm², PTS implantation: B dosage=5×10¹¹/cm², Vth+PTS implantation: (BF₂ dosage=1.8×10¹¹/cm²)+(B dosage=1.8×10¹¹/cm²), silicon body thickness Tsi=100 nm, and gate length L=0.5 μm.

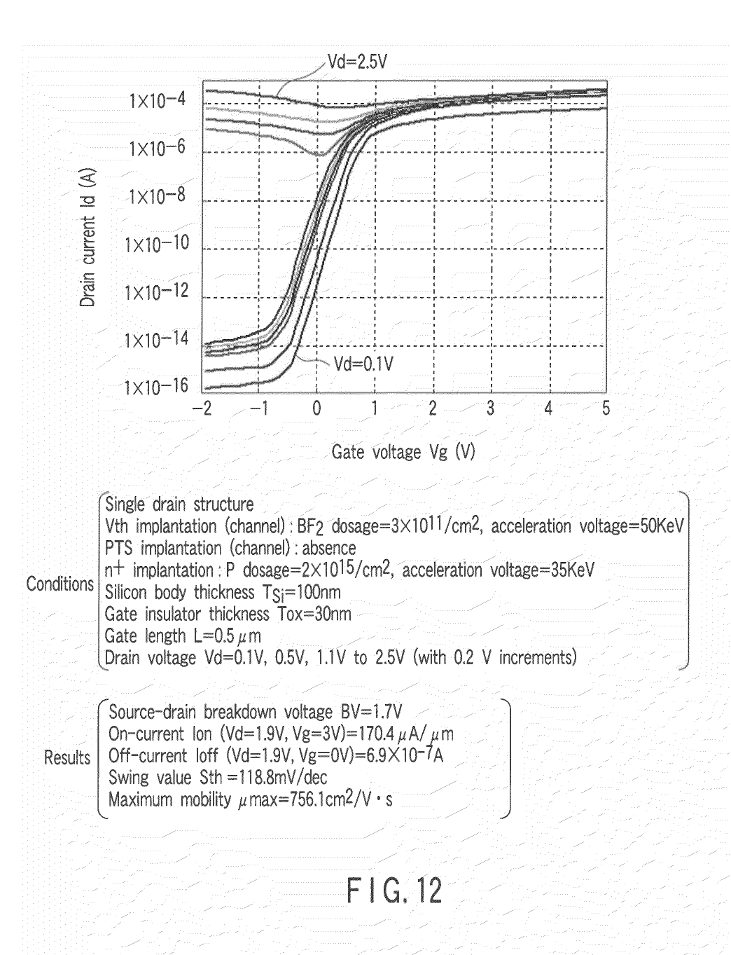

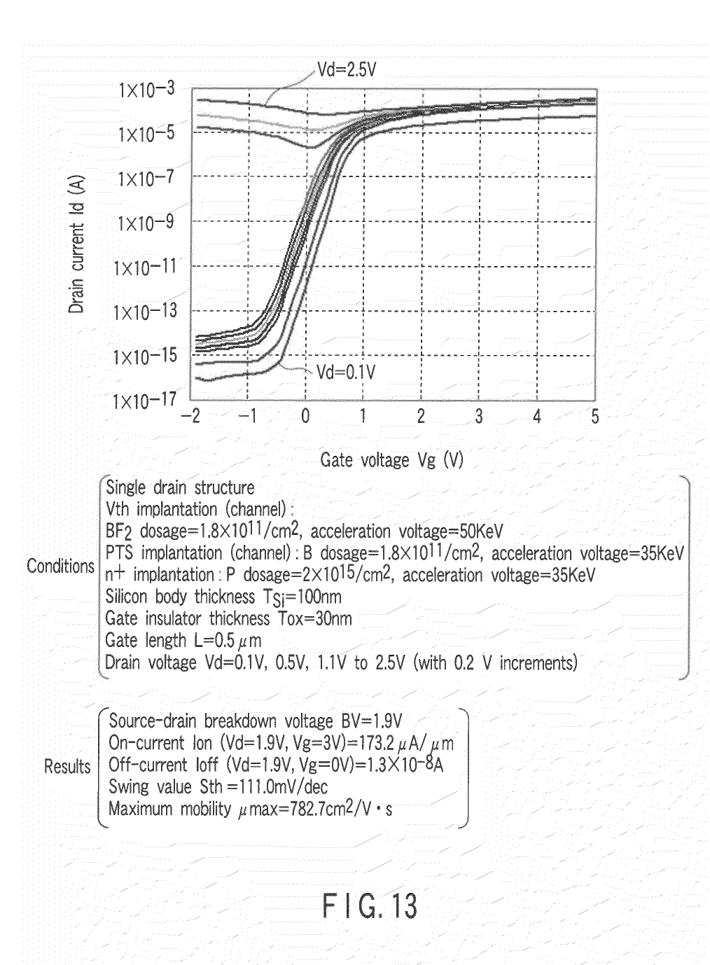

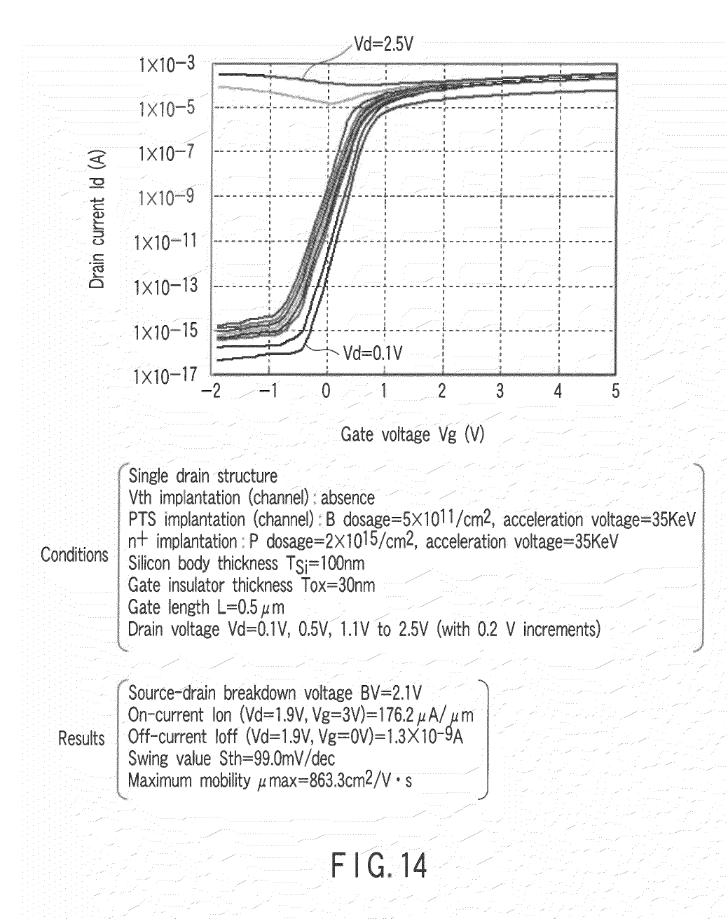

FIGS. 12 to 14 show gate voltage Vg-drain current Id characteristics in the case where only the Vth implantation is performed, in the case where both the Vth implantation and the PTS implantation are performed, and in the case where only the PTS implantation is performed in the device having the single drain structure whose gate length L is set at 0.5 μm respectively. The results of FIG. 12 were obtained under the following measurement conditions: Vth implantation (channel): BF₂ dosage=3×10¹¹/cm², acceleration voltage=50 KeV; PTS implantation (channel): absence; n⁺ implantation: P dosage=2×10¹⁵/cm², acceleration voltage=35 KeV; silicon body thickness Tsi=100 nm, gate insulator thickness Tox=30 nm, gate length L=0.5 μm, drain voltage Vd=0.1 V, 0.5 V, and 1.1 V to 2.5 V (with 0.2 V increments). In this case, the following results were obtained: source-drain breakdown voltage BV=1.7 V, on-current Ion (Vd=1.9 V and Vg=3 V)=170.4 μA/μm, off-current Ioff (Vd=1.9 V and Vg=0 V)=6.9×10⁻⁷ A, swing value Sth=118.8 mV/dec, and maximum mobility μmax=756.1 cm²/V·s. The results of FIG. 13 were obtained under the following measurement conditions: Vth implantation (channel): BF dosage=1.8×10¹¹/cm², acceleration voltage=50 KeV; PTS implantation (channel): B dosage=1.8×10¹¹/cm², acceleration voltage=35 KeV; n⁺ implantation: P dosage=2×10¹⁵/cm², acceleration voltage=35 KeV; silicon body thickness Tsi=100 nm, gate insulator thickness Tox=30 nm, gate length L=0.5 μm, drain voltage Vb=0.1 V, 0.5 V, and 1.1 V to 2.5 V (with 0.2 V increments). In this case, the following results were obtained: source-drain breakdown voltage BV=1.9 V, on-current Ion (Vd=1.9 V and Vg=3 V)=173.2 μA/μm, off-current Ioff (Vd=1.9 V and Vg=0 V)=1.3×10⁻⁸ A, swing value Sth=111.0 mV/dec, and maximum mobility μmax=782.7 cm²/V·s. The results of FIG. 14 were obtained under the following measurement conditions: Vth implantation (channel): absence; PTS implantation (channel): B dosage=5×10¹¹/cm², acceleration voltage=35 KeV; n⁺ implantation: P dosage=2×10¹⁵/cm², acceleration voltage=35 KeV; silicon body thickness Tsi=100 nm, gate insulator thickness Tox=30 nm, gate length L=0.5 μm, drain voltage Vd=0.1 V, 0.5 V, and 1.1 V to 2.5 V (with 0.2 V increments). In this case, the following results were obtained: source-drain breakdown voltage BV=2.1 V, on-current Ion (Vd=1.9 V and Vg=3 V)=176.2 μA/μm, off-current Ioff (Vd=1.9 V and Vg=0 V)=1.3×10⁻⁹ A, swing value Sth=99.0 mV/dec, and maximum mobility μmax=863.3 cm²/V·s. From these characteristics, the source-drain breakdown voltage BV becomes 1.7 V in the case where only the Vth implantation is performed, becomes 1.9 V in the case where both the Vth implantation and the PTS implantation are performed, and becomes 2.1 V in the case where only the PTS implantation is performed.

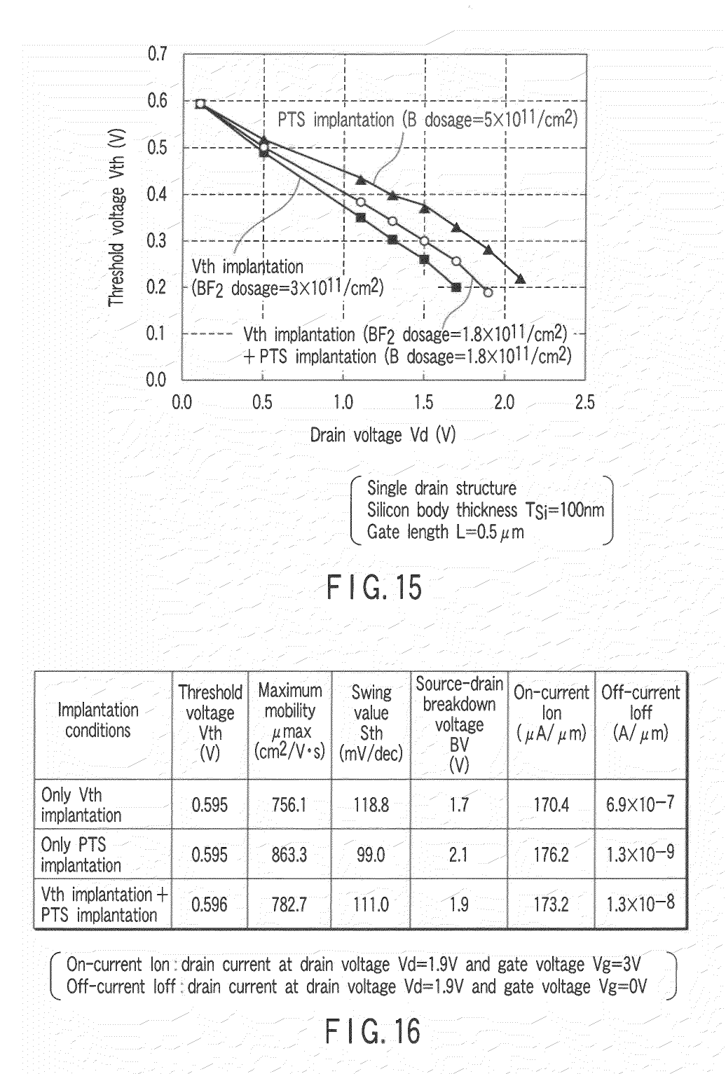

FIG. 15 shows an influence of boron (B) ion implantation conditions on dependence of the threshold voltage Vth on the drain voltage Vd. The results of FIG. 15 were obtained under the following measurement conditions: Vth implantation: BF₂ dosage=3×10¹¹/cm², PTS implantation: B dosage=5×10¹¹/cm², Vth implantation+PTS implantation: (BF₂ dosage=1.8×10¹¹/cm²)+(B dosage=1.8×10¹¹/cm²); silicon body thickness Tsi=100 nm, and gate length L=0.5 μm. At this point, each dosage, which is the detailed implantation condition, is adjusted such that substantially the same threshold voltage Vth is obtained in the case of the low drain voltage Vd (0.1 V in this case). Generation of a DIBL (Drain Induced Barrier Lowering) effect, in which the threshold voltage Vth is changed depending on the drain voltage Vd, is hardly avoided in the thin-film transistor. As can be seen from FIG. 15, DIBL has the strongest influence in the case where only the Vth implantation is performed, and has little influence in the case where only the PTS implantation is performed.

FIG. 16 shows a list of an influence of implantation conditions on the maximum mobility μmax, the swing value Sth, the source-drain breakdown voltage BV, the on-current Ion, and the off-current Ioff of the thin-film transistor. The implantation conditions are the acceleration voltage of the ion implantation apparatus. In the case of only the Vth implantation, the results are obtained as follows: source-drain breakdown voltage BV=1.7 V, on-current Ion (Vd=1.9 V and Vg=3 V)=170.4 μA/μm, off-current Ioff (Vd=1.9 V and Vg=0 V)=6.9×10⁻⁷ A, swing value Sth=118.8 mV/dec, and maximum mobility μmax=756.1 cm²/V·s. In the case of only the PTS implantation, the results are obtained as follows: source-drain breakdown voltage BV=2.1 V, on-current Ion (Vd=1.9 V and Vg=3 V)=176.2 μA/μm, off-current Ioff (Vd=1.9 V and Vg=0 V)=1.3×10⁻⁹ A, swing value Sth=99.0 mV/dec, and maximum mobility μmax=863.3 cm²/V·s. In the case of the Vth implantation+PTS implantation, the results are obtained as follows: source-drain breakdown voltage BV=1.9 V, on-current Ion (Vd=1.9 V and Vg=3 V)=173.2 μA/μm, off-current Ioff (Vd=1.9 V and Vg=0 V)=1.3×10⁻⁸ A, swing value Sth=111.0 mV/dec, and maximum mobility μmax=782.7 cm²/V·s. It is found from these results that the best maximum mobility μmax, swing value Sth, source-drain breakdown voltage BV, on-current Ion, and off-current Ioff are obtained in the case where only the PTS implantation is performed.

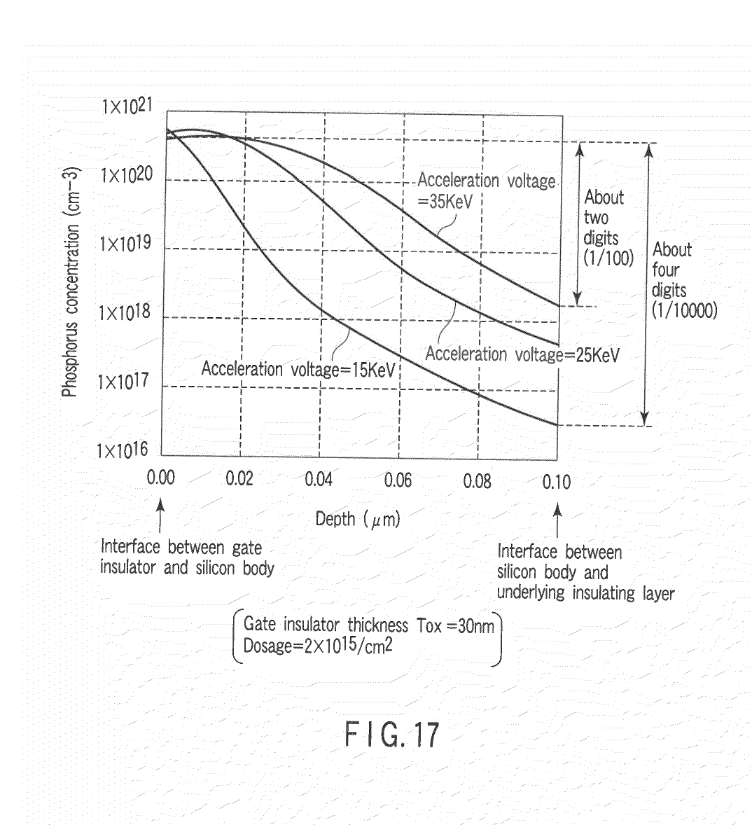

FIG. 17 shows an influence of the acceleration voltage of the ion implantation apparatus for performing the phosphorus (P) ion implantation on the impurity profile of the n⁺ region such as the source region 12S and the drain region 12D. The results of FIG. 17 were obtained under the following measurement conditions: gate insulator thickness Tox=30 nm and dosage=2×10¹⁵/cm². At this point, the P ion implantation is performed such that the n⁺ implantation lowers the concentration of the portion away from the interface with the gate insulator 14 in the thickness direction, that is, the depth direction of the semiconductor thin film 12. When the simulation is performed for the n⁺ implantation, a different impurity profile is obtained for each acceleration voltage, as shown in FIG. 17. In the case of the acceleration voltage of 35 KeV, the phosphorus concentration near the insulating support substrate 10 is lower than the phosphorus concentration near the gate insulator 14 by two digits, that is, by a factor of about 100. In the case of the acceleration voltage of 15 KeV, the phosphorus concentration near the insulating support substrate 10 is lower than the phosphorus concentration near the gate insulator 14 by four digits, that is, by a factor of about 10000.

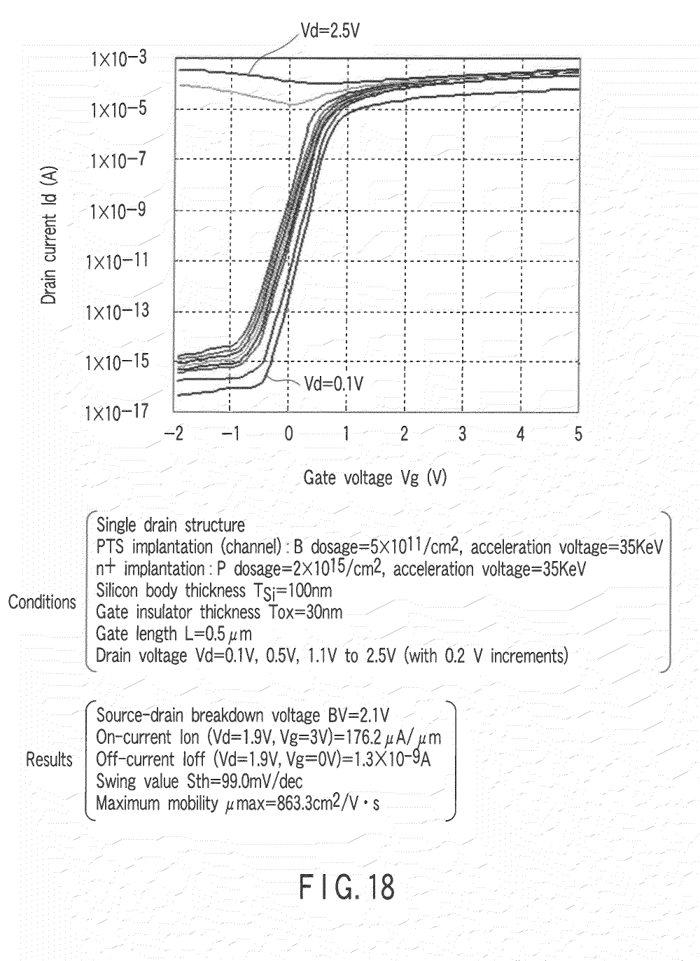

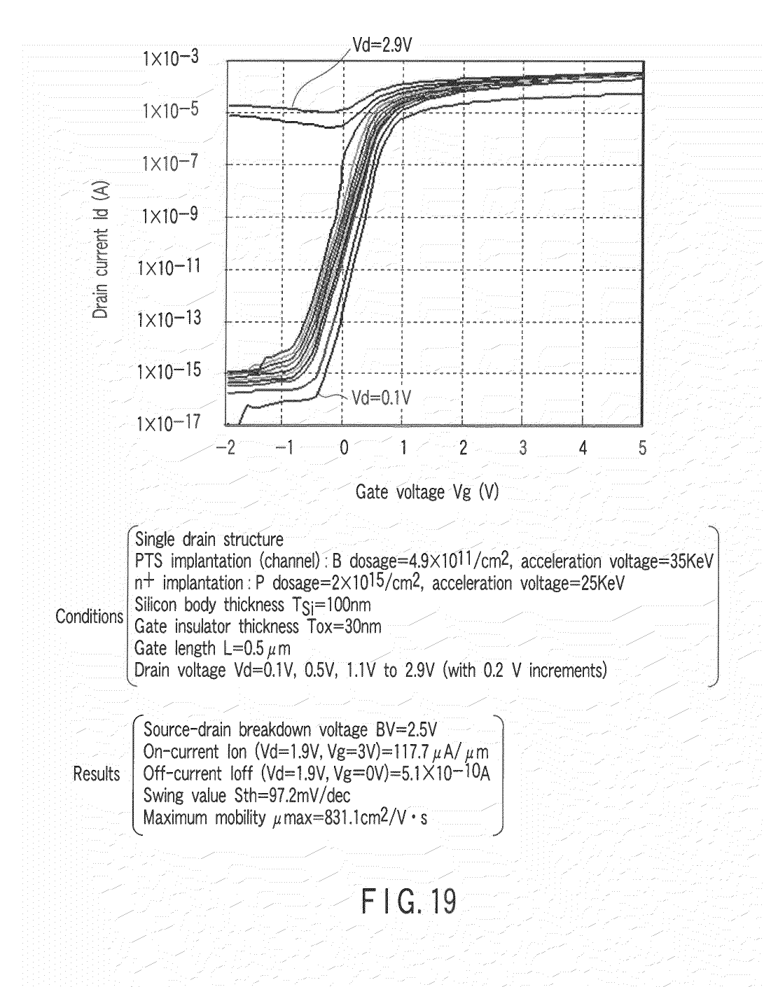

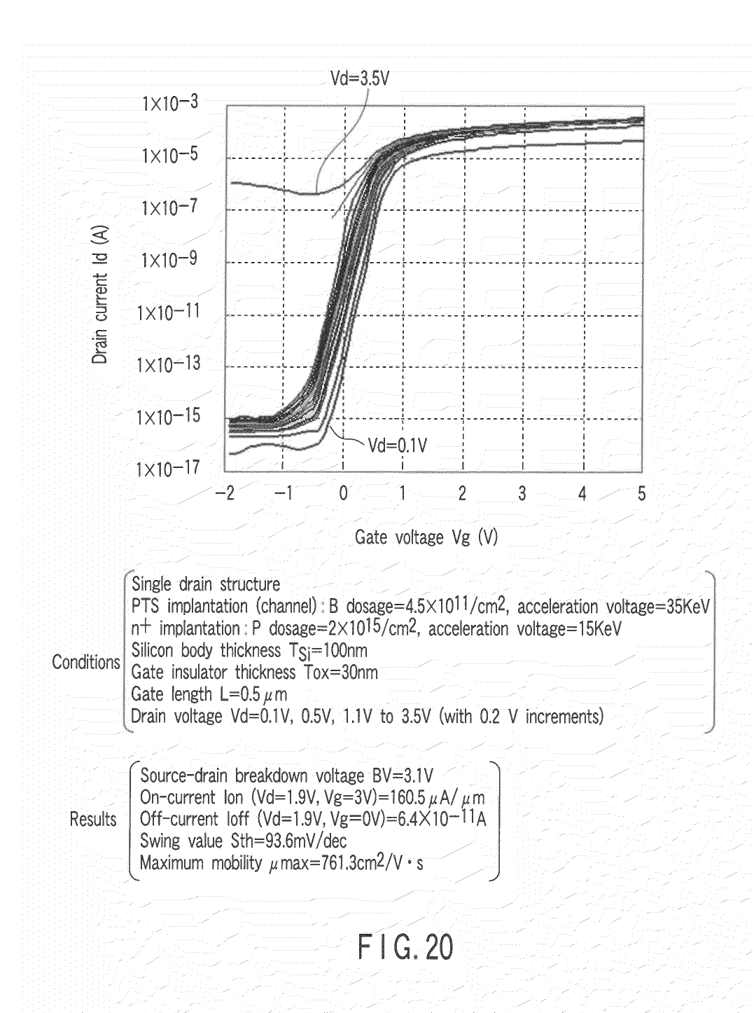

FIGS. 18 to 20 show gate voltage Vg-drain current Id characteristics in the case where the n⁺ implantation is performed with the acceleration voltages of 35, 25, and 15 KeV in the thin-film transistor having the single drain structure whose gate length L is set to 0.5 μm. The results of FIG. 18 were obtained under the following measurement conditions: PTS implantation (channel): B dosage=5×10¹¹/cm², acceleration voltage=35 KeV; n⁺ implantation: B dosage=2×10¹⁵/cm², acceleration voltage=35 KeV; silicon body thickness Tsi=100 nm, gate insulator thickness Tox=30 nm, gate length L=0.5 μm, drain voltage Vd=0.1 V, 0.5 V, and 1.1 V to 2.5 V (with 0.2 V increments). In this case, the following results were obtained: source-drain breakdown voltage BV=2.1 V, on-current Ion (Vd=1.9 V and Vg=3 V)=176.2 μA/μm, off-current Ioff (Vd=1.9 V and Vg=0 V)=1.3×10⁻⁹ A, swing value Sth=99.0 mV/dec, and maximum mobility μmax=863.3 cm²/V·s. The results of FIG. 19 were obtained under the following measurement conditions: PTS implantation (channel): B dosage=4.9×10¹¹/cm², acceleration voltage=35 KeV; n⁺ implantation: B dosage=2×10¹⁵/cm², acceleration voltage=25 KeV; silicon body thickness Tsi=100 nm, gate insulator thickness Tox=30 nm, gate length L=0.5 μm, drain voltage Vd=0.1 V, 0.5 V, and 1.1 V to 2.9 V (with 0.2 V increments). In this case, the following results were obtained: source-drain breakdown voltage BV=2.5 V, on-current Ion (Vd=1.9 V and Vg=3 V)=117.7 μA/μm, off-current Ioff (Vd=1.9 V and Vg=0 V)=5.1×10⁻¹⁰ A, swing value Sth=97.2 mV/dec, maximum mobility μmax=831.1 cm²/V·s. The results of FIG. 20 were obtained under the following measurement conditions: PTS implantation (channel): B dosage=4.5×10¹¹/cm², acceleration voltage=35 KeV; n⁺ implantation: B dosage=2×10¹⁵/cm², acceleration voltage=15 KeV; silicon body thickness Tsi=100 nm, gate insulator thickness Tox=30 nm, gate length L=0.5 μm, drain voltage Vd=0.1 V, 0.5 V, and 1.1 V to 3.5 V (with 0.2 V increments). In this case, the following results were obtained: source-drain breakdown voltage BV=3.1 V, on-current Ion (Vd=1.9 V, Vg=3 V)=160.5 μA/μm, off-current Ioff (Vd=1.9 V, Vg=0 V)=6.4×10¹¹ A, swing value Sth=93.6 mV/dec, and maximum mobility μmax=761.3 cm²/V·s. From these characteristics, the source-drain breakdown voltage BV becomes 2.1 V in the case where the n⁺ implantation is performed with acceleration voltage of 35 KeV, becomes 2.5 V in the case where the n⁺ implantation is performed with acceleration voltage of 25 KeV, and becomes 3.1 V in the case where the n⁺ implantation is performed with acceleration voltage of 15 KeV.

FIG. 21 shows an influence of the acceleration voltage of phosphorus (P) ion implantation on dependence of the threshold voltage Vth on the drain voltage Vd. The results of FIG. 21 were obtained under the following measurement conditions: B dosage=4.5×10¹¹/cm² for channel region in the case of acceleration voltage=15 KeV, B dosage=4.9×10¹¹/cm² for channel region in the case of acceleration voltage=25 KeV, B dosage=5×10¹¹/cm² for channel region in the case of acceleration voltage=35 KeV, n⁺ implantation: P dosage=2×10¹⁵/cm², silicon body thickness Tsi=100 nm, and gate length L=0.5 μm. At this point, the PTS implantation is performed such that the boron concentration is increased from the interface with the gate insulator 14 toward the interface with the insulating support substrate 10 in the channel region 12C, and the dosage, which is the detailed ion implantation condition for the channel region 12C, is adjusted for each acceleration voltage such that substantially the same threshold voltage Vth is obtained in the case of the low drain voltage Vd (Vd=0.1 V in this case). As can be seen from FIG. 21, DIBL has less influence as the acceleration voltage becomes smaller during the formation of the n⁺ region.

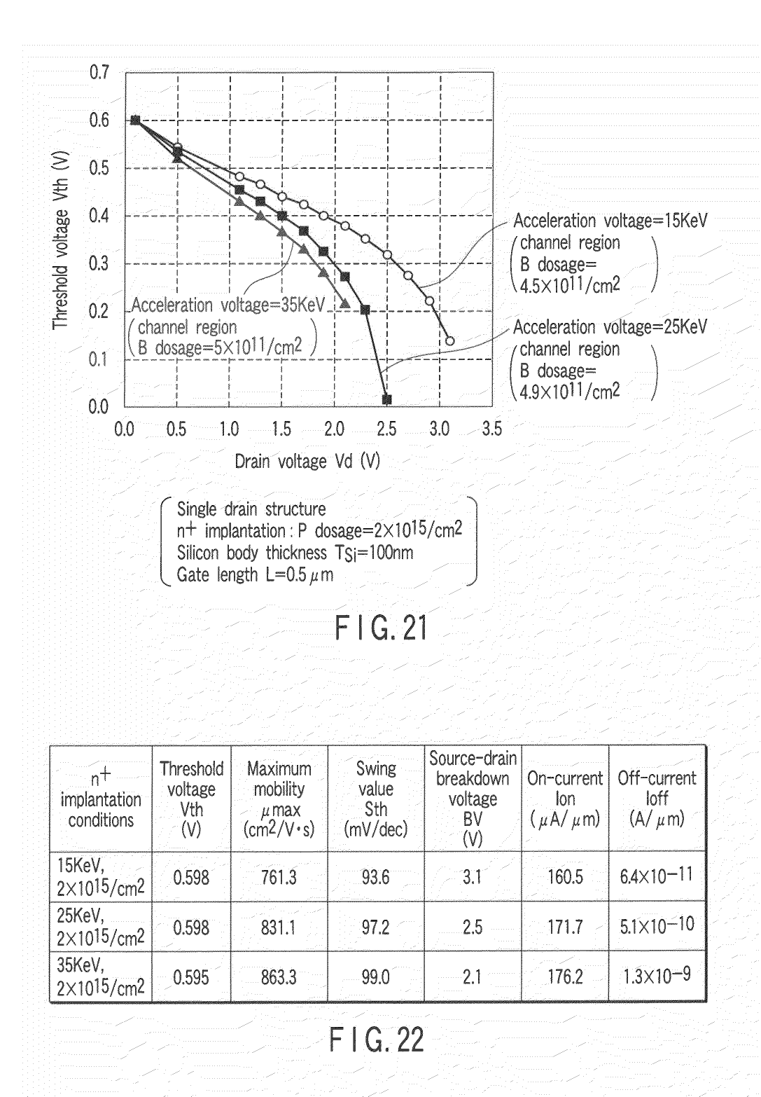

FIG. 22 shows a list of an influence of the acceleration voltage on the maximum mobility μmax, swing value Sth, source-drain breakdown voltage BV, on-current Ion, and off-current Ioff. In the case of the acceleration voltage=15 KeV, the following results were obtained: maximum mobility μmax=761.3 cm²/V·s, swing value Sth=93.6 mV/dec, source-drain breakdown voltage BV=3.1 V, on-current Ion=160.5 μA/μm, and off-current Ioff=6.4×10⁻¹¹ A. In the case of acceleration voltage=25 KeV, the following results were obtained: maximum mobility μmax=831.1 cm²/V·s, swing value Sth=97.2 mV/dec, source-drain breakdown voltage BV=2.5 V, on-current Ion=171.7 μA/μm, and off-current Ioff=5.1×10⁻¹⁰ A. In the case of the acceleration voltage=35 KeV, the following results were obtained: maximum mobility μmax=863.3 cm²/V·s, swing value Sth=99.0 mV/dec, source-drain breakdown voltage BV=2.1 V, on-current Ion=176.2 μA/μm, and off-current Ioff=1.3×10⁻⁹ A. It is found from these results that the source-drain breakdown voltage BV is largely improved by decreasing the acceleration voltage although the on-current Ion is lowered.

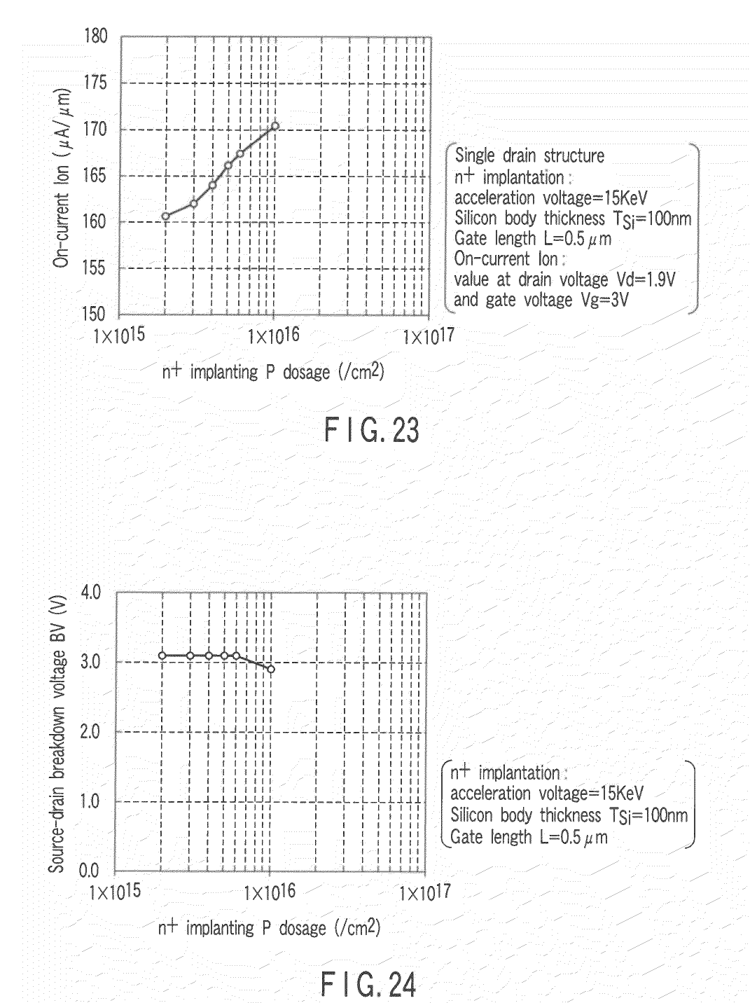

FIG. 23 shows an influence of an n⁺ implanting phosphorus (P) dosage on the on-current Ion of the thin-film transistor, and FIG. 24 shows an influence of the n⁺ implanting phosphorus (P) dosage on the source-drain breakdown voltage BV of the thin-film transistor. The results of FIG. 23 were obtained under the following measurement conditions: n⁺ implantation: acceleration voltage=15 KeV, silicon body thickness Tsi=100 nm, gate length L=0.5 μm, on-current Ion: drain voltage Vd=1.9 V, and gate voltage Vg=3 V. The results of FIG. 24 were obtained under the following measurement conditions: n⁺ implantation: acceleration voltage=15 KeV, silicon body thickness Tsi=100 nm, and gate length L=0.5 μm. As can be seen from FIGS. 23 and 24, the on-current Ion can be increased by increasing the phosphorus dosage while the source-drain breakdown voltage BV is not substantially lowered. From the detailed investigation of FIG. 23, it is found that the dosage of not more than 3×10¹⁵/cm² differs largely from the dosage not lower than 4×10¹⁵/cm² in a gradient of the increase in on-current Ion to the dosage. That is, the on-current Ion can effectively be increased by setting the dosage at 4×10¹⁵/cm² or more. The thin-film transistor in which the on-current characteristics and the source-drain breakdown voltage characteristics are optimized can be obtained, when the n⁺ implanting phosphorus (P) dosage is set at a value of 4×10¹⁵/cm² or more at which the gradient of the increase in on-current Ion is largely changed as shown in FIG. 23 up to a value of 1×10¹⁶/cm² at which the source-drain breakdown voltage BV is considerably lowered as shown in FIG. 24.

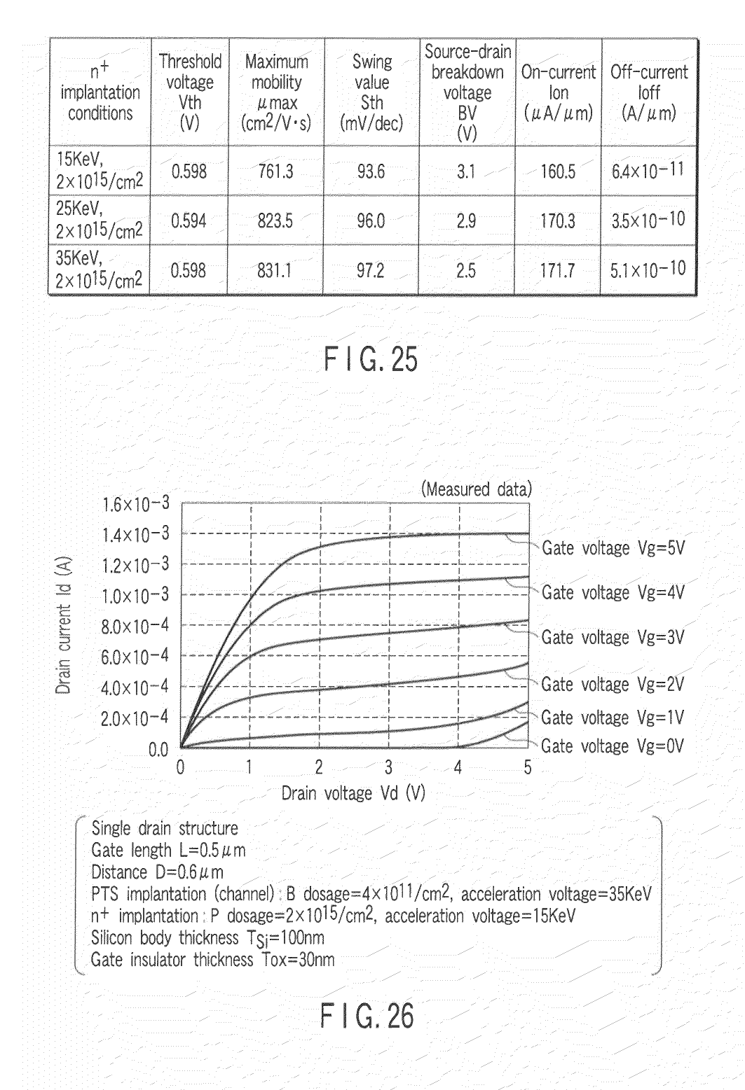

FIG. 25 shows a list of an influence of the n⁺ implanting phosphorus dosage and acceleration voltage on the maximum mobility μmax, swing value Sth, source-drain breakdown voltage BV, on-current Ion, and off-current Ioff. In the case of the acceleration voltage=15 KeV, the following results were obtained: maximum mobility μmax=761.3 cm²/V·s, swing value Sth=93.6 mV/dec, source-drain breakdown voltage BV=3.1 V, on-current Ion=160.5 μA/μm, and off-current Ioff=6.4×10⁻¹¹ A. In the case of the acceleration voltage=25 KeV, the following results were obtained: maximum mobility max=823.5 cm²/V·s, swing value Sth=96.0 mV/dec, source-drain breakdown voltage BV=2.9 V, on-current Ion=170.3 μA/μm, and off-current Ioff=3.5×10⁻¹⁰ A. In the case of the acceleration voltage=35 KeV, the following results were obtained: maximum mobility μmax=831.1 cm²/V·s, swing value Sth=97.2 mV/dec, source-drain breakdown voltage BV=2.5 V, on-current Ion=171.7 μA/μm, and off-current Ioff=5.1×10⁻¹⁰ A. For example, in the case of acceleration voltage=15 KeV, a good source-drain breakdown voltage BV=2.9 V and on-current Ion=170.3 can basically be obtained when the n⁺ implanting phosphorus dosage is set at 1×10¹⁶/cm².

In the first embodiment, the impurity concentration profile is provided in the source region 12S such that the impurity concentration is decreased from the interface with the gate insulator toward the interface with the insulating support substrate in the thickness direction of the semiconductor thin film. Therefore, the maximum mobility μmax of the thin-film transistor is increased, the swing value Sth is decreased, the on-current Ion is increased, the off-current Ioff is decreased, the source-drain breakdown voltage BV is improved, and the fluctuation in threshold voltage Vth caused by the DIBL effect can be decreased. Even if the threshold voltage is shifted from a desired value in order to obtain the impurity concentration profile which improves the source-drain breakdown voltage BV, a ratio of the impurity concentration near the insulating support substrate 10 to the impurity concentration near the gate insulator 14 is maintained by adjusting the impurity dosage, whereby the desired threshold voltage Vth can be obtained.

In the first embodiment, a distance D between a contact portion of the drain electrode 18D for the drain region 18D and an end of the drain region 12D adjacent to the channel region 12C is set at 0.5 μm, which is identical to the gate length L. The distance D between a contact portion of the source electrode 18S for the source region 18S and an end of the source region 12S adjacent to the channel region 12C is set at 0.5 μm, which is identical to the gate length L. At least the distance D between the contact portion of the drain electrode 18D and the end of the drain region 12D adjacent to the channel region 12C should be set so as not to exceed 4 μm, more preferably 1 μm in order not to degrade the good device characteristics obtained by the impurity concentration profiles of the channel region 12C, source region 12S, and drain region 12D.

That the distance D from the inside end of the contact portion (contact hole) of the drain electrode 18D to the junction between the channel region 12C and the drain region 12D is not more than 4 μm can be confirmed by measurement with a laser microscope, an ultraviolet microscope, or an optical microscope.

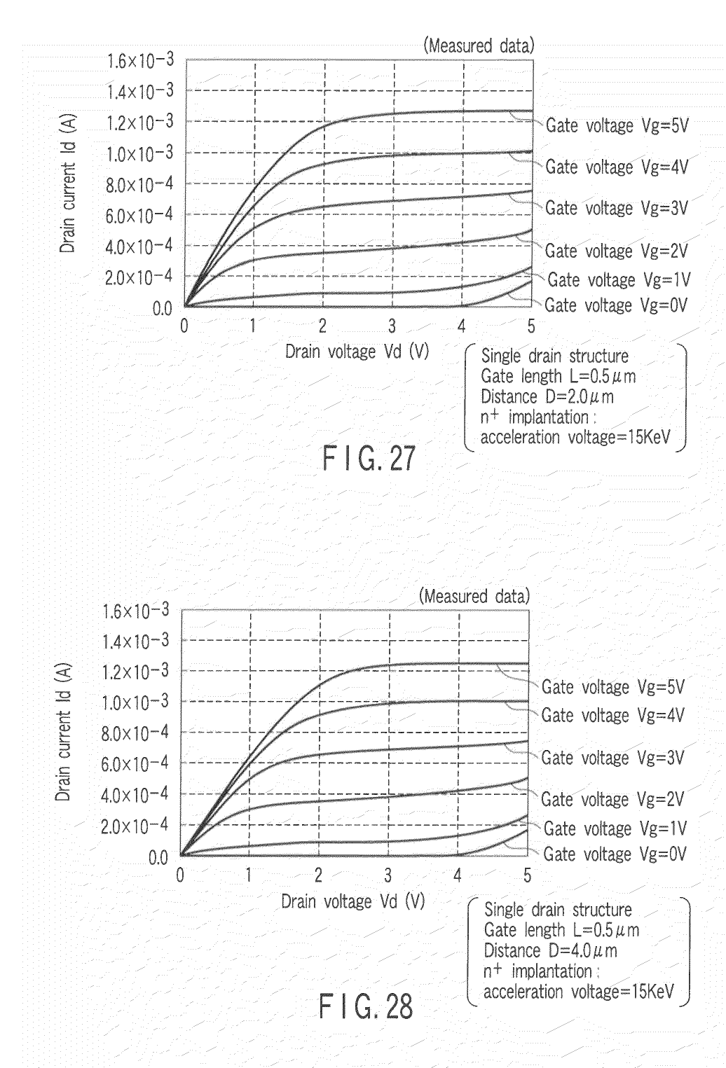

FIGS. 26 to 29 show drain current Id-drain voltage Vd characteristics which are obtained in the case where the distances D of 0.6 μm, 2.0 μm, 4.0 μm, and 7.0 μm are applied to a shallow junction obtained at the n⁺ ion implanting acceleration voltage of 15 KeV in the thin-film transistor having the single drain structure whose gate length L is set at 0.5 μm. The results of FIGS. 26 to 29 were obtained under the following measurement conditions: gate length L=0.5 μm, PTS implantation (channel): B dosage=4×10¹¹/cm², acceleration voltage=35 KeV, n⁺ implantation: P dosage=2×10¹⁵/cm², silicon body thickness Tsi=100 nm, and gate insulator thickness Tox=30 nm. In the case of distance D=7.0 μm, it is found that the inclination of the characteristic curve becomes significantly small due to the parasitic capacitance corresponding to the distance D. Accordingly, the distance D is set at 4 μm or less, preferably 1 μm or less.

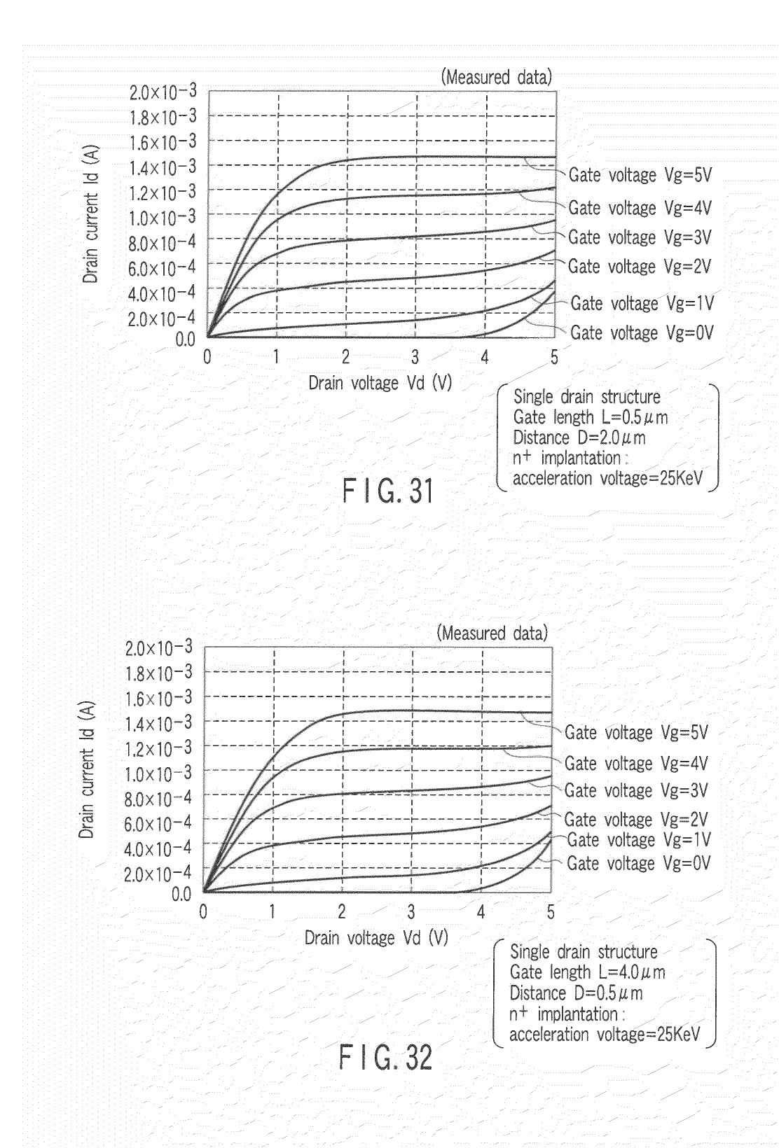

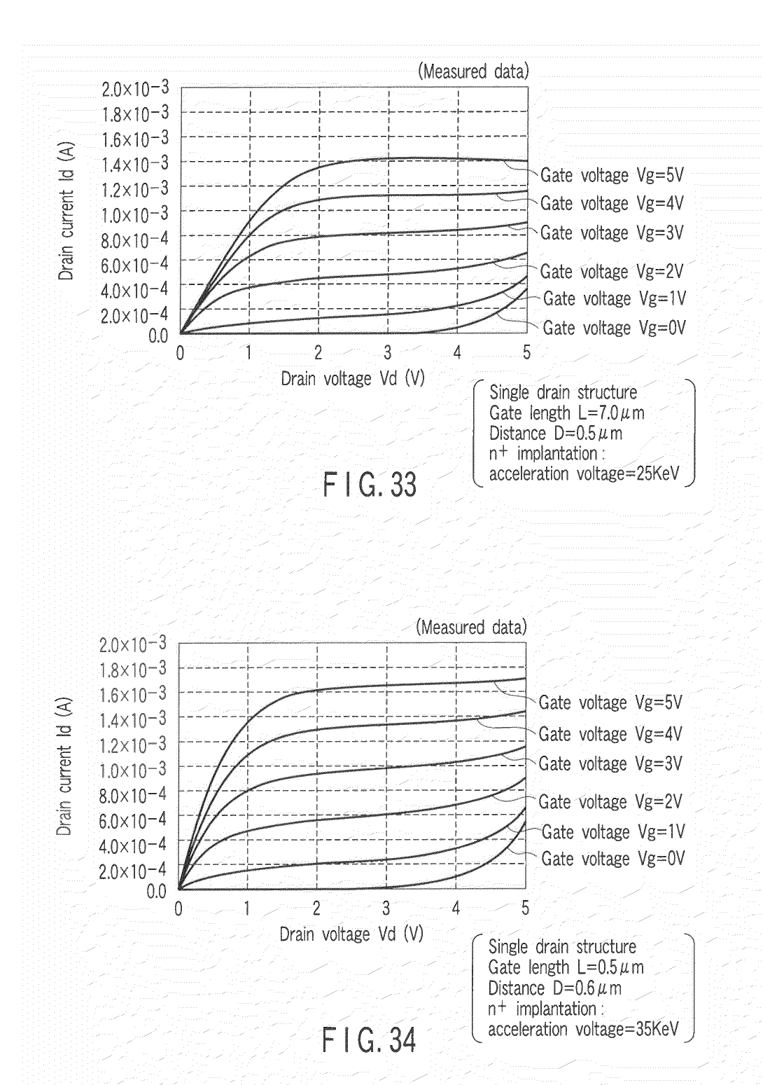

FIGS. 30 to 33 show drain current Id-drain voltage Vd characteristics which are obtained in the case where the distances D of 0.6 μm, 2.0 μm, 4.0 μm, and 7.0 μm are applied to a moderate junction obtained at the n⁺ ion implanting acceleration voltage of 25 KeV. In each case, the gate length L is set at 0.5 μm. In the moderate junction, it is also found that, when the distance D is 7.0 μm, the inclination of the characteristic curve becomes significantly small due to the parasitic capacitance corresponding to the distance D. Accordingly, the distance D is set at 4 μm or less, preferably 1 μm or less.

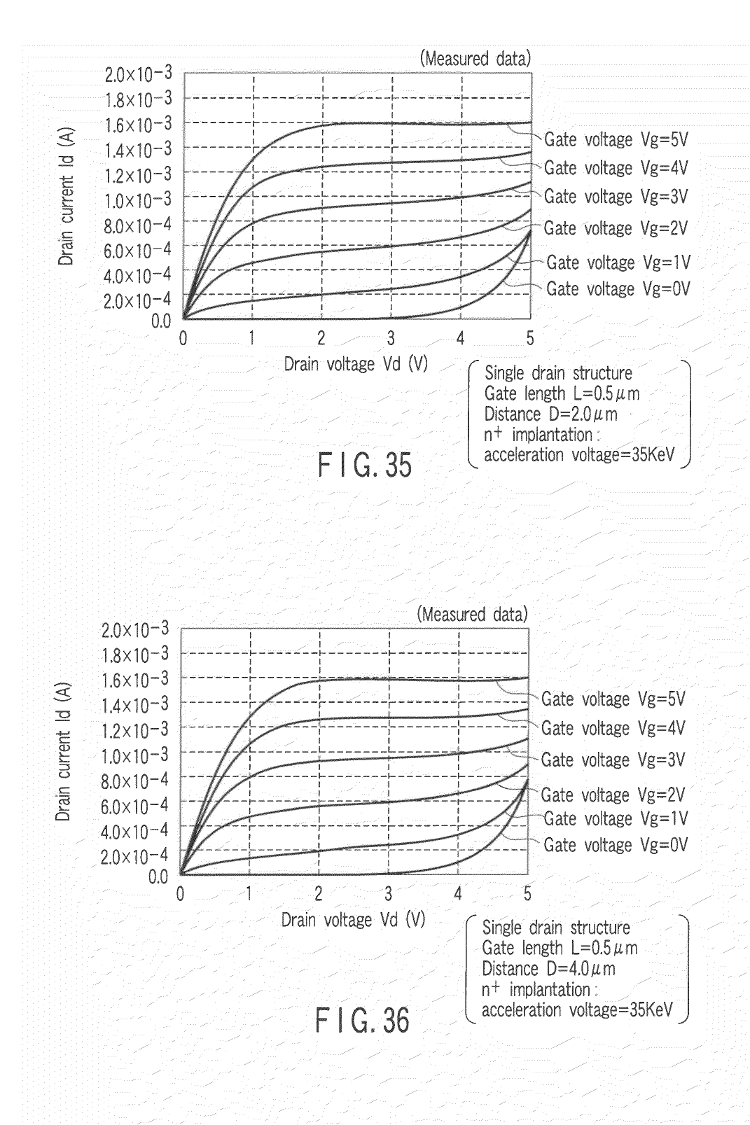

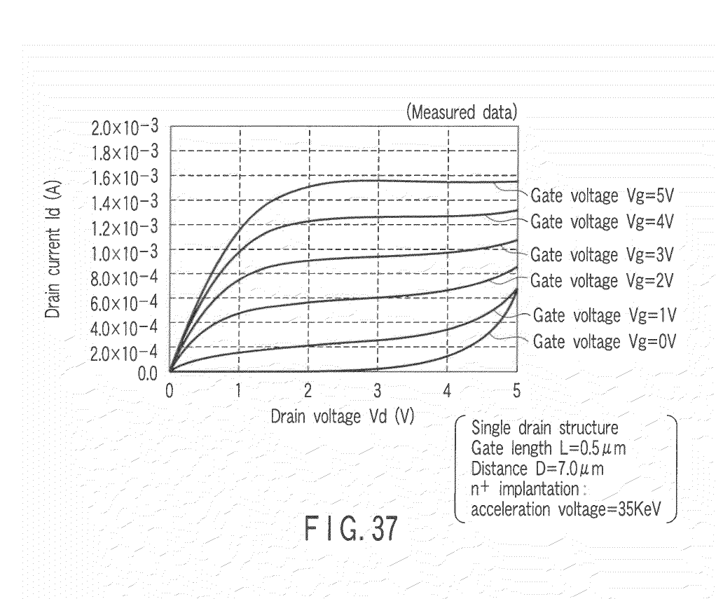

FIGS. 34 to 37 show drain current Id-drain voltage Vd characteristics which are obtained in the case where the distances D of 0.6 μm, 2.0 μm, 4.0 μm, and 7.0 μm are applied to a deep junction obtained at the n⁺ ion implanting acceleration voltage of 35 KeV. In each case, the gate length L is set at 0.5 μm. In the deep junction, it is found that the parasitic capacitance has a small influence even in the case of distance D=7.0 μm. However, good characteristics cannot be obtained for the source-drain breakdown voltage.

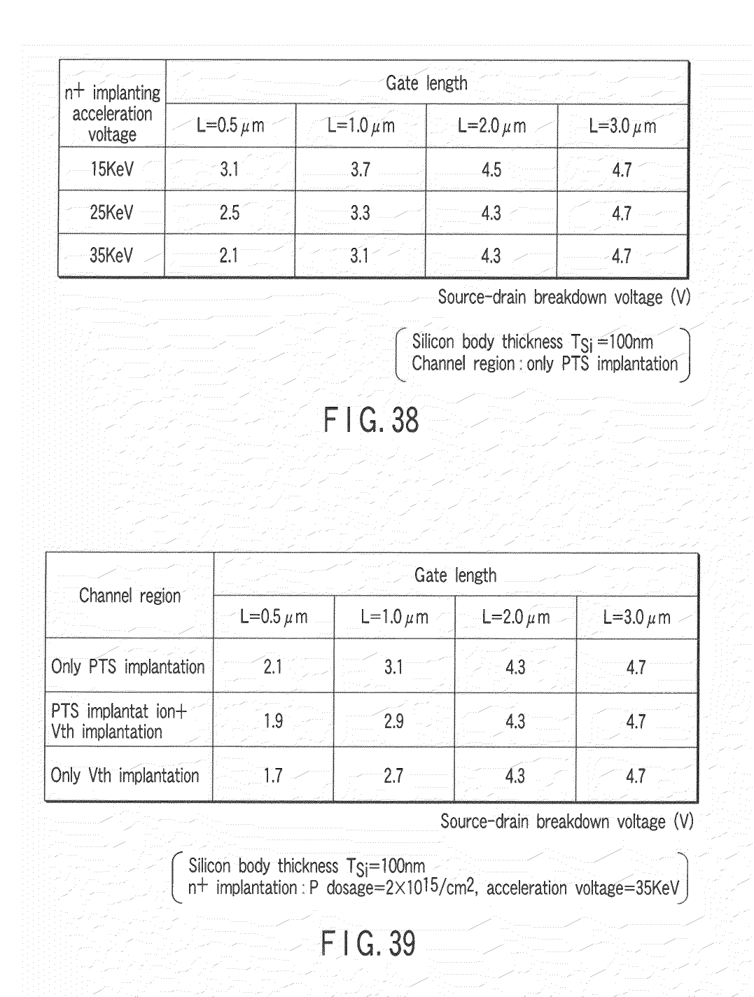

FIG. 38 shows an influence of the n⁺ implanting acceleration voltage and gate length L on the source-drain breakdown voltage BV in the thin-film transistor having the single drain structure. The results of FIG. 38 were obtained under the following conditions: silicon body thickness Tsi=100 nm, channel region: only PTS implantation is performed. In the case where the n⁺ implantation acceleration voltage is set at 15 KeV, the source-drain breakdown voltage BV becomes 3.1 V at L=0.5 μm, 3.7 V at L=1.0 μm, 4.5 V at L=2.0 μm, and 4.7 V at L=3.0 μm. In the case where the n⁺ implantation acceleration voltage is set at 25 KeV, the source-drain breakdown voltage BV becomes 2.5 V at L=0.5 μm, 3.3 V at L=1.0 μm, 4.3 V at L=2.0 μm, and 4.7 V at L=3.0 μm. In the case where the n⁺ implantation acceleration voltage is set at 35 KeV, the source-drain breakdown voltage BV becomes 2.1 V at L=0.5 μm, 3.1 V at L=1.0 μm, 4.3 V at L=2.0 μm, and 4.7 V at L=3.0 μm. FIG. 39 shows an influence of channel implantation conditions and the gate length L on the source-drain breakdown voltage BV in the thin-film transistor having the single drain structure. The results of FIG. 39 were obtained under the following conditions: silicon body thickness Tsi=100 nm, n⁺ implantation: P dosage=2×10¹⁵/cm², and acceleration voltage=35 KeV. In the case where only the PTS implantation is performed in the channel region, the source-drain breakdown voltage BV becomes 2.1 V at L=0.5 μm, 3.1 V at L=1.0 μm, 4.3 V at L=2.0 μm, and 4.7 V at L=3.0 μm. In the case where the PTS implantation and the Vth implantation are performed in the channel region, the source-drain breakdown voltage BV becomes 1.9 V at L=0.5 μm, 2.9 V at L=1.0 μm, 4.3 V at L=2.0 μm, and 4.7 V at L=3.0 μm. In the case where only the Vth implantation is performed in the channel region, the source-drain breakdown voltage BV becomes 1.7 V at L=0.5 μm, 2.7 V at L=1.0 μm, 4.3 V at L=2.0 μm, and 4.7 V at L=3.0 μm. As can be seen from FIGS. 38 and 39, in the case where the gate length L exceeds 1 μm, the effect of large improvement in the source-drain breakdown voltage BV cannot be expected even if the n⁺ junction is shallowed. In other words, the source-drain breakdown voltage BV is effectively improved by setting the gate length L at 1 μm or less.

That the gate length L is not more than 1 μm can be confirmed by measurement with a laser microscope, an ultraviolet microscope, or an optical microscope. In the thin-film transistor in which the distance from the inside end of the contact portion (contact hole) of the drain electrode 18D to the junction between the channel region 12C and the drain region 12D is not more than 4 μm, the high source-drain breakdown voltage can be obtained by setting the source region 12S and the drain region 12D at the above-described impurity concentration profiles.

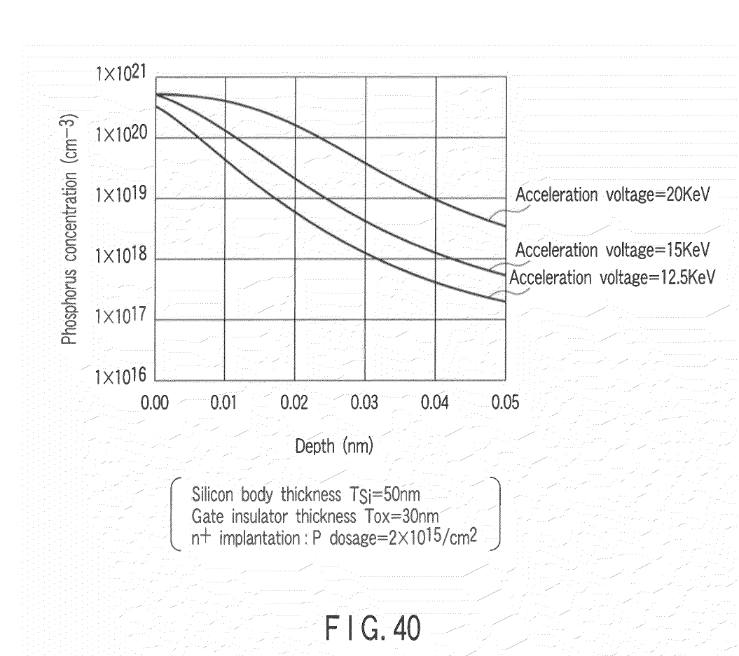

The case in which the thin-film transistor has the silicon body thickness Tsi of 50 nm will supplementarily be described below. FIG. 40 shows an influence of the acceleration voltage of the ion implantation apparatus, which performs the phosphorus (P) ion implantation, on the impurity profile of the n⁺ region such as the source region 12S and the drain region 12D. The results of FIG. 40 were obtained under the following measurement conditions: gate insulator thickness Tox=30 nm and n⁺ implantation: P dosage=2×10¹⁵/cm². At this point, the P ion implantation is performed such that the n⁺ implantation lowers the concentration of the portion away from the interface with the gate insulator 14 in the thickness direction, that is, the depth direction of the semiconductor thin film 12. When the simulation is performed for the n⁺ implantation, a different impurity profile is obtained for each acceleration voltage as shown in FIG. 40. In the case of the acceleration voltage of 20 KeV, the phosphorus concentration near the insulating support substrate 10 is lower than the phosphorus concentration near the gate insulator 14 by two digits, that is, by a factor of about 100. In the case of the acceleration voltage of 12.5 KeV, the phosphorus concentration near the insulating support substrate 10 is lower than the phosphorus concentration near the gate insulator 14 by three digits, that is, by a factor of about 1000.

For example, the impurity concentration profiles of the source region 12S and the drain region 12D can be measured with the secondary ion mass spectrometer.

When the silicon body thickness Tsi is decreased to 50 nm, the effect of the improvement in the source-drain breakdown voltage BV by the shallow junction can be confirmed though not to the extent of the silicon body thickness Tsi of 100 nm.

The channel implanting acceleration voltage is selected as a value suitable for the case in which the gate insulator is fixed at 30 nm. When the gate insulator 14 is thinned, the same effect is obtained, because basically the channel region 12C can have the same impurity concentration profile by lowering the acceleration voltage.

The invention is not limited to the first embodiment, and various modifications can be made without departing from the scope of the invention.

The first embodiment is applied to the high-quality semiconductor thin film having the large-grain crystallized region as the semiconductor thin film whose source-drain breakdown voltage is lower than that of the thin-film transistor formed in a polysilicon semiconductor thin film. Alternatively, the thin-film transistor may be formed of polysilicon, which has relatively good source-drain breakdown voltage characteristics. In this case, the support body of the thin-film transistor has an insulating support substrate such as a glass substrate, a substrate in which the underlying insulating layer is provided on the substrate, and an SOI substrate in which the insulating surface is provided on the support substrate.

The insulating support substrate 10 is not limited to the insulating substrate of which the entire substrate has the insulating property, but the insulating support substrate 10 may be formed by a semiconductor wafer or a metal plate in which a surface constituting the ground of the semiconductor thin film has the insulating property.

In the first embodiment, the n-channel type thin-film transistor is used as shown in FIG. 7. However, a similar effect is obtained in the p-channel type thin-film transistor.

The impurity profile of the n⁺ drain region 12D is set to substantially the same impurity profile of the n⁺ source region 12S because the production process does not become complicated. Alternatively, the impurity profile of the n⁺ drain region 12D may be set independently of that of the n⁺ source region 12S.

An n-channel type thin-film transistor having an LDD structure according to a second embodiment of the invention will be described below with reference to the accompanying drawings. The thin-film transistor of the second embodiment is used to form a pixel switch and a drive circuit in which the high source-drain breakdown voltage is required, for example, in a display panel of an active matrix liquid crystal display apparatus.

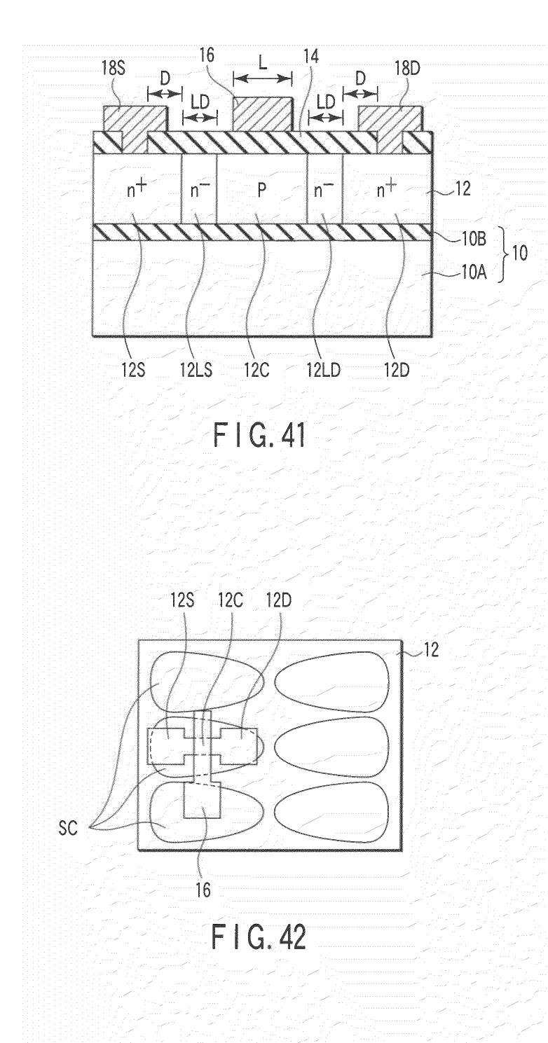

FIG. 41 shows a sectional structure of the n-channel type thin-film transistor having the LDD structure. The thin-film transistor includes the insulating support substrate 10, the semiconductor thin film 12, the gate insulator 14, and the gate electrode layer 16. The semiconductor thin film 12 has the thickness of about 30 to 200 nm, and is disposed on the insulating surface of the insulating support substrate 10. The semiconductor thin film 12 is covered with the gate insulator 14 having the thickness of, for example, about 30 nm. The gate electrode layer 16 having the thickness of, for example, about 200 nm is formed on the semiconductor thin film 12 with the gate insulator 14 interposed therebetween. The semiconductor thin film 12 includes the channel region 12C, the source region 12S, the drain region 12D, an LDD region 12LD, and an LDD region 12LS. The channel region 12C is disposed below the gate electrode layer 16. The source region 12S and the drain region 12D are disposed on both sides of the channel region 12C. The LDD region 12LD is disposed between the channel region 12C and the drain region 12D. The LDD region 12LS is disposed between the source region 12S and the channel region 12C. The source electrode 18S and the drain electrode 18D are connected to the source region 12S and the drain region 12D through the pair of contact holes made in the gate insulator 14. The channel region 12C is a region which is used to move the carrier such as the electron and the hole between the source region 12S and the drain region 12D, and the movement of the carrier is controlled by the electric field corresponding to the gate voltage applied to the gate electrode layer 16. Each of the source region 12S and the drain region 12D is an n⁺-type impurity region containing the n-type impurity such as phosphorus (P), each of the LDD regions 12LS and 12LD is an n⁻-type impurity region containing the n-type impurity such as phosphorus (P) whose amount is lower than that in each of the source region 12S and the drain region 12D, and the channel region 12C is a p-type impurity region containing the p-type impurity such as boron (B). The gate electrode layer 16 has the gate length L not more than 1 μm, for example, 0.5 μm along the channel between the source region 12S and the drain region 12D. Each of the LDD regions 12LS and 12LD has an LDD length LD of 0.2 μm. The gate electrode layer 16 is formed by a MoW metal film. The gate insulator 14 is made of an oxide such as silicon dioxide (SiO₂), and electrically insulates the gate electrode layer 16 from the channel region 12C in order to make the thin-film transistor serve as the field effect transistor.

The insulating substrate 10A made of a material such as glass, fused quartz, sapphire, plastic, or polyimide can be used as the insulating support substrate 10. In the second embodiment, the glass substrate is used as the insulating substrate 10A, which is covered with the underlying insulating layer 10B constituting a ground of the semiconductor thin film 12. The semiconductor thin film 12 is formed by the single-crystal silicon grain film. The amorphous silicon film is deposited on the underlying insulating layer 10B, and the amorphous silicon film is melt-recrystallized to obtain the single-crystal silicon grain film by the phase-modulated excimer laser crystallization method. In the phase-modulated excimer laser crystallization method, the amorphous silicon film is irradiated with the excimer laser beam whose intensity is spatially modulated using the phase shifter which modulates the phase of the incident light beam to emit the light beam with the light intensity distribution having the reverse peak shape. In the phase-modulated excimer laser crystallization method, the excimer laser is set to the light intensity distribution on the semiconductor thin film 12 according to the phase shifter, and generates the temperature gradient in the semiconductor thin film 12 according to the light intensity distribution. The light intensity distribution includes continuous triangular light intensity distributions. The region irradiated with the excimer laser beam is melted in the semiconductor thin film 12. A crystal is grown in the period during which the excimer laser beam is interrupted. The temperature gradient promotes the growth of the single-crystal silicon grain SC from the lower temperature portion toward the higher temperature portion in the lateral direction parallel to the plain of the semiconductor thin film 12. As a result, as shown in FIG. 42, the single-crystal silicon grain SC is grown to the grain having the diameter of several micrometers in which at least one thin-film transistor can be accommodated. Desirably the thin-film transistor is formed such that electrons or holes are moved toward the crystal growth direction in which the single-crystal silicon grain SC is grown. FIG. 42 shows the shape of the single-crystal silicon grain SC. In the semiconductor thin film 12, the MESA etching is performed during the production process such that only the island portion including the source region 12S, the drain region 12D, and the channel region 12C is left. The whole of the channel region 12C is disposed within the single-crystal silicon grain SC.

The semiconductor thin film 12 may directly be formed on the insulating substrate 10A while the underlying insulating layer 10B is not interposed therebetween. The semiconductor thin film 12 may be formed by a semiconductor wafer in which SOI (Semiconductor On Insulator) structure substrate is formed by bonding the semiconductor wafer to the insulating substrate. The semiconductor thin film 12 may include semiconductor such as silicon (Si) and silicon-germanium (SiGe). The threshold voltage of the thin-film transistor depends on the impurity concentration of the channel region 12C, and the current driving performance of the thin-film transistor depends on the gate length.

The channel region 12C has the impurity concentration profile in which the impurity concentration is increased from the interface with the gate insulator 14 toward the interface with the insulating support substrate 10 in the thickness direction of the semiconductor thin film 12. The source region 12S and the drain region 12D have the impurity concentration profiles in which the impurity concentrations are decreased from the interface with the gate insulator 14 toward the interface with the insulating support substrate 10 in the thickness direction of the semiconductor thin film 12. The LDD region 12LD and the LDD region 12LS have impurity concentration profiles in which the impurity concentrations are decreased from the interface with the gate insulator 14 toward the interface with the insulating support substrate 10 in the thickness direction of the semiconductor thin film 12. In the impurity concentration profiles of the source region 12S and drain region 12D, desirably the impurity concentration near the insulating support substrate 10 is lower than the impurity concentration near the gate insulator 14 by two digits or more, that is, by a factor of 100 or more. Additionally, in the impurity concentration profiles of the LDD region 12LD and the LDD region 12LS, desirably the impurity concentration near the insulating support substrate 10 is lower than the impurity concentration near the gate insulator 14 by three digits or more, that is, by a factor of 1000 or more. However, another impurity concentration profile than that described above may be provided for the channel region 12C, the drain region 12D, and the LDD region 12LS.

In the conventional n-channel type thin-film transistor in which the electron is used as the carrier, there is the problem that the thin-film transistor has the low source-drain breakdown voltage while the high mobility characteristics can be obtained. On the other hand, in the n-channel type thin-film transistor of the second embodiment shown in FIG. 41, the high breakdown voltage is realized by decreasing the impurity concentration near the insulating support substrate 10 by a factor of 100 or more with respect to the impurity concentration near the gate insulator 14 in the impurity concentration profiles of the source region 12S and drain region 12D. In the n-channel type thin-film transistor of the second embodiment, the high breakdown voltage is realized by decreasing the impurity concentration near the insulating support substrate 10 by a factor of 100 or more, preferably 1000 or more with respect to the impurity concentration near the gate insulator 14 in the impurity concentration profile of the LDD region 12LD.

For example, the impurity concentration profiles of the source region 12S, the drain region 12D, and the LDD regions 12LS and 12LD can be measured with the secondary ion mass spectrometer.

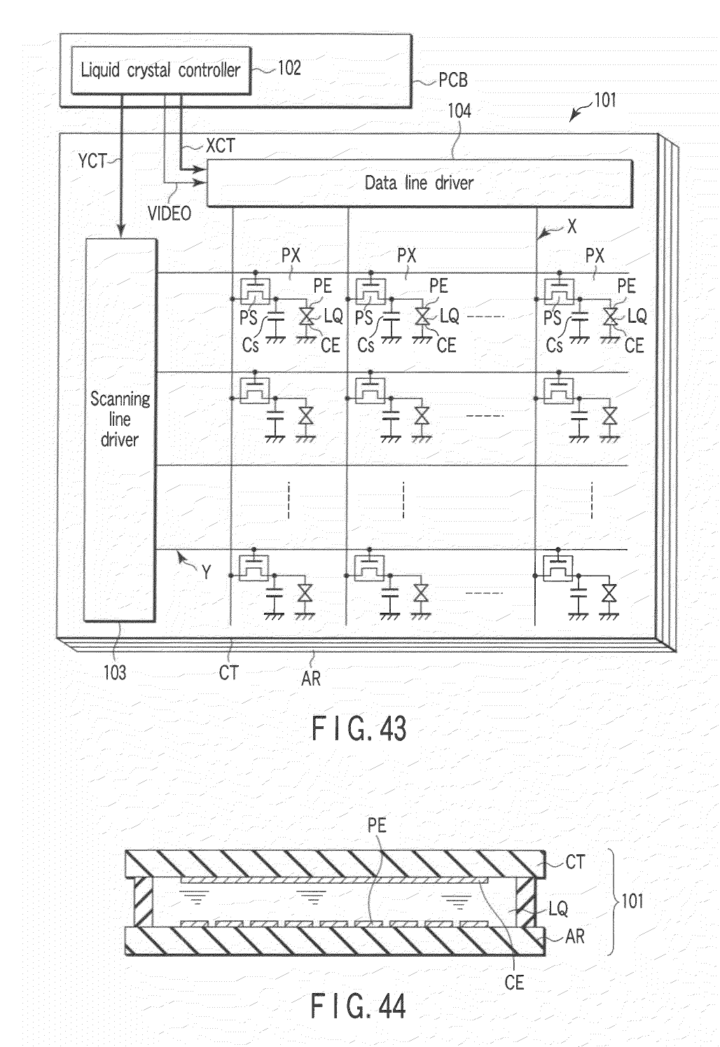

FIG. 43 shows a schematic circuit configuration of a liquid crystal display apparatus in which the thin-film transistor is used, and FIG. 44 shows a schematic sectional structure of the liquid crystal display apparatus.

The liquid crystal display apparatus includes the liquid crystal display panel 101 and the liquid crystal controller 102 which controls the liquid crystal display panel 101. The liquid crystal display panel 101 has the structure in which the liquid crystal layer LQ is retained between the array substrate AR and the counter substrate CT. The liquid crystal controller 102 is disposed on the drive circuit board PCB which is independent of the liquid crystal display panel 101.

The liquid crystal display panel 101 includes the plural display pixels PX which are disposed in a matrix, the plural scanning lines Y which are disposed along each row of the plural display pixels PX, the plural data lines X which are disposed along each column of the plural display pixels PX, the plural pixel switches PS, the scanning line driver 103 which drives the plural scanning lines Y, and the data line driver 104 which drives the plural data lines X. Each of the plural pixel switches PS is disposed near the crossing point of the data line X and the scanning line Y, takes in a data signal from one data line X in response to the gate pulse from one scanning line Y, and supplies the data signal to one display pixel PX. The plural scanning lines Y, the plural data lines X, the pixel switches PX, the scanning line driver 103, and the data line driver 104 are formed on the array substrate AR. Each of the display pixels PX includes one of plural pixel electrodes PE formed on the array substrate AR, the single common electrode CE, a part of the liquid crystal layer LQ, and the auxiliary capacitance Cs. The common electrode CE is formed on the counter electrode CT while facing the plural pixel electrodes PE, and is set at a common potential. The part of the liquid crystal layer LQ is located between the pixel electrode PE and the common electrode CE. The auxiliary capacitance Cs is formed on the array substrate AR, and is connected in parallel with the liquid crystal capacitance between the pixel electrode PE and the common electrode CE. The auxiliary capacitance Cs retains the voltage of the data signal supplied from the pixel switch PX, and applies the voltage of the data signal to the pixel electrode PE. The transmittance of the display pixel PX is controlled by the potential difference between the pixel electrode PE and the common electrode CE.

The liquid crystal controller 102 receives the digital video signal VIDEO and the synchronous signal which are supplied from the outside, and generates the vertical scanning control signal YCT and the horizontal scanning control signal XCT. The vertical scanning control signal YCT is supplied to the scanning line driver 103, and the horizontal scanning control signal XCT is supplied to the data line driver 104 along with the video signal VIDEO. The scanning line driver 103 is controlled by the vertical scanning control signal YCT, and sequentially supplies the gate pulses to the plural scanning lines Y during one vertical scanning (frame) period. The gate pulse is supplied to each scanning line Y only during one horizontal scanning period (1H). The data line driver 104 is controlled by the horizontal scanning control signal XCT, and performs the serial-parallel conversion and digital-analog conversion of the video signal VIDEO to supply the one-row data signal to each of the plural data lines X. The video signal VIDEO is fed during the horizontal scanning period in which the one scanning line Y is driven by the gate pulse. Each of the pixel switch PS, the scanning line driver 103, and the data line driver 104 is formed with the thin-film transistor having the structure of FIG. 41.

The simulation results obtained by the thin-film transistor having the LDD structure of FIG. 41 will be described below.

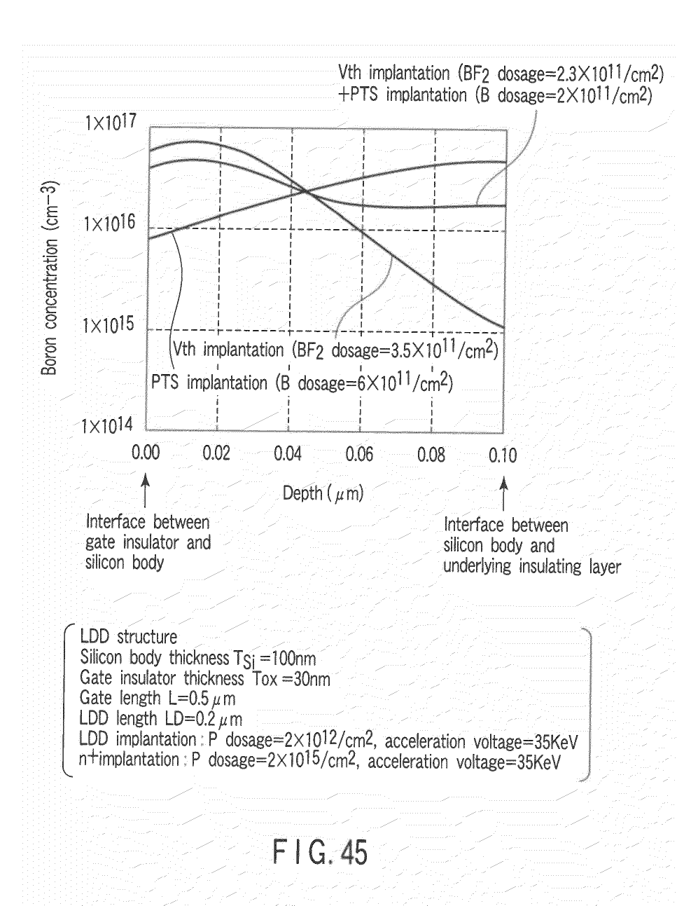

FIG. 45 shows an influence of boron (B) ion implantation conditions on the impurity profile of the channel region 12C in the LDD structure. Similarly to the first embodiment, the Vth implantation is an implantation method for performing the ion implantation of BF₂ to control the threshold voltage of the thin-film transistor. The PTS (Punch Through Stop) implantation is an implantation method in which the ion implantation of B is performed to increase a concentration of a portion away from the interface with the gate insulator 14 in the thickness direction, that is, the depth direction of the semiconductor thin film 12, whereby the resistance of the portion is lowered to prevent the accumulation of the impact ions. Different impurity profiles are obtained as shown in FIG. 45, when the simulations are performed for the case where only the Vth implantation is performed, the case where both the Vth implantation and the PTS implantation are performed, and the case where only the PTS implantation is performed. The results of FIG. 45 are obtained by the following measurement conditions: Vth implantation: BF₂ dosage=3.5×10¹¹/cm², PTS implantation: B dosage=6×10¹¹/cm², Vth implantation+PTS implantation: (BF₂ dosage=2.3×10¹¹/cm²)+(B dosage=2×10¹¹/cm²), silicon body thickness Tsi=100 nm, gate length L=0.5 μm, LDD length LD=0.2 μm, LDD implantation: P dosage=2×10¹²/cm², acceleration voltage=35 KeV; n⁺ implantation: P dosage=2×10¹⁵/cm², and acceleration voltage=35 KeV.

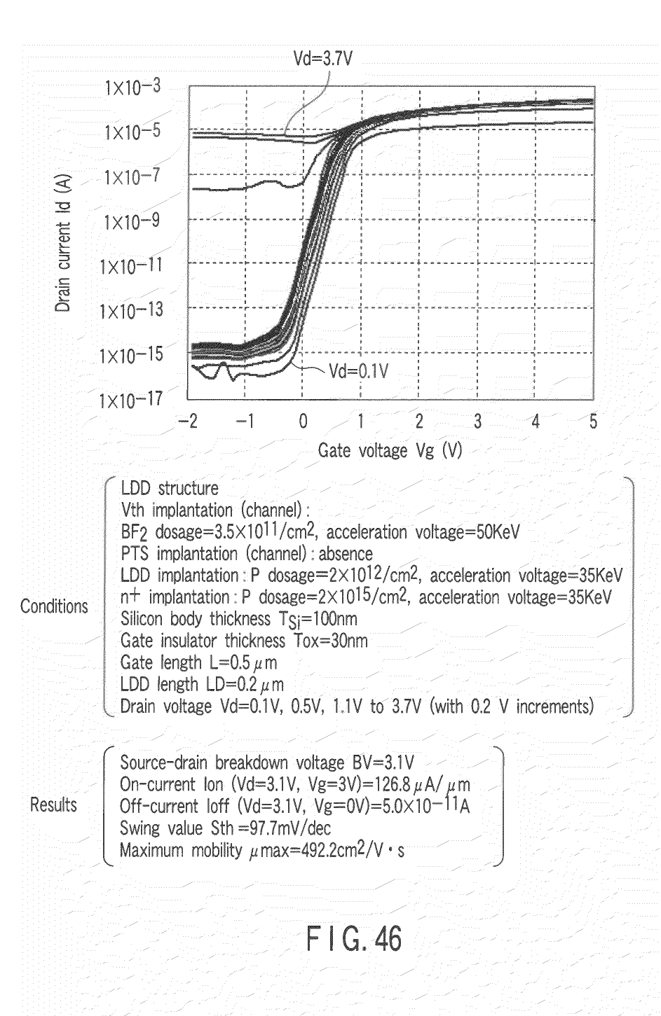

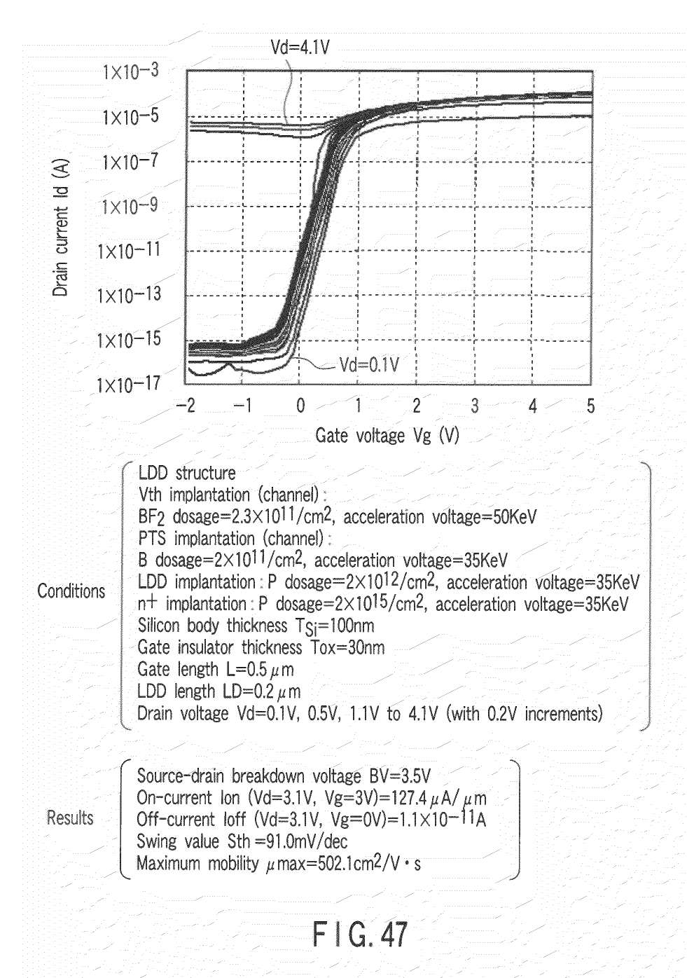

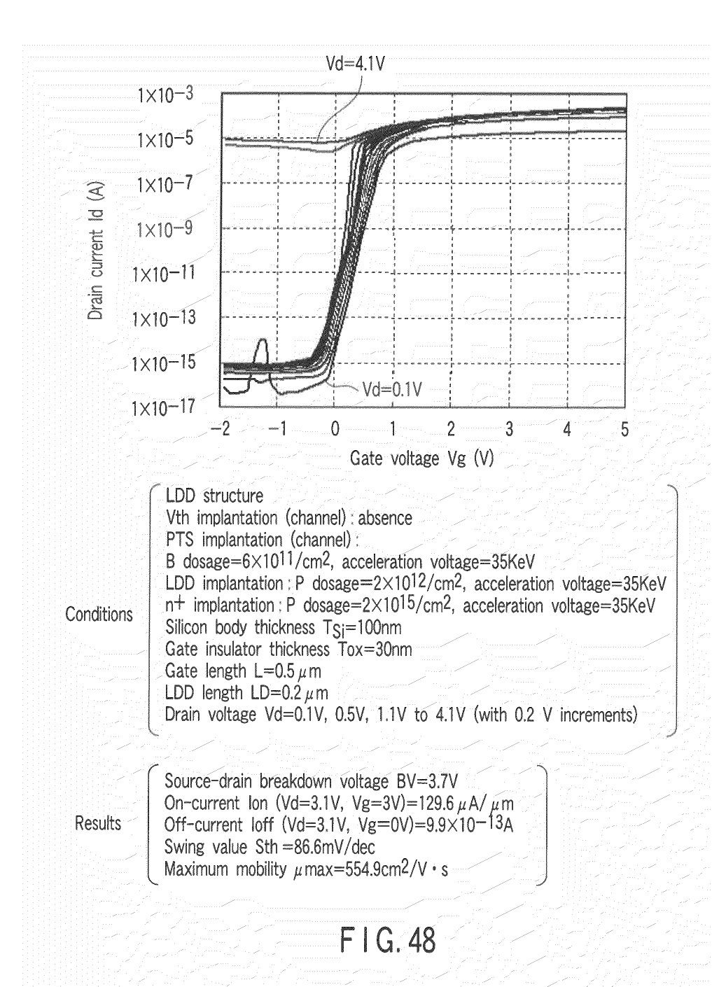

FIGS. 46 to 48 show gate voltage Vg-drain current Id characteristics in the case where only the Vth implantation is performed, in the case where both the Vth implantation and the PTS implantation are performed, and in the case where only the PTS implantation is performed. The results of FIG. 46 were obtained under the following measurement conditions: Vth implantation (channel): BF₂ dosage=3.5×10¹¹/cm², acceleration voltage=50 KeV; PTS implantation (channel): absence; LDD implantation: P dosage=2×10¹²/cm², acceleration voltage=35 KeV; n⁺ implantation: P dosage=2×10¹⁵/cm², acceleration voltage=35 KeV; silicon body thickness Tsi=100 nm, gate insulator thickness Tox=30 nm, gate length L=0.5 μm, LDD length LD=0.2 μm, drain voltage Vd=0.1 V, 0.5 V, and 1.1 V to 3.7 V (with 0.2 V increments). In this case, the following results were obtained: source-drain breakdown voltage BV=3.1 V, on-current Ion (Vd=3.1 V and Vg=3 V)=126.8 μA/μm, off-current Ioff (Vd=3.1 V and Vg=0 V)=5×10⁻¹¹ A, swing value Sth=97.7 mV/dec, and maximum mobility μmax=492.2 cm²/V·s. The results of FIG. 47 were obtained under the following measurement conditions: Vth implantation (channel): BF₂ dosage=2.3×10¹¹/cm², acceleration voltage=50 KeV; PTS implantation (channel): B dosage=2×10¹¹/cm², acceleration voltage=35 KeV; LDD implantation: P dosage=2×10¹²/cm², acceleration voltage=35 KeV; n⁺ implantation: P dosage=2×10¹⁵/cm², acceleration voltage=35 KeV; silicon body thickness Tsi=100 nm, gate insulator thickness Tox=30 nm, gate length L=0.5 μm, LDD length LD=0.2 μm, drain voltage Vd=0.1 V, 0.5 V, and 1.1 V to 4.1 V (with 0.2 V increments). In this case, the following results were obtained: source-drain breakdown voltage BV=3.5 V, on-current Ion (Vd=3.1 V and Vg=3 V)=127.4 μA/μm, off-current Ioff (Vd=3.1 V and Vg=0 V)=1.1×10⁻¹¹ A, swing value Sth=91.0 mV/dec, and maximum mobility μmax=502.1 cm²/V·s. The results of FIG. 48 were obtained under the following measurement conditions: Vth implantation (channel): absence; PTS implantation (channel): B dosage=6×10¹¹/cm², acceleration voltage=35 KeV; LDD implantation: P dosage=2×10¹²/cm², acceleration voltage=35 KeV; n⁺ implantation: P dosage=2×10¹⁵/cm², acceleration voltage=35 KeV; silicon body thickness Tsi=100 nm, gate insulator thickness Tox=30 nm, gate length L=0.5 μm, LDD length LD=0.2 μm, drain voltage Vd=0.1 V, 0.5 V, and 1.1 V to 4.1 V (with 0.2 V increments). In this case, the following results were obtained: source-drain breakdown voltage BV=3.7 V, on-current Ion (Vd=3.1 V and Vg=3 V)=129.6 μA/μm, off-current Ioff (Vd=3.1 V and Vg=0 V)=9.9×10⁻¹³ A, swing value Sth=86.6 mV/dec; and maximum mobility μmax=554.9 cm²/V·s. From these characteristics, the source-drain breakdown voltage BV becomes 3.1 V in the case where only the Vth implantation is performed, becomes 3.5 V in the case where both the Vth implantation and the PTS implantation are performed, and becomes 3.7 V in the case where only the PTS implantation is performed.

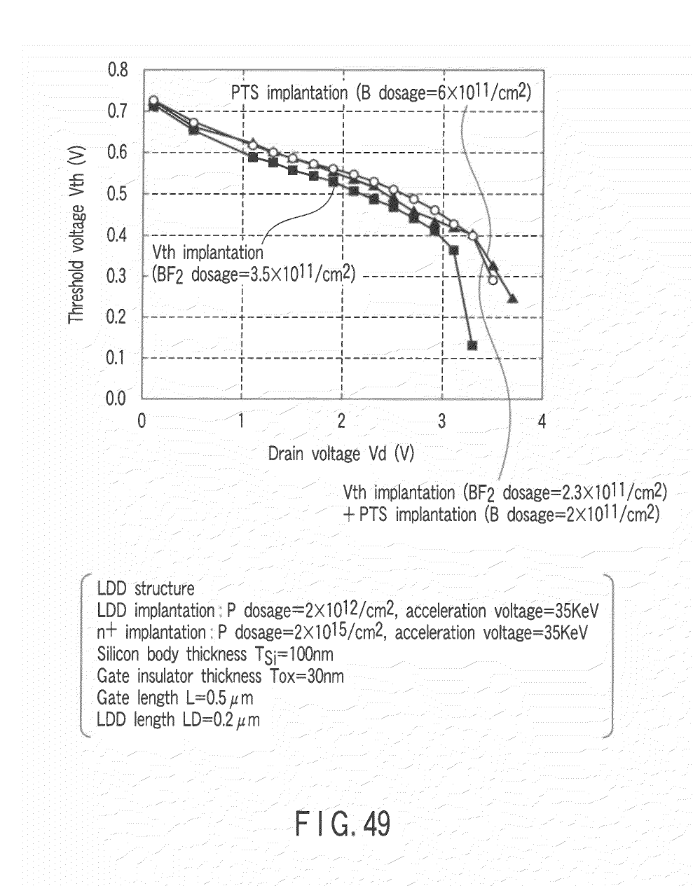

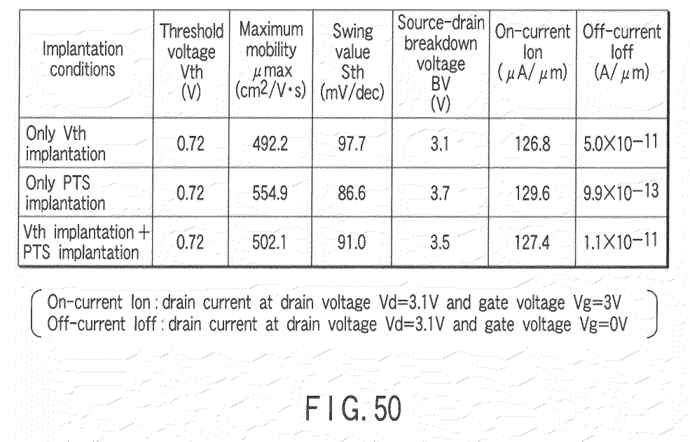

FIG. 49 shows an influence of boron (B) ion implantation conditions on dependence of the threshold voltage Vth on the drain voltage Vd. The results of FIG. 49 were obtained under the following measurement conditions: Vth implantation: BF₂ dosage=3.5×10¹¹/cm², PTS implantation: B dosage=6×10¹¹/cm², Vth implantation+PTS implantation: (BF₂ dosage=2.3×10¹¹/cm²)+(B dosage=2×10¹¹/cm²); LDD implantation: P dosage=2×10¹²/cm², acceleration voltage=35 KeV; n⁺ implantation: P dosage=2×10¹⁵/cm², acceleration voltage=35 KeV; silicon body thickness Tsi=100 nm, gate length L=0.5 μm, and LDD length LD=0.2 μm. At this point, each dosage, which is the detailed implantation condition, is adjusted such that substantially the same threshold voltage Vth is obtained in the case of the low drain voltage Vd (0.1 V in this case). The generation of the DIBL (Drain Induced Barrier Lowering) effect, in which the threshold voltage Vth is changed depending on the drain voltage Vd, is unavoidable in the thin-film transistor. As can be seen from FIG. 49, DIBL has the strongest influence in the case where only the Vth implantation is performed, and DIBL has little influence in both the case where the Vth implantation and the PTS implantation are performed and the case where only the PTS implantation is performed.

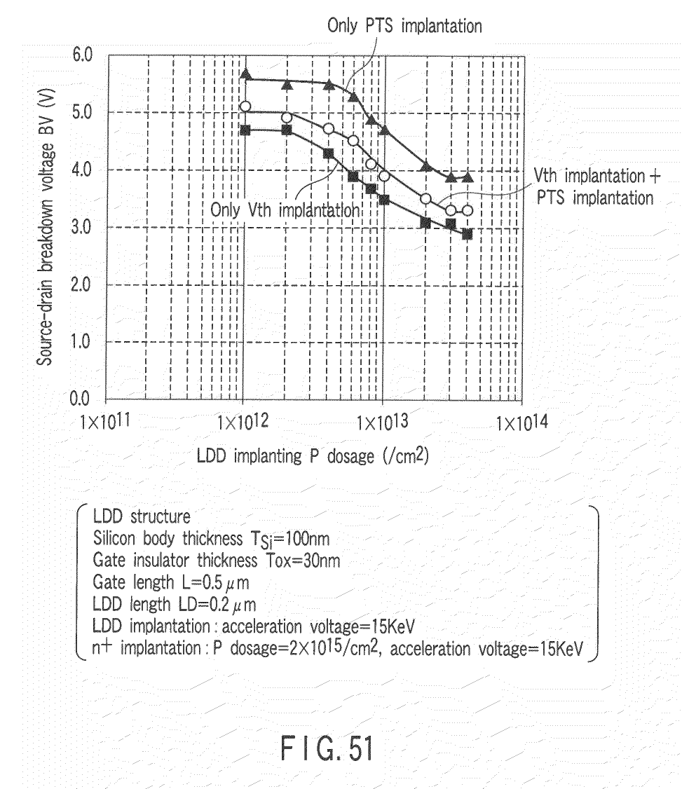

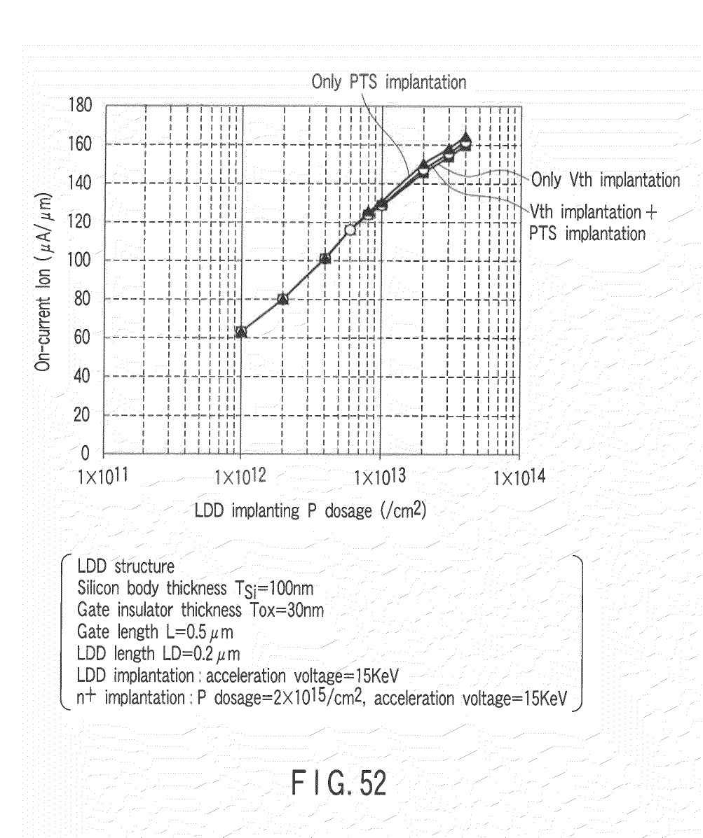

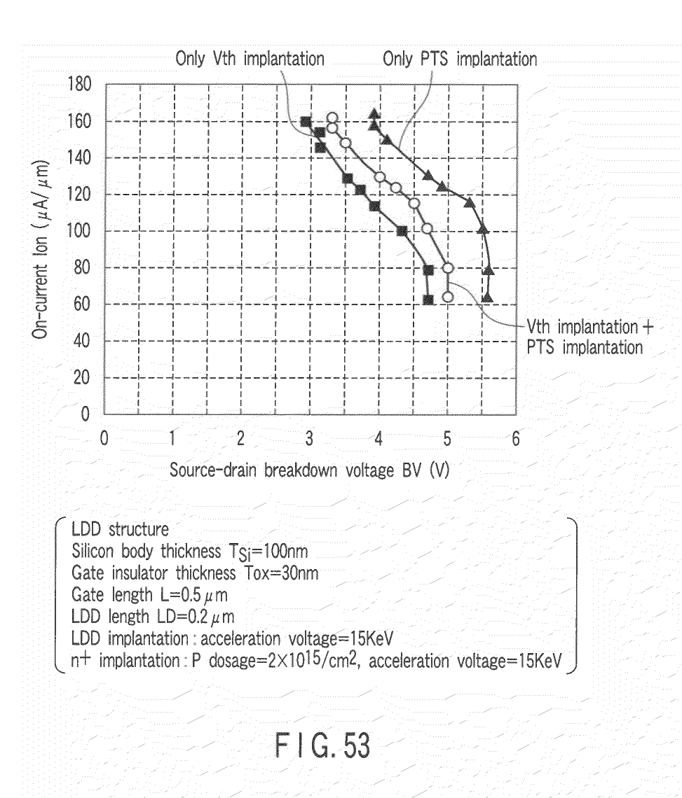

FIG. 50 shows a list of an influence of implantation conditions on the maximum mobility μmax, the swing value Sth, the source-drain breakdown voltage BV, the on-current Ion, and the off-current Ioff of the thin-film transistor. The implantation conditions are the acceleration voltage of the ion implantation apparatus. In the case of only the Vth implantation, the results were obtained as follows: source-drain breakdown voltage BV=3.1 V, on-current Ion (Vd=3.1 V and Vg=3 V)=126.8 μA/μm, off-current Ioff (Vd=3.1 V and Vg=0 V)=5.0×10⁻¹¹ A, swing value Sth=97.7 mV/dec, and maximum mobility μmax=492.2 cm²/V·s. In the case of only the PTS implantation, the results were obtained as follows: source-drain breakdown voltage BV=3.7 V, on-current Ion (Vd=3.1 V and Vg=3 V)=129.6 μA/μm, off-current Ioff (Vd=3.1 V and Vg=0 V)=9.9×10⁻¹³ A, swing value Sth=86.6 mV/dec, and maximum mobility μmax=554.9 cm²/V·s. In the case of the Vth implantation+PTS implantation, the results were obtained as follows: source-drain breakdown voltage BV=3.5 V, on-current Ion (Vd=3.1 V and Vg=3 V)=127.4 μA/μm, off-current Ioff (Vd=3.1 V and Vg=0 V)=1.1×10⁻¹¹ A; swing value Sth=91.0 mV/dec, and maximum mobility μmax=502.1 cm²/V·s. It is found from these results that the best maximum mobility μmax, swing value Sth, source-drain breakdown voltage BV, on-current Ion, and off-current Ioff are obtained in the case where only the PTS implantation is performed (FIGS. 50 to 53). FIG. 51 shows an influence of ion implantation conditions of the channel region 12C on a relationship between the source-drain breakdown voltage BV of the thin-film transistor and the LDD implanting phosphorus (P) dosage. FIG. 52 shows an influence of ion implantation conditions of the channel region 12C on a relationship between the on-current Ion of the thin-film transistor and the LDD implanting phosphorus (P) dosage. FIG. 53 shows an influence of ion implantation conditions of the channel region 12C on a relationship between the on-current Ion and source-drain breakdown voltage BV of the thin-film transistor. The results of FIGS. 51 to 53 were obtained under the following measurement conditions: silicon body thickness Tsi=100 nm, gate insulator thickness Tox=30 nm, gate length L=0.5 μm, LDD length LD=0.2 μm, LDD implantation: acceleration voltage=15 KeV, and n⁺ implantation: P dosage=2×10¹⁵/cm², acceleration voltage=15 KeV. It is found from these results that the source-drain breakdown voltage BV and the on-current Ion can be optimized in each impurity profile of the channel region 12C in the LDD structure. In the LDD structure, it is also found that the PTS implantation exerts the best source-drain breakdown voltage and on-current characteristics for the impurity profile of the channel region 12C.

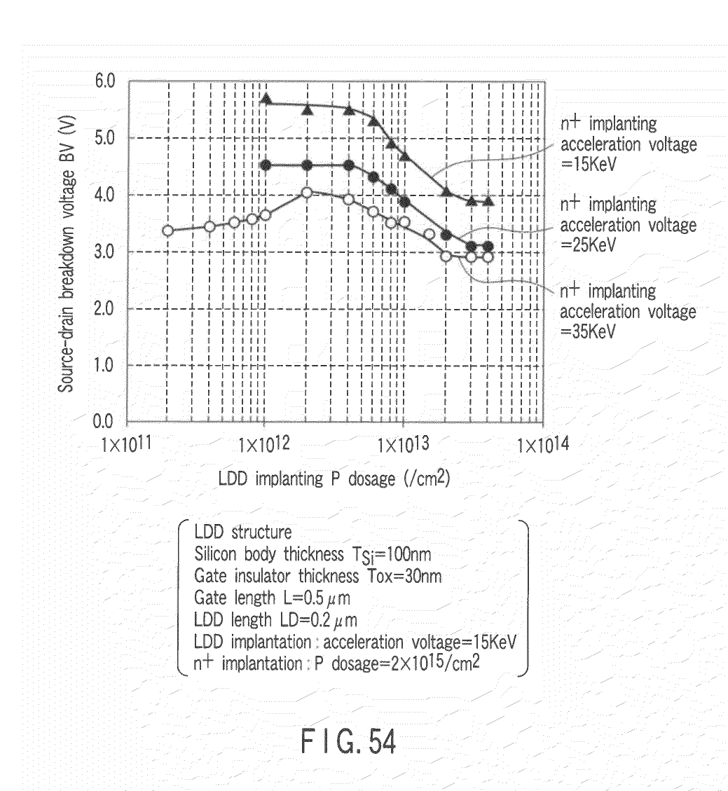

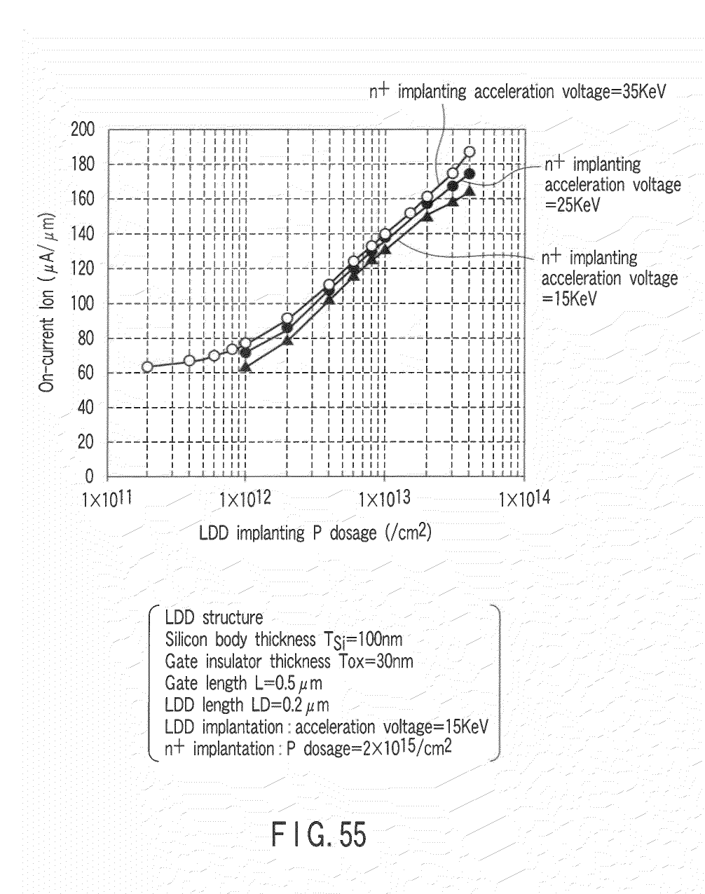

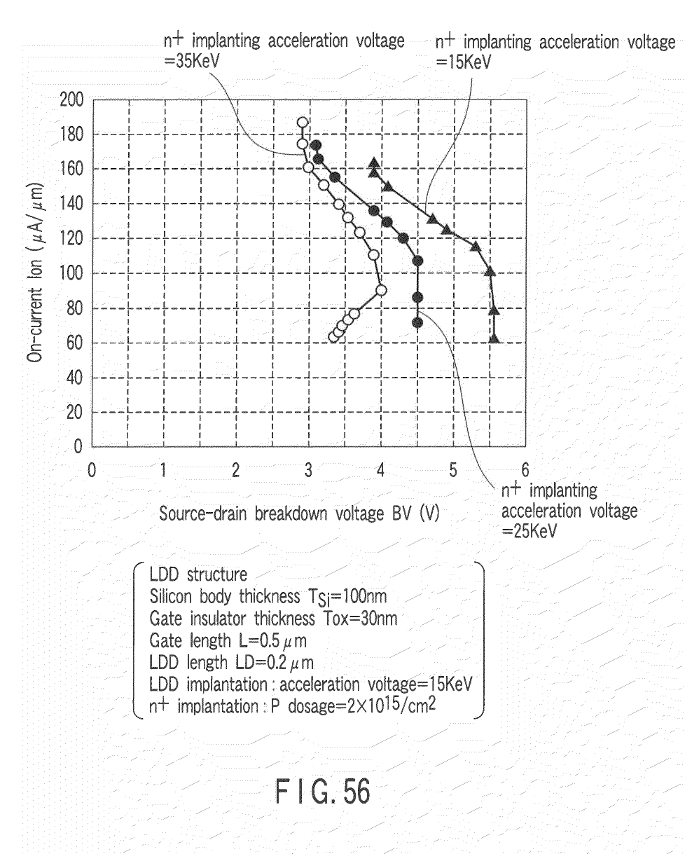

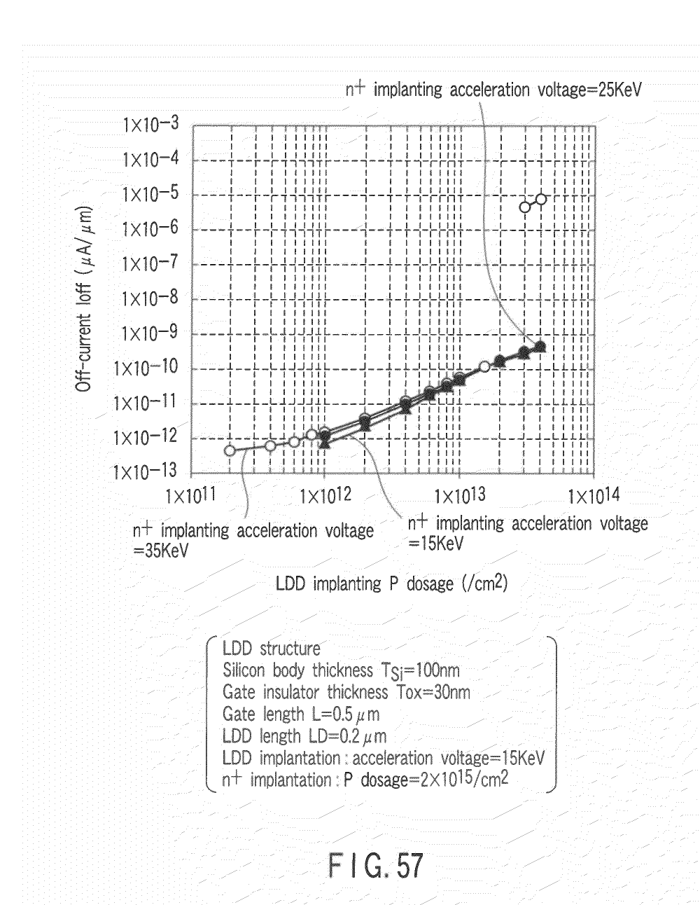

FIG. 54 shows an influence of the n⁺ implanting acceleration voltage on the relationship between the source-drain breakdown voltage BV of the thin-film transistor and the LDD implanting phosphorus (P) dosage. FIG. 55 shows an influence of the n⁺ implanting acceleration voltage on the relationship between the on-current Ion of the thin-film transistor and the LDD implanting phosphorus (P) dosage. FIG. 56 shows an influence of the n⁺ implanting acceleration voltage on the relationship between the on-current Ion of the thin-film transistor and the source-drain breakdown voltage BV. FIG. 57 is a view showing an influence of the n⁺ implanting acceleration voltage on a relationship between the off-current Ioff of the thin-film transistor and the LDD implanting phosphorus (P) dosage. The results of FIGS. 54 to 57 were obtained under the following measurement conditions: silicon body thickness Tsi=100 nm, gate insulator thickness Tox=30 nm, gate length L=0.5 μm, LDD length LD=0.2 μm, LDD implantation: acceleration voltage=15 KeV, and n⁺ implantation: P dosage=2×10¹⁵/cm². It is found from these results that the source-drain breakdown voltage BV, the on current Ion and the off-current Ioff can be optimized in each n⁺ implanting acceleration voltage in the LDD structure. In the LDD structure, it is also found that the n⁺ implanting acceleration voltage is decreased to form the impurity concentration profile which is decreased from the interface with the gate insulator toward the interface with the insulating support substrate in the thickness direction of the semiconductor thin film, thereby exerting the best source-drain breakdown voltage and on-current characteristics.

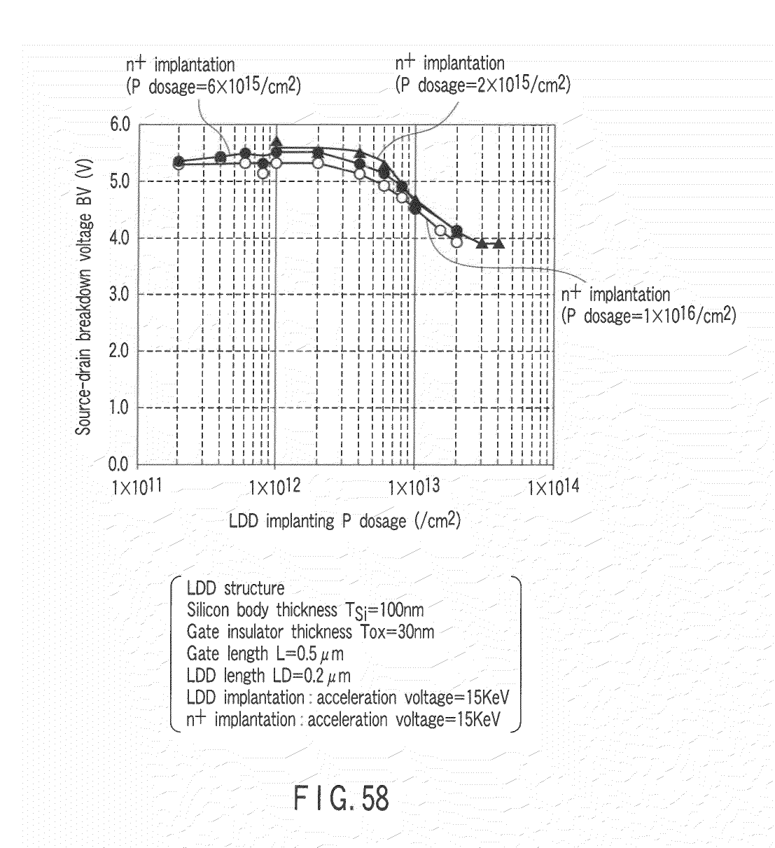

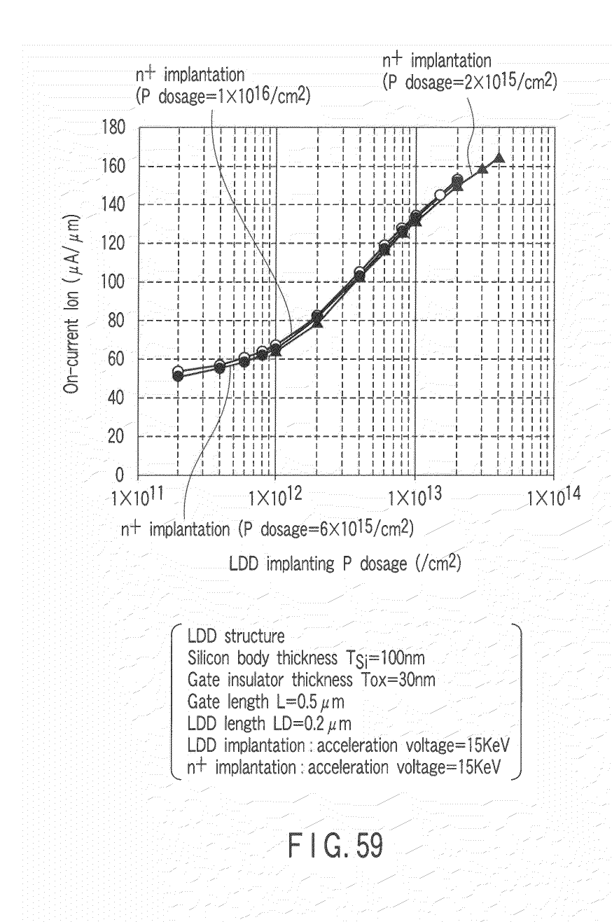

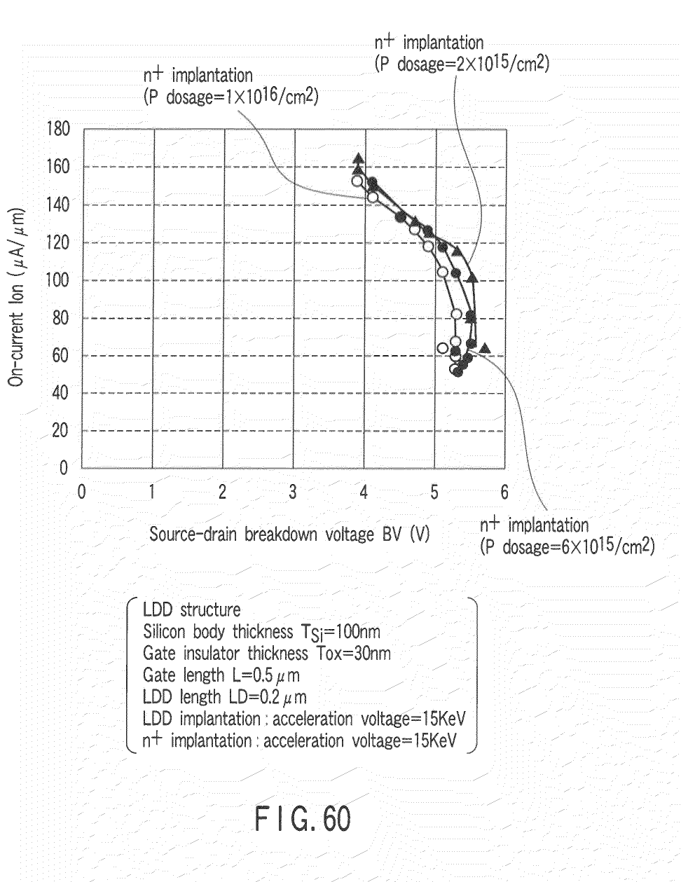

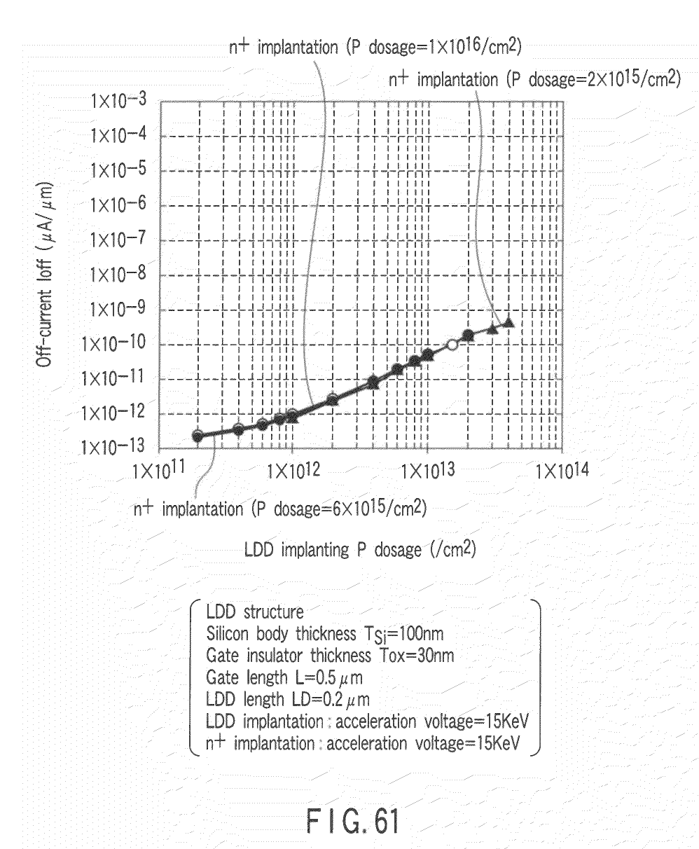

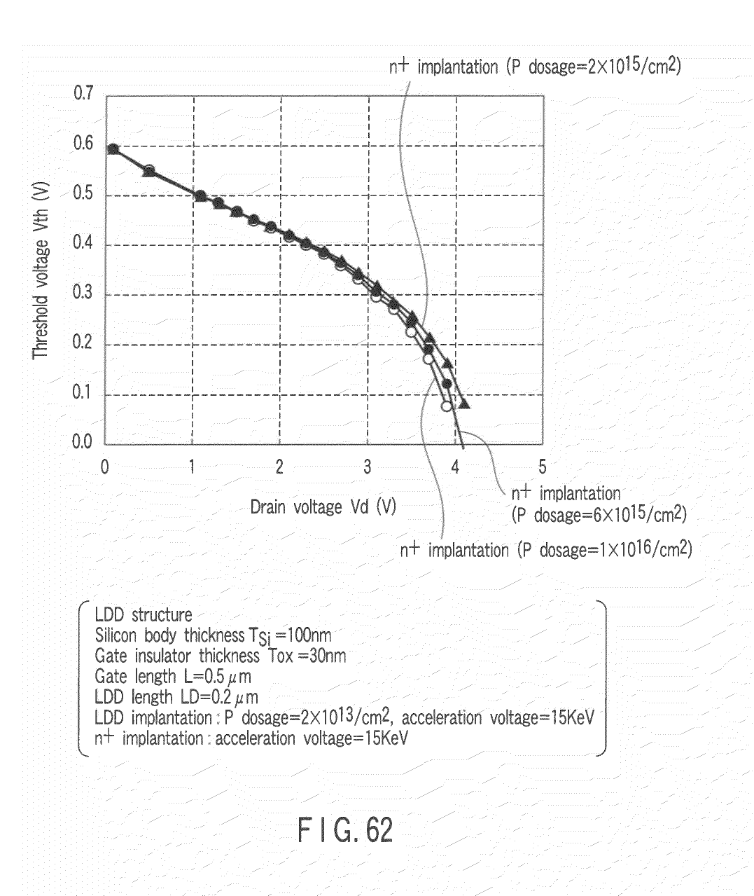

FIG. 58 shows an influence of the n⁺ implanting phosphorus (P) dosage on the relationship between the source-drain breakdown voltage BV of the thin-film transistor and the LDD implanting phosphorus (P) dosage. FIG. 59 shows an influence of the n⁺ implanting phosphorus (P) dosage on the relationship between the on-current Ion of the thin-film transistor and the LDD implanting phosphorus (P) dosage. FIG. 60 shows an influence of the n⁺ implanting phosphorus (P) dosage on the relationship between the on-current Ion of the thin-film transistor and the source-drain breakdown voltage BV. FIG. 61 shows an influence of the n⁺ implanting phosphorus (P) dosage on the relationship between the off-current Ioff of the thin-film transistor and the LDD implanting phosphorus (P) dosage. FIG. 62 shows an influence of the n⁺ implanting phosphorus (P) dosage on the relationship between the threshold voltage Vth and drain voltage Vd of the thin-film transistor. The results of FIGS. 58 to 61 were obtained under the following measurement conditions: silicon body thickness Tsi=100 nm, gate insulator thickness Tox=30 nm, gate length L=0.5 μm, LDD length LD=0.2 μm, LDD implantation: acceleration voltage=15 KeV, and n⁺ implantation: acceleration voltage=15 KeV. The results of FIG. 62 were obtained under the following measurement conditions: silicon body thickness Tsi=100 nm, gate insulator thickness Tox=30 nm, gate length L=0.5 μm, LDD length LD=0.2 μm; LDD implantation: P dosage=2×10¹³/cm², acceleration voltage=15 KeV; and n⁺ implantation: acceleration voltage=15 KeV. It is found from these results that preferably the n⁺ implanting phosphorus (P) dosage is not more than 2×10¹⁵/cm² in the LDD structure, and that the source-drain breakdown voltage BV, the on-current Ion, the off-current Ioff, and the threshold voltage Vth can be optimized in each n⁺ implanting phosphorus (P) dosage. In the LDD structure, it is also found that the best source-drain breakdown voltage and the on-current characteristics are exerted by decreasing the n⁺ implanting dosage.

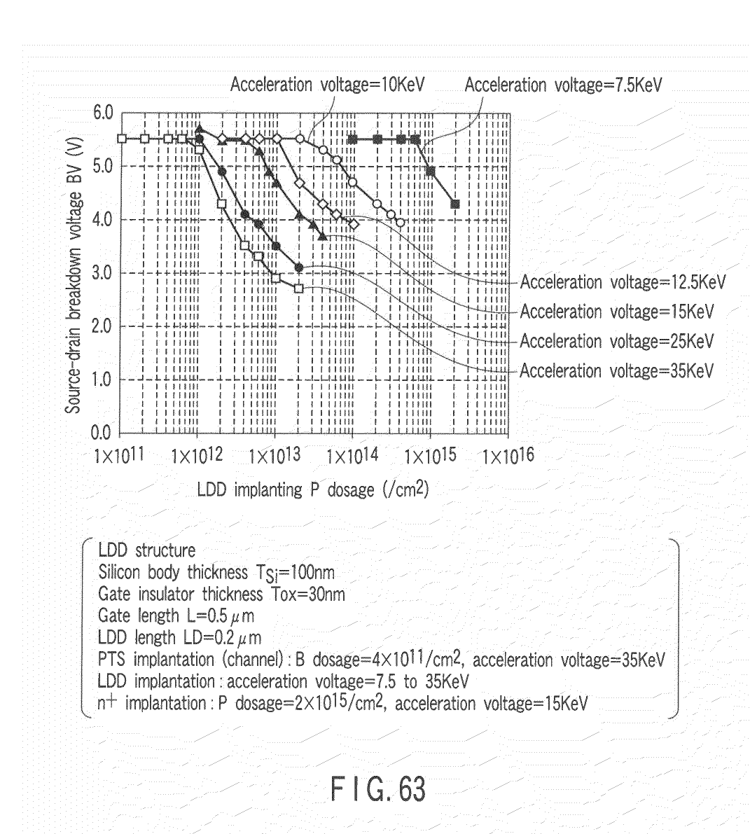

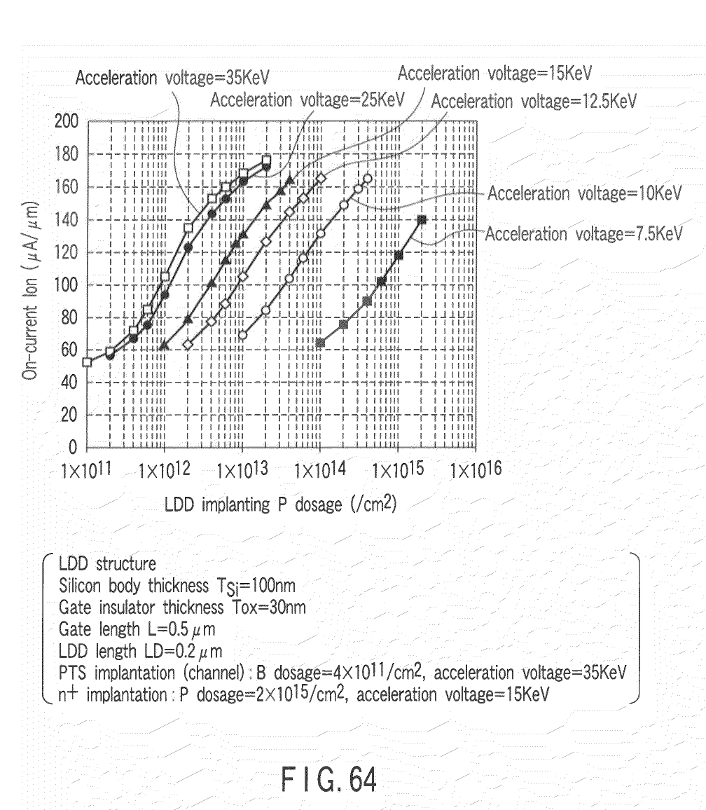

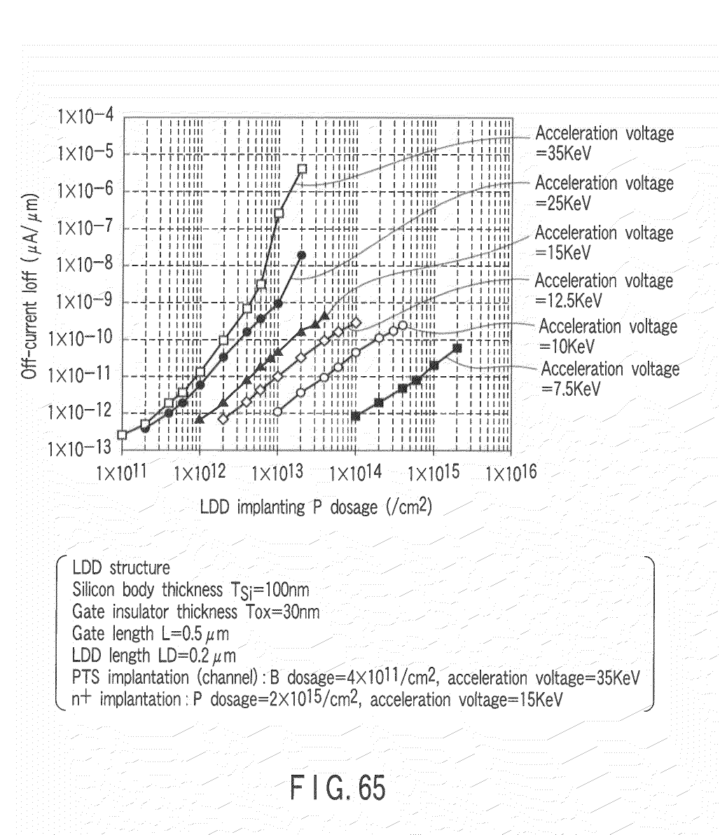

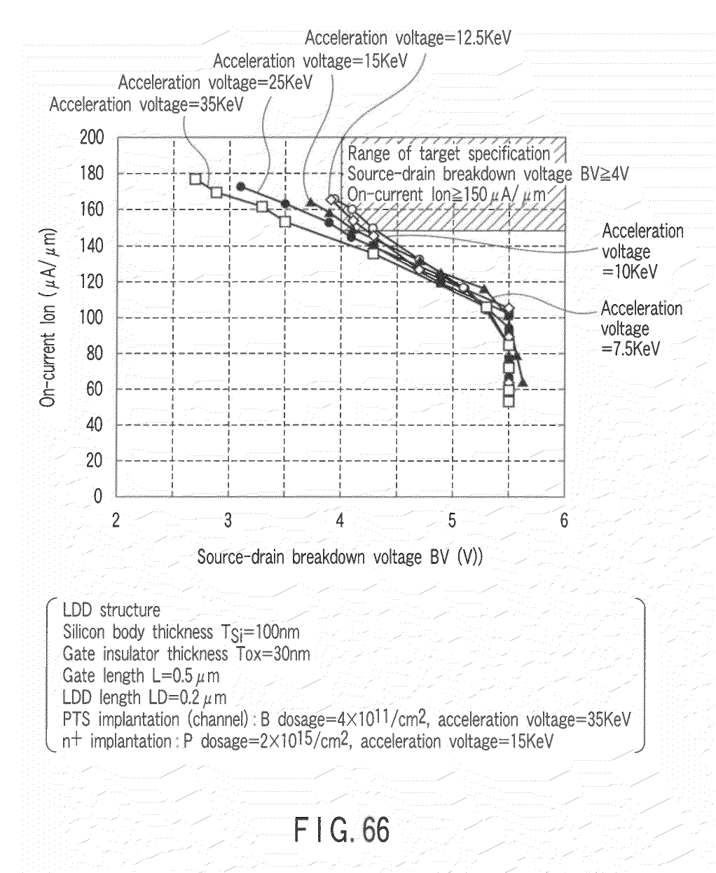

FIG. 63 shows an influence of the LDD implanting acceleration voltage on the relationship between the source-drain breakdown voltage BV of the thin-film transistor and the LDD implanting phosphorus (P) dosage. FIG. 64 shows an influence of the LDD implanting acceleration voltage on the relationship between the on-current Ion of the thin-film transistor and the LDD implanting phosphorus (P) dosage. FIG. 65 shows an influence of the LDD implanting acceleration voltage on the relationship between the off-current Ioff of the thin-film transistor and the LDD implanting phosphorus (P) dosage. FIG. 66 shows an influence of the LDD implanting acceleration voltage on the relationship between the on-current Ion and source-drain breakdown voltage BV of the thin-film transistor. The results of FIGS. 63 to 66 were obtained under the following measurement conditions: silicon body thickness Tsi=100 nm, gate insulator thickness Tox=30 nm, gate length L=0.5 μm, LDD length LD=0.2 μm; PTS implantation (channel): B dosage=4×10¹¹/cm², acceleration voltage=35 KeV; LDD implantation: acceleration voltage=7.5 to 35 KeV; n⁺ implantation: P dosage=2×10¹⁵/cm², and acceleration voltage=15 KeV. It is found from these results that the LDD implanting phosphorus (P) dosage can be increased to optimize the source-drain breakdown voltage BV, on-current Ion and off-current Ioff when the LDD implanting acceleration voltage is lowered to decrease the phosphorus concentration in the LDD structure. When the LDD implanting acceleration voltage ranges from 10 to 15 KeV, a good source-drain breakdown voltage BV and on-current Ion can be obtained. In the case of the LDD implanting acceleration voltage of 10 KeV, the source-drain breakdown voltage BV and the on-current Ion are optimized when the LDD implanting phosphorus (P) dosage ranges from 1×10¹³/cm² to 4×10¹⁴/cm². In the case of the LDD implanting acceleration voltage of 15 KeV, the source-drain breakdown voltage BV and the on-current Ion are optimized when the LDD implanting phosphorus (P) dosage ranges from 6×10¹²/cm² to 4×10¹³/cm².

In FIG. 66, in the optimum working range, the source-drain breakdown voltage BV is not lower than 3.5 V, and the on-current Ion is not lower than 120 μA/μm. In the maximum working range, the source-drain breakdown voltage BV is not lower than 4 V, and the on-current Ion is not lower than 140 μA/μm.

When the same investigation is performed for the case in which many defects exist in the crystal, because the number of recombination centers is increased at the same dosage in comparison with the case in which the small number of defects exists in the crystal, the source-drain breakdown voltage BV is raised and the mobility is decreased. Therefore, the on-current Ion is decreased, and thus the optimum dosage is shifted to the range of about 2×10¹³/cm² to about 1×10¹⁴/cm² in the case of the LDD implanting acceleration voltage of 15 KeV.

Accordingly, the LDD implanting phosphorus (P) dosage becomes optimum in the range of 6×10¹²/cm² to 1×10¹⁴/cm², when the LDD implanting acceleration voltage is set such that the impurity concentration near the support substrate 10 is lower than the impurity concentration near the gate insulator 14 by a factor of about 1000 to about 10000 (15 KeV in this case).

In the case where the LDD implanting acceleration voltage is set such that the impurity concentration near the support substrate 10 is lower than the impurity concentration near the gate insulator 14 by a factor of about 10000 to about 100000 (10 KeV in this example), when the same investigation is performed for the case in which many defects exist in the crystal, the source-drain breakdown voltage BV is raised and the on-current Ion is decreased. Thus, the optimum dosage is shifted to the range of about 3×10¹³/cm² to about 1×10¹⁵/cm².

Accordingly, the LDD implanting phosphorus (P) dosage becomes optimum in the range of 1×10¹³/cm² to 1×10¹⁵/cm², when the LDD implanting acceleration voltage is set such that the impurity concentration near the support substrate 10 is lower than the impurity concentration near the gate insulator 14 by a factor of about 10000 to about 100000 (10 KeV in this case).

That the distance from the inside end of the contact portion (contact hole) of the drain electrode 18D to the junction between the channel region 12C and the drain region 12D is not more than 4 μm can be confirmed by measurement with a laser microscope, an ultraviolet microscope, or an optical microscope.

In the second embodiment, the LDD length LD is fixed at 0.2 μm. However, the same results can be obtained even if the LDD length LD is lengthened by about 0.3 to about 0.4 μm to increase the LDD implanting phosphorus (P) dosage. To the contrary, the same results can be obtained even if the LDD length LD is shortened by about 0.05 to about 0.1 μm to decrease the LDD implanting phosphorus (P) dosage. That is, even if the LDD length LD is arbitrarily changed, the same results can be obtained.

In the second embodiment, the impurity concentration profile is provided in the channel region 12C such that the impurity concentration is increased from the interface with the gate insulator 14 toward the interface with the insulating support substrate 10 in the thickness direction of the semiconductor thin film 12, and the impurity concentration profiles are provided in the source region 12S and the LDD region 12LD such that the impurity concentrations are decreased from the interface with the gate insulator 14 toward the interface with the insulating support substrate 10 in the thickness direction of the semiconductor thin film 12. Therefore, the maximum mobility μmax is enhanced, the swing value Sth is decreased, the on-current Ion is increased, the off-current Ioff is decreased, the source-drain breakdown voltage BV is improved, and the fluctuation in threshold voltage Vth by the DIBL effect can be decreased. Even if the threshold voltage Vth is shifted from a desired value in order to obtain the impurity concentration profile which improves the source-drain breakdown voltage BV, the ratio of the impurity concentration near the insulating support substrate 10 to the impurity concentration near the gate insulator 14 is maintained by adjusting the impurity dosage, whereby the desired threshold voltage Vth can be obtained.

In the second embodiment, the distance D between the contact portion of the drain electrode 18D for the drain region 18D and the end of the drain region 12D adjacent to the LDD region 12LD is set at 0.5 μm, which is identical to the gate length L. The distance D between the contact portion of the source electrode 18S for the source region 18S and the end of the source region 12S adjacent to the LDD region 12LS is set at 0.5 μm, which is identical to the gate length L. At least the distance D between the contact portion of the drain electrode 18D and the end of the drain region 12D adjacent to the LDD region 12LD should be set so as not to exceed 4 μm, more preferably 1 μm in order not to degrade the good device characteristics obtained by the impurity concentration profiles of the channel region 12C, source region 12S, drain region 12D, LDD region 12LS, and LDD region 12LD.

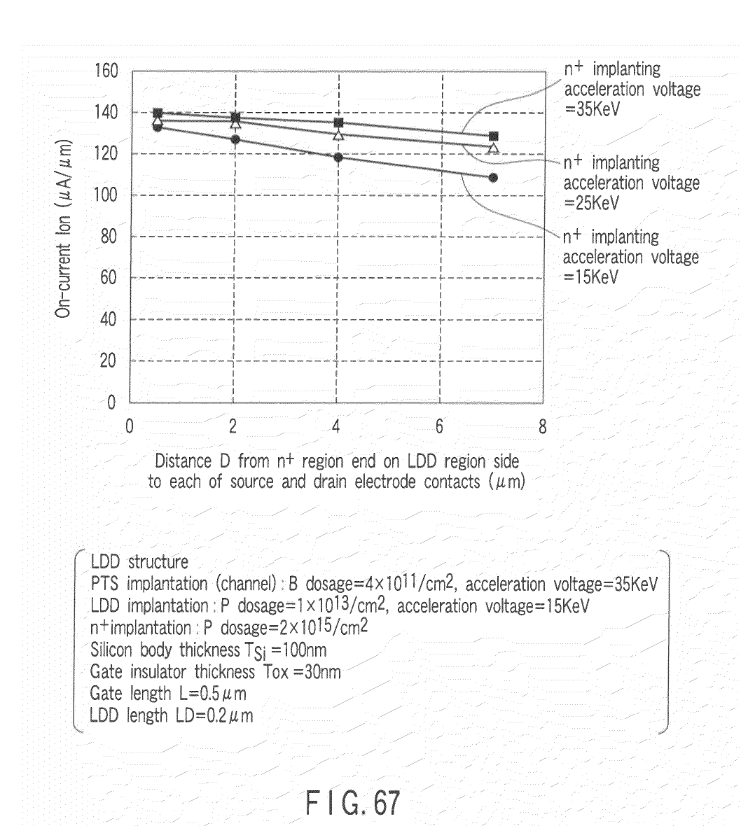

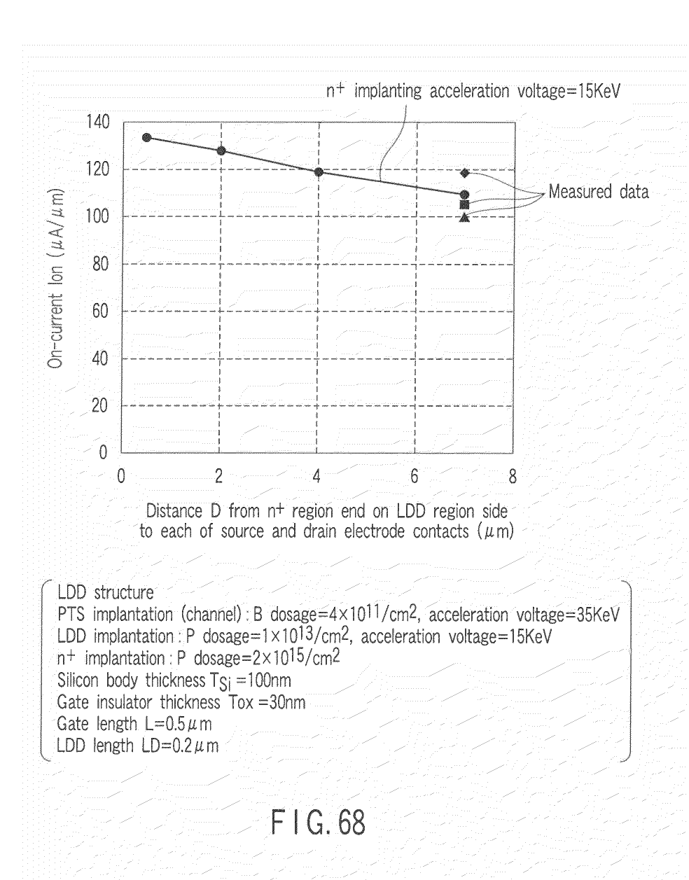

FIG. 67 shows simulation results of dependence of the on-current Ion on the distance D from the contact portion of the drain electrode 18D with the drain region 18D to the end of the drain region 12D adjacent to the LDD region 12LD in the thin-film transistor having the LDD structure whose gate length L is set at 0.5 μm. FIG. 68 shows experimental results of the dependence of the on-current Ion on the distance D from the contact portion of the drain electrode 18D to the end of the drain region 12D adjacent to the LDD region 12LD. The results of FIGS. 67 and 68 were obtained under the following measurement conditions: PTS implantation (channel): B dosage=4×10¹¹/cm², acceleration voltage=35 KeV; LDD implantation: P dosage=1×10¹³/cm², acceleration voltage=15 KeV; n⁺ implantation: P dosage=2×10¹⁵/cm²; silicon body thickness Tsi=100 nm, gate insulator thickness Tox=30 nm, gate length L=0.5 μm, and LDD length LD=0.2 μm. It was confirmed that the values measured in the actual device substantially agreed with the simulation result. The on-current Ion is not substantially changed in both the shallow junction and the deep junction when the distance D is shortened. On the other hand, the current is remarkably decreased due to the shallow junction when the distance D is lengthened. Accordingly, in order to exert the meaningful effect of the improvement of the source-drain breakdown voltage BV by the shallow junction, it is important to shorten the distance D. The distance is set to at most 4 μm, preferably 1 μm, so that the source-drain breakdown voltage BV and the on-current Ion can be set at higher values.

That the gate length L is not more than 1 μm can be confirmed by measurement with a laser microscope, an ultraviolet microscope, or an optical microscope. In the thin-film transistor in which the distance from the inside end of the contact portion (contact hole) of the drain electrode 18D to the junction between the channel region 12C and the drain region 12D is not more than 4 μm, the high source-drain breakdown voltage can be obtained by setting the source region 12D and the drain region 12D at the above-described impurity concentration profiles.

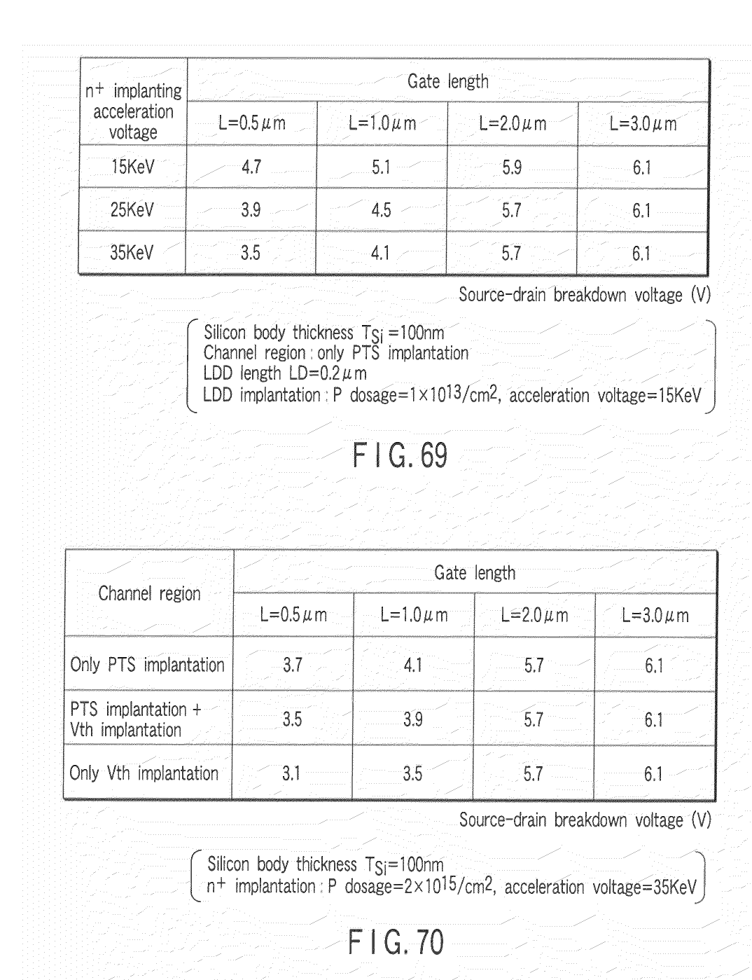

FIG. 69 shows an influence of the n⁺ implanting acceleration voltage and gate length L on the source-drain breakdown voltage BV in the thin-film transistor having the LDD structure. The results of FIG. 69 were obtained under the following measurement conditions: silicon body thickness Tsi=100 nm; channel region: only PTS implantation is performed; LDD length LD=0.2 μm; and LDD implantation: P dosage=1×10¹³/cm², acceleration voltage=15 KeV. In the case where the n⁺ implantation acceleration voltage is set at 15 KeV, the source-drain breakdown voltage BV becomes 4.7 V at L=0.5 μm, 5.1 V at L=1.0 μm, 5.9 V at L=2.0 μm, and 6.1 V at L=3.0 μm. In the case where the n⁺ implantation acceleration voltage is set at 25 KeV, the source-drain breakdown voltage BV becomes 3.9 V at L=0.5 μm, 4.5 V at L=1.0 μm, 5.7 V at L=2.0 μm, and 6.1 V at L=3.0 μm. In the case where the n⁺ implantation acceleration voltage is set at 35 KeV, the source-drain breakdown voltage BV becomes 3.5 V at L=0.5 μm, 4.1 V at L=1.0 μm, 5.7 V at L=2.0 μm, and 6.1 V at L=3.0 μm. FIG. 70 shows an influence of channel implantation conditions and the gate length L on the source-drain breakdown voltage BV in the thin-film transistor having the LDD structure. The results of FIG. 70 were obtained under the following measurement conditions: silicon body thickness Tsi=100 nm and n⁺ implantation: P dosage=2×10¹⁵/cm², acceleration voltage=35 KeV. In the case where only the PTS implantation is performed in the channel region, the source-drain breakdown voltage BV becomes 3.7 V at L=0.5 μm, 4.1 V at L=1.0 μm, 5.7 V at L=2.0 μm, and 6.1 V at L=3.0 μm. In the case where the PTS implantation and the Vth implantation are performed in the channel region, the source-drain breakdown voltage BV becomes 3.5 V at L=0.5 μm, 3.9 V at L=1.0 μm, 5.7 V at L=2.0 μm, and 6.1 V at L=3.0 μm. In the case where only the Vth implantation is performed in the channel region, the source-drain breakdown voltage BV becomes 3.1 V at L=0.5 μm, 3.5 V at L=1.0 μm, 5.7 V at L=2.0 μm, and 6.1 V at L=3.0 μm. As can be seen from FIGS. 69 and 70, in the case where the gate length L exceeds 1 μm, the effect of large improvement of the source-drain breakdown voltage BV cannot be expected even if the n⁺ junction is shallowed. In other words, the source-drain breakdown voltage BV is effectively improved by setting the gate length L at 1 μm or less.

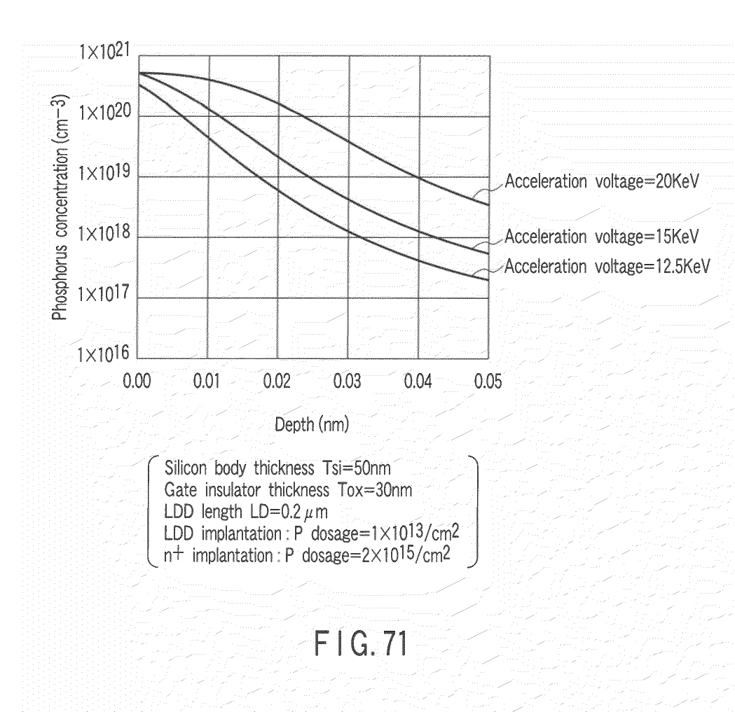

The case in which the thin-film transistor has the silicon body thickness Tsi of 50 nm will supplementarily be described below. FIG. 71 shows an influence of the acceleration voltage of the ion implantation apparatus, which performs the phosphorus (P) ion implantation, on the impurity profile of the n⁺ region such as the source region 12S and the drain region 12D. The results of FIG. 71 were obtained under the following measurement conditions: silicon body thickness Tsi=50 nm, gate insulator thickness Tox=30 nm, LDD length LD=0.2 μm, LDD implantation: P dosage=1×10¹³/cm², and n⁺ implantation: P dosage=2×10¹⁵/cm². At this point, the P ion implantation is performed such that the n⁺ implantation lowers the concentration of the portion away from the interface with the gate insulator 14 in the thickness direction, that is, the depth direction of the semiconductor thin film 12. When the simulation is performed for the n⁺ implantation, a different impurity profile is obtained for each acceleration voltage, as shown in FIG. 71. In the case of the acceleration voltage of 20 KeV, the phosphorus concentration near the insulating support substrate 10 is lower than the phosphorus concentration near the gate insulator 14 by two digits, that is, by a factor of about 100. In the case of the acceleration voltage of 12.5 KeV, the phosphorus concentration near the insulating support substrate 10 is lower than the phosphorus concentration near the gate insulator 14 by three digits, that is, by a factor of about 1000.

For example, the impurity concentration profiles of the source region 12S, the drain region 12D, and the LDD regions 12LS and 12LD can be measured with the secondary ion mass spectrometer.

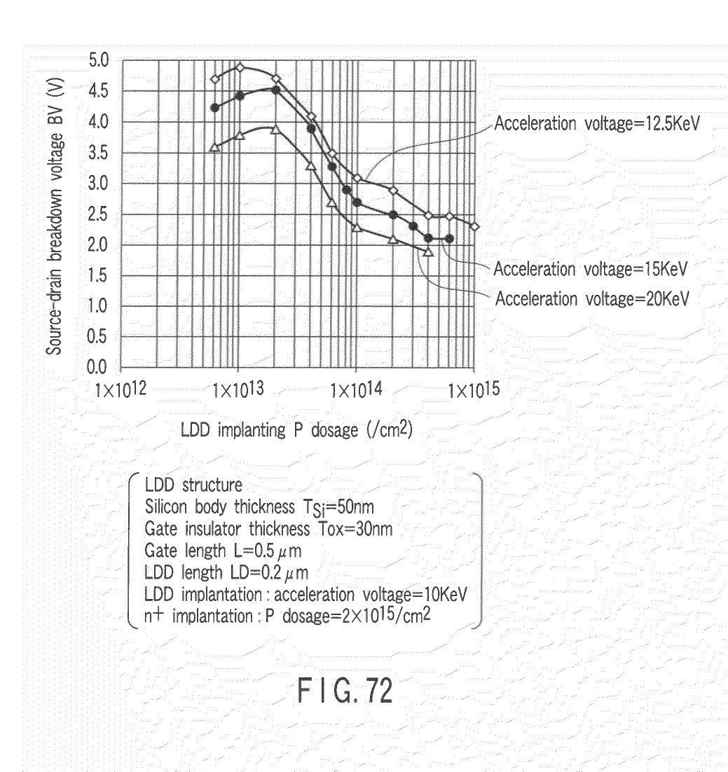

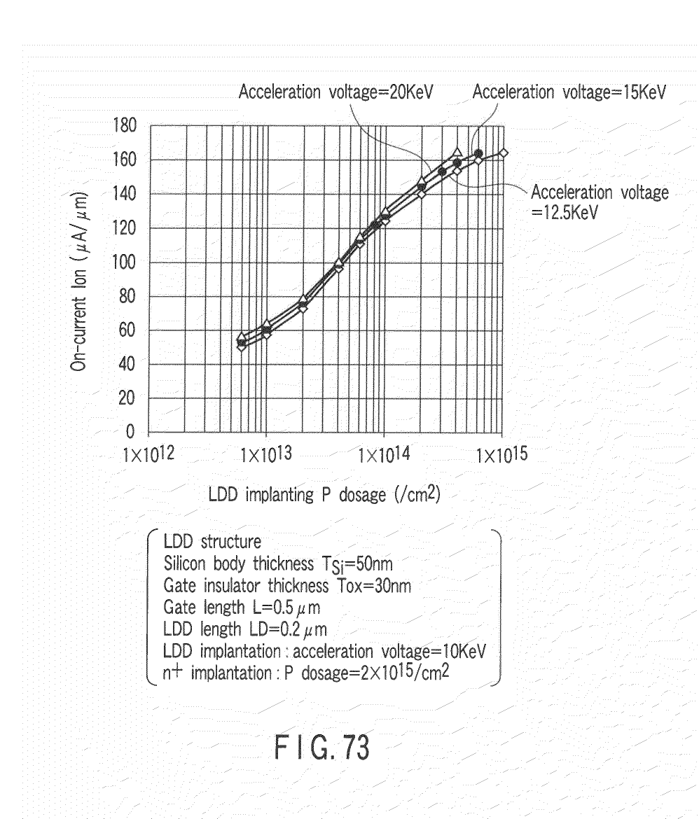

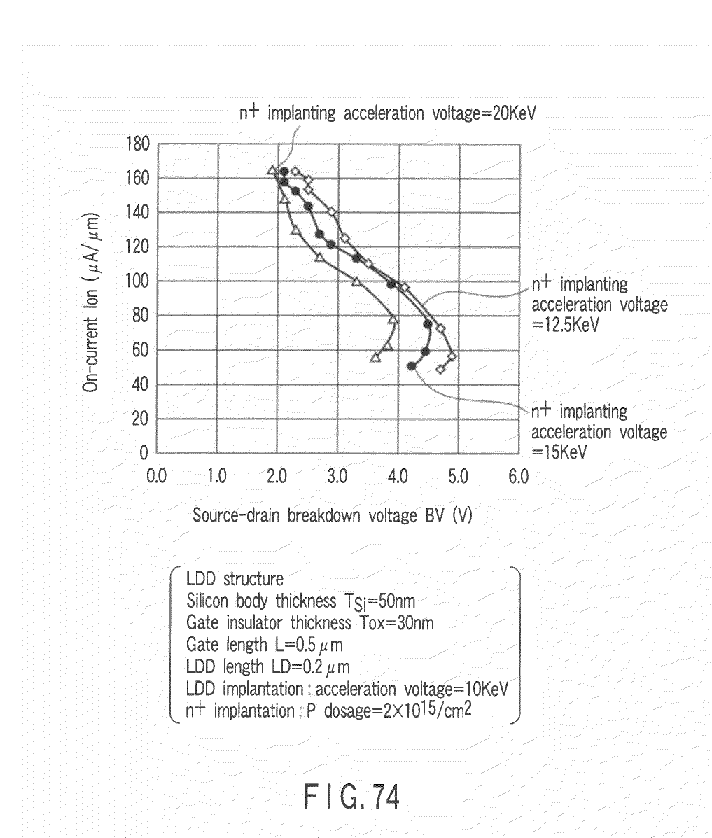

FIG. 72 shows an influence of the n⁺ implanting acceleration voltage on the relationship between the source-drain breakdown voltage BV and the LDD implanting phosphorus dosage. FIG. 73 shows an influence of the n⁺ implanting acceleration voltage on the relationship between the on-current Ion and the LDD implanting phosphorus dosage. FIG. 74 shows an influence of the n⁺ implanting acceleration voltage on the relationship between the on-current Ion and the source-drain breakdown voltage BV. The results of FIGS. 72 to 74 were obtained under the following measurement conditions: silicon body thickness Tsi=50 nm, gate insulator thickness Tox=30 nm, gate length L=0.5 μm, LDD length LD=0.2 μm, LDD implantation: acceleration voltage=10 KeV, and n⁺ implantation: P dosage=2×10¹⁵/cm². It is found from these results that the source-drain breakdown voltage BV, the on-current Ion, and the off-current Ioff can be optimized in each n⁺ implanting acceleration voltage in the LDD structure. In the LDD structure, it is also found that the n⁺ implanting acceleration voltage is decreased to form the impurity concentration profile which is decreased from the interface with the gate insulator toward the interface with the insulating support substrate in the thickness direction of the semiconductor thin film, thereby exerting the best source-drain breakdown voltage and on-current characteristics.

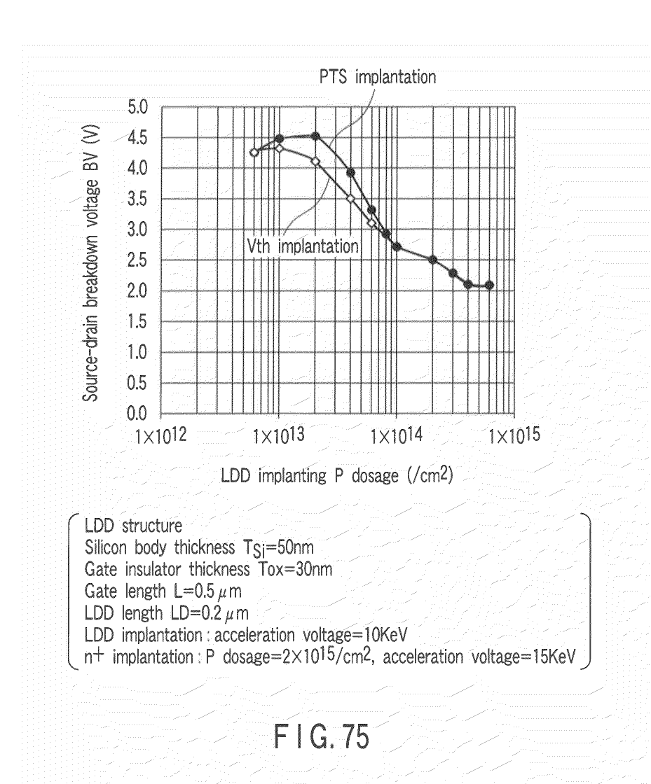

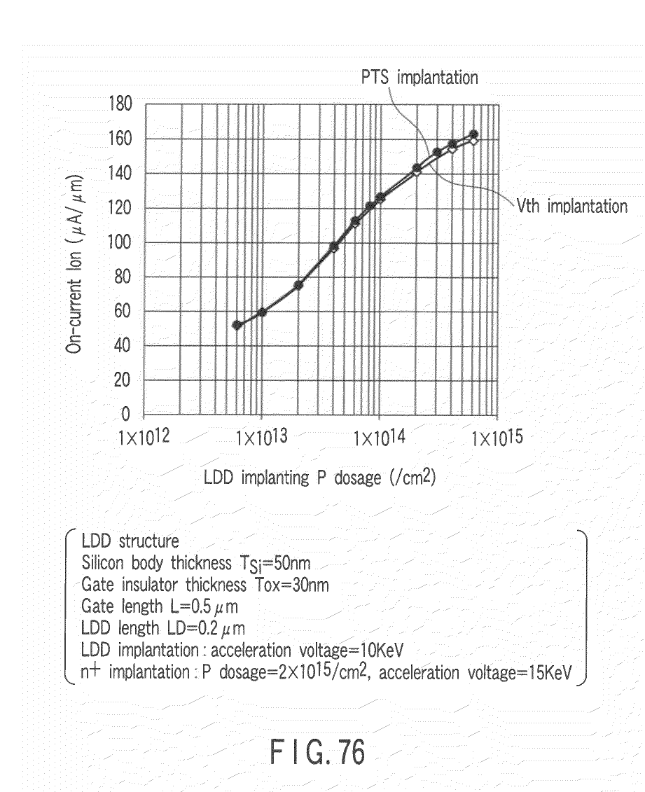

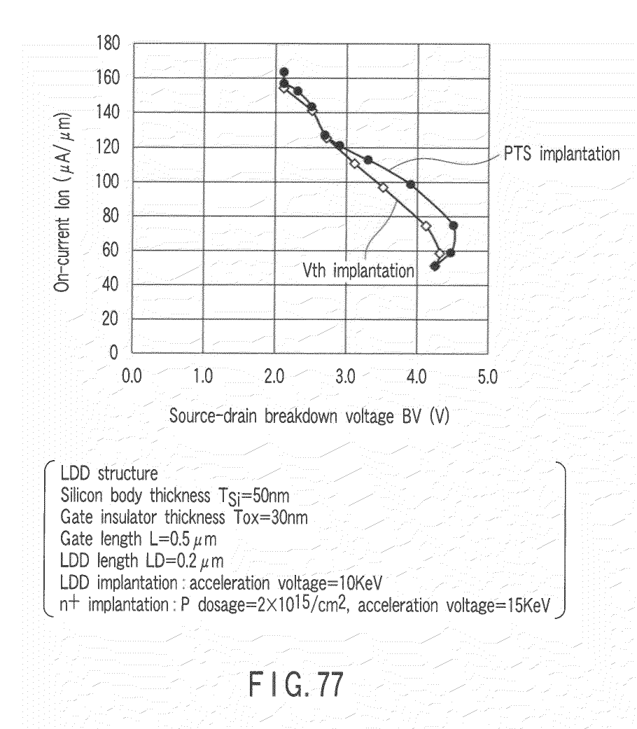

FIG. 75 shows an influence of the ion implantation conditions of the channel region on the relationship between the source-drain breakdown voltage BV and the LDD implanting phosphorus dosage. FIG. 76 shows an influence of the ion implantation conditions of the channel region on the relationship between the on-current Ion and the LDD implanting phosphorus dosage. FIG. 77 shows an influence of the ion implantation conditions of the channel region on the relationship between the on-current Ion and the source-drain breakdown voltage BV. The results of FIGS. 72 to 74 were obtained under the following measurement conditions: silicon body thickness Tsi=50 nm, gate insulator thickness Tox=30 nm, gate length L=0.5 μm, LDD length LD=0.2 μm, LDD implantation: acceleration voltage=10 KeV; and n⁺ implantation: P dosage=2×10¹⁵/cm², acceleration voltage=15 KeV. It is found from these results that the source-drain breakdown voltage BV and the on-current Ion can be optimized in each impurity profile of the channel region 12C in the LDD structure. In the LDD structure, it is also found that the PTS implantation exerts the best source-drain breakdown voltage and on-current characteristics for the impurity profile of the channel region 12C.

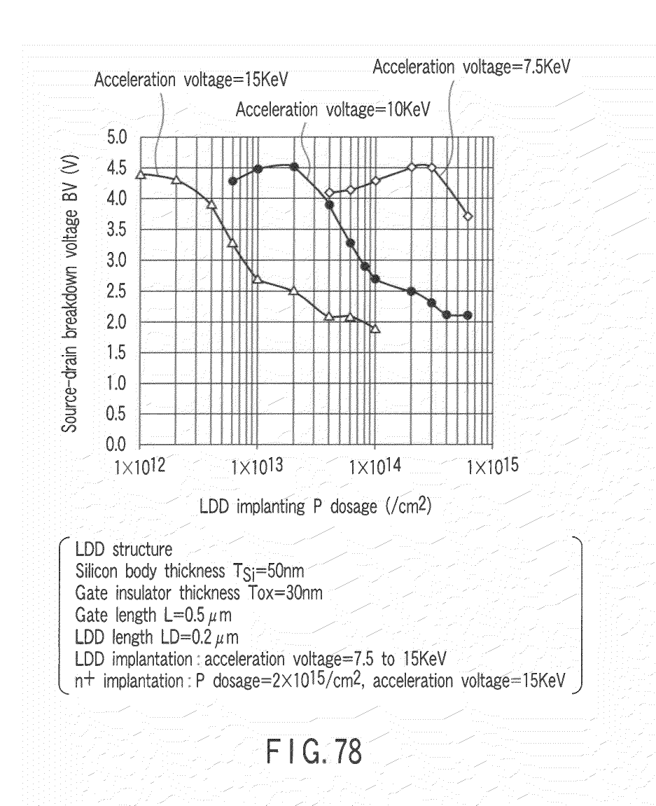

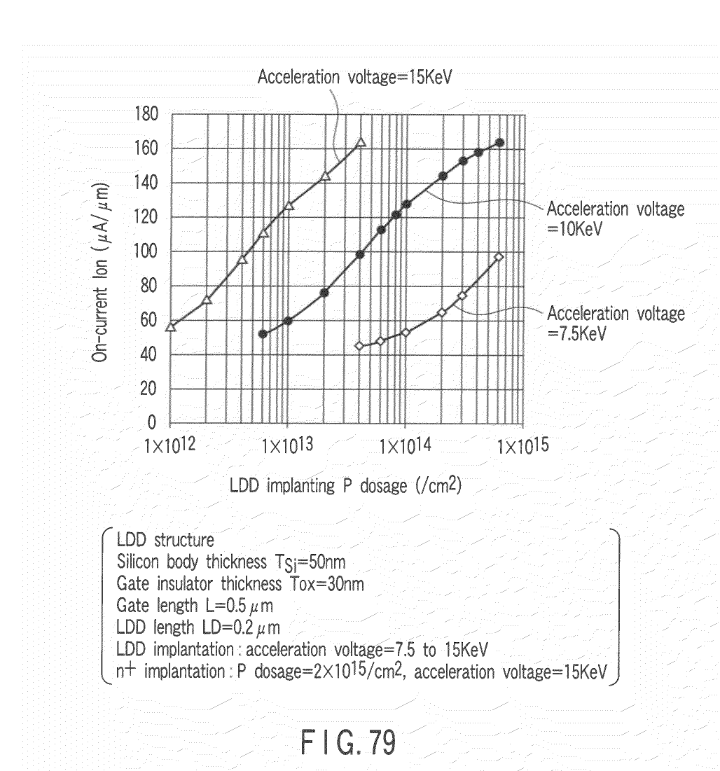

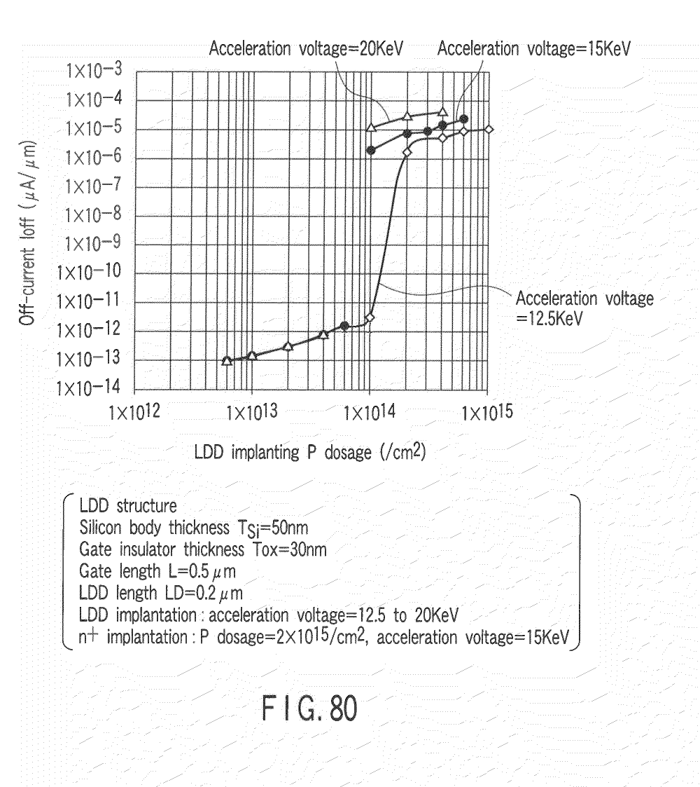

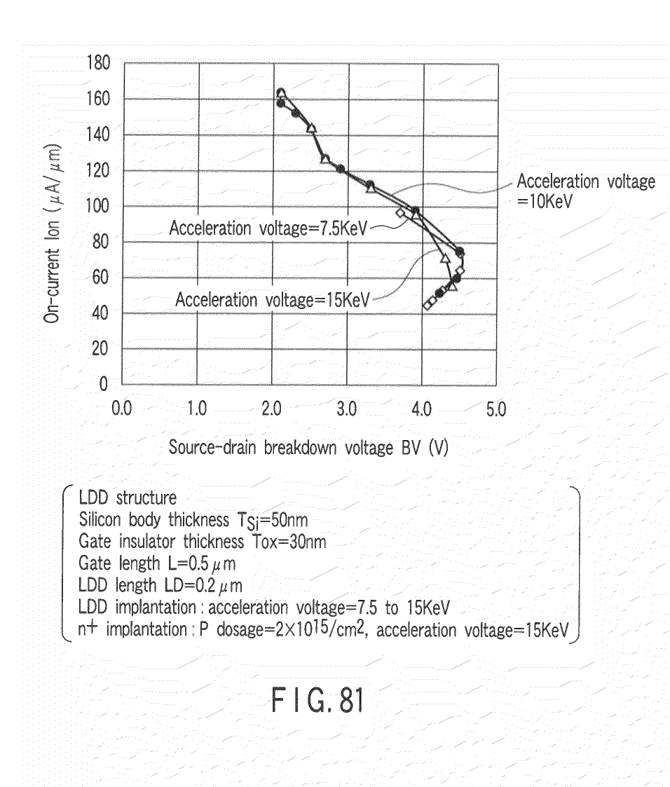

FIG. 78 shows an influence of the LDD implanting acceleration voltage on the relationship between the source-drain breakdown voltage BV and the LDD implanting phosphorus dosage. FIG. 79 shows an influence of the LDD implanting acceleration voltage on the relationship between the on-current Ion and the LDD implanting phosphorus dosage. FIG. 80 shows an influence of the LDD implanting acceleration voltage on the relationship between the off-current Ioff and the LDD implanting phosphorus dosage. FIG. 81 shows an influence of the LDD implanting acceleration voltage on the relationship between the on-current Ion and the source-drain breakdown voltage BV. The results of FIGS. 78 to 81 were obtained under the following measurement conditions: silicon body thickness Tsi=50 nm, gate insulator thickness Tox=30 nm, gate length L=0.5 μm, LDD length LD=0.2 μm, LDD implantation: acceleration voltage=7.5 to 15 KeV (FIGS. 78, 79, and 81), acceleration voltage=12.5 to 20 KeV (FIG. 80); and n⁺ implantation: P dosage=2×10¹⁵/cm², acceleration voltage=15 KeV. In the LDD structure, it is found from these results that the source-drain breakdown voltage BV, the off-current Ioff, and the on-current Ion can be optimized by increasing the LDD implanting phosphorus (P) dosage when the LDD implanting acceleration voltage is lowered to decrease the phosphorus concentration.

When the silicon body thickness Tsi is decreased to 50 nm, the effect of the improvement of the source-drain breakdown voltage BV by the shallow junction can be confirmed though not to the extent of the silicon body thickness Tsi of 100 nm.

When the LDD implanting acceleration voltage is set equal to or slightly smaller than the n⁺ implanting acceleration voltage, good source-drain breakdown voltage BV characteristics can be obtained. That is, assuming that Δ is a concentration difference of the impurity profile decreased from the interface with the gate insulator 14 toward the interface with the insulating support substrate 10 in the thickness direction of the silicon body which is the semiconductor thin film 12, when the concentration difference Δ of the LDD region 12LD is set smaller than the concentration difference Δ of the n⁺ source region 12S, good source-drain breakdown voltage BV characteristics can effectively be obtained.

The channel implanting acceleration voltage is selected as a value suitable for the case in which the gate insulator is fixed at 30 nm. When the gate insulator 14 is thinned, the same effect is obtained, because basically the channel region 12C can have the same impurity concentration profile by lowering the acceleration voltage.

The invention is not limited to the first embodiment, but various modifications can be made without departing from the scope of the invention.

The insulating support substrate 10 is not limited to the insulating substrate of which the entire substrate has the insulating property, but may be formed by a semiconductor wafer or a metal plate in which a surface constituting the ground of the semiconductor thin film has the insulating property.

In the second embodiment, the n-channel type thin-film transistor is used as shown in FIG. 41. However, a similar effect is obtained in the p-channel type thin-film transistor.

The impurity profile of the n⁺ drain region 12D is set to substantially the same impurity profile of the n⁺ source region 12D while the impurity profile of the LDD region 12LS is set to substantially the same impurity profile of the LDD region 12LD such that the production process does not become complicated. Alternatively, the impurity profile of the n⁺ drain region 12D may be set independently of the impurity profile of the n⁺ source region 12D while the impurity profile of the LDD region 12LS may be set independently of the impurity profile of the LDD region 12LD.

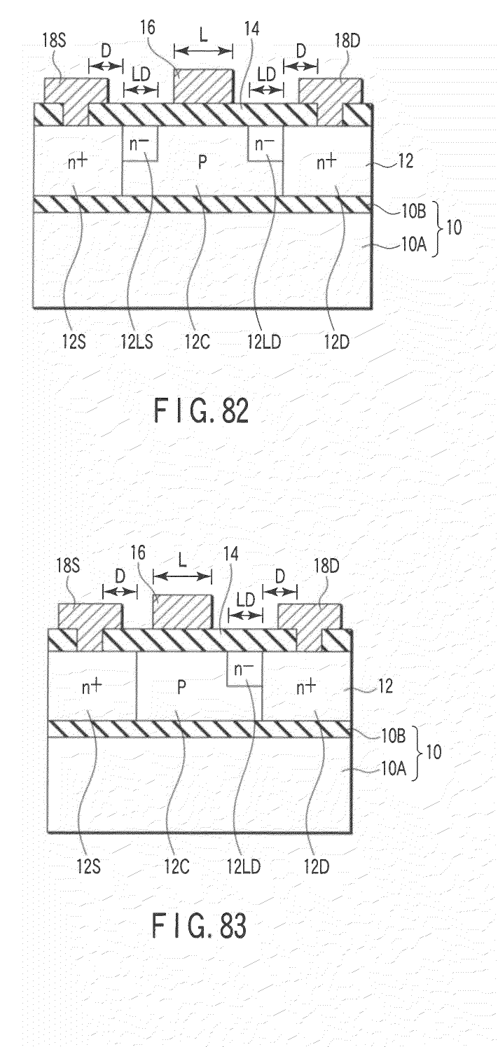

In the second embodiment, the LDD regions 12LS and 12LD of the thin-film transistor are connected to the interface with the underlying insulating layer 10B as shown in FIG. 41. As shown in FIG. 82, it is only necessary to bring the LDD regions 12LS and 12LD into contact with the interface with the gate insulator 14 and the interfaces with the source region 12S and drain region 12D.

In the second embodiment, the LDD regions of the thin-film transistor are provided between the channel region 12C and the source region 12S and between the channel region 12C and the drain region 12D. As shown in FIG. 83, it is only necessary to provide the LDD region at least between the channel region 12C and the drain region 12D.

The second embodiment is applied to the high-quality semiconductor thin film having the large-grain crystallized region as the semiconductor thin film whose source-drain breakdown voltage is lower than that of the thin-film transistor formed in the polysilicon semiconductor thin film. Alternatively, the thin-film transistor may be formed of polysilicon, which has relatively good source-drain breakdown voltage characteristics. In this case, the support body of the thin-film transistor has an insulating support substrate such as the glass substrate, the substrate in which the underlying insulating layer is provided on the substrate, and the SOI substrate in which the insulating surface is provided on the support substrate.

In the first and second embodiments, mainly a good source-drain breakdown voltage is ensured on the high-quality semiconductor thin film. It was confirmed by the following investigation that the thin-film transistors of the first and second embodiments had extremely good reliability against the hot carrier stress degradation.

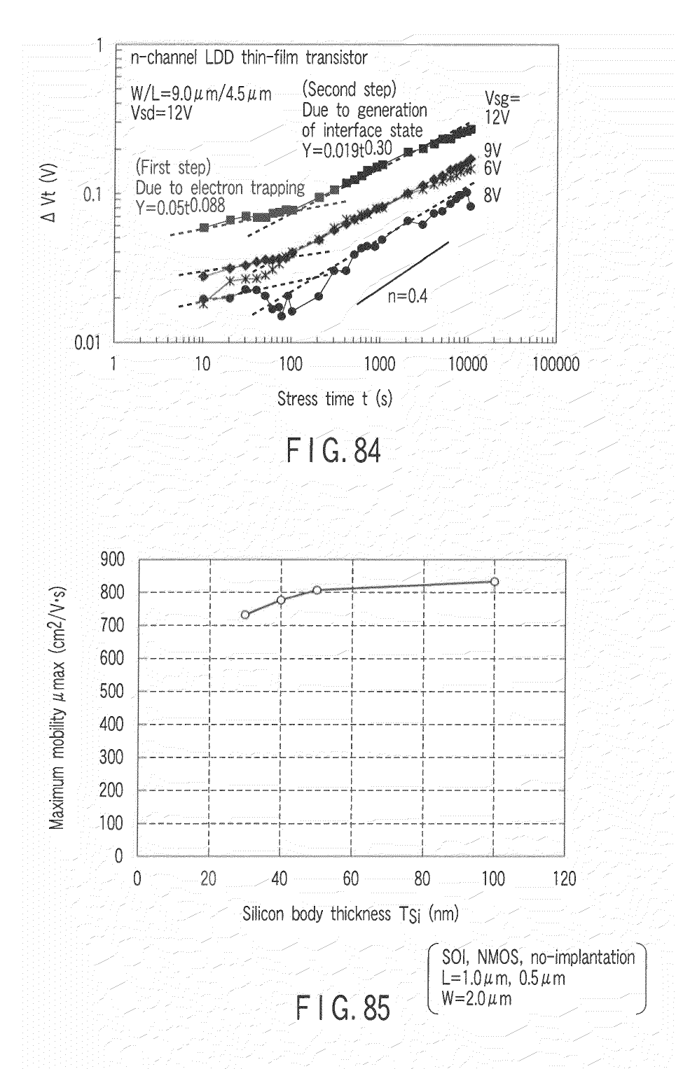

It is reported that the hot carrier stress degradation becomes a two-stage degradation mode shown in FIG. 84 (for example, see “Current reliability analysis of TFT” H. Tango, T. Usami, and M. Suganuma, Transaction of IEICE C, J87-C/3, pp. 283-295, 2004). The first-stage degradation mode is caused by electron trapping, and the second-stage degradation mode is caused by generation of an interface state.

The inventor observed the degradation of the device characteristics by measuring the Id-Vg curve (Vd=0.1 V) before and after a stress (gate voltage Vg=2.1 V and drain voltage Vd=3.5 V to 6.5 V) was applied in the verification test of the hot carrier stress degradation. A drain current degradation ratio Delta-Id/Io is an attenuation factor of the drain current Id at Vg=Vth+3 V. The threshold Vth was defined by the gate voltage Vg at which the drain current Id normalized by gate width W/gate length L became 10⁻⁷ A.

FIG. 85 shows an influence of a body film thickness Tsi on a hot carrier reliability lifetime. In this case, the body film thickness Tsi=100, 50, 40, and 30 nm was investigated for the n-channel type MOS transistor (impurity doping is not performed on the channel) on SOI (Single crystal On Insulator). In the n-channel type MOS transistor, the gate length L was set at 1.0 μm and 0.5 μm and the gate width W was set at 2.0 μm. As a result, it is found that the maximum mobility μmax is slightly decreased when the body film thickness Tsi is thinned.

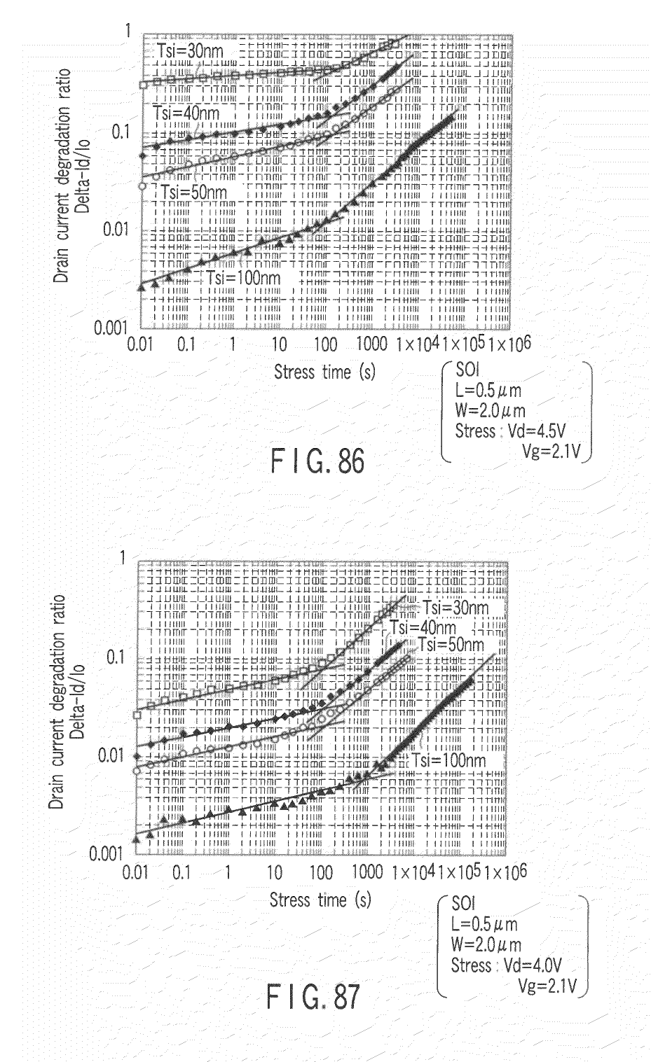

FIGS. 86 and 87 show an influence of the body film thickness Tsi on the drain current degradation ratio Delta-Id/Io due to the hot carrier stress degradation. The results of FIG. 86 were obtained under the following conditions: SOI, L=0.5 μm, W=2.0 μm; stress: Vd=4.5 V and Vg=2.1 V. The results of FIG. 87 were obtained under the following conditions: SOI, L=0.5 μm, W=2.0 μm; and stress: Vd=4.0 V and Vg=2.1 V. As can be seen from FIGS. 86 and 87, the hot carrier stress degradation is decreased as the body film thickness Tsi is increased. The tendency is strengthened as the stress condition becomes severer.

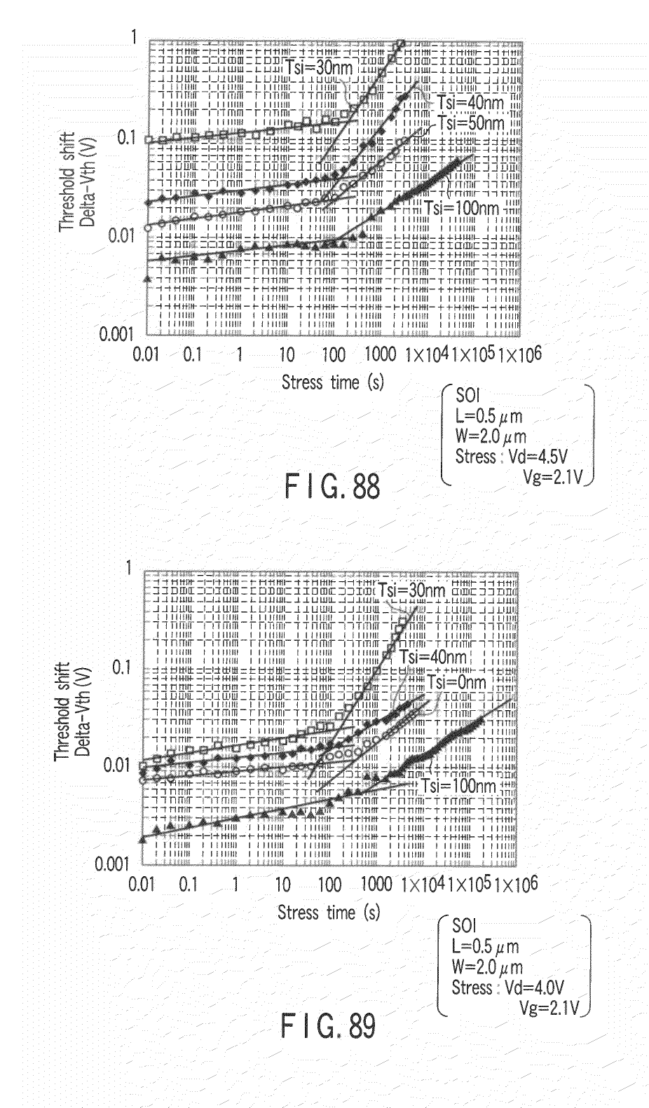

FIGS. 88 and 89 show an influence of the body film thickness Tsi on the threshold shift due to the hot carrier stress degradation. The results of FIG. 88 were obtained under the following conditions: SOI, L=0.5 μm, W=2.0 μm; and stress: Vd=4.5 V and Vg=2.1 V. The results of FIG. 89 were obtained under the following conditions: SOI, L=0.5 μm, W=2.0 μm; and stress: Vd=4.0 V and Vg=2.1 V. As a result, the gradient of the second-stage degradation mode becomes steeper as the body film thickness Tsi is decreased. Accordingly, from the standpoint of reliability against the hot carrier stress degradation, it is found effective to set the body film thickness Tsi larger.

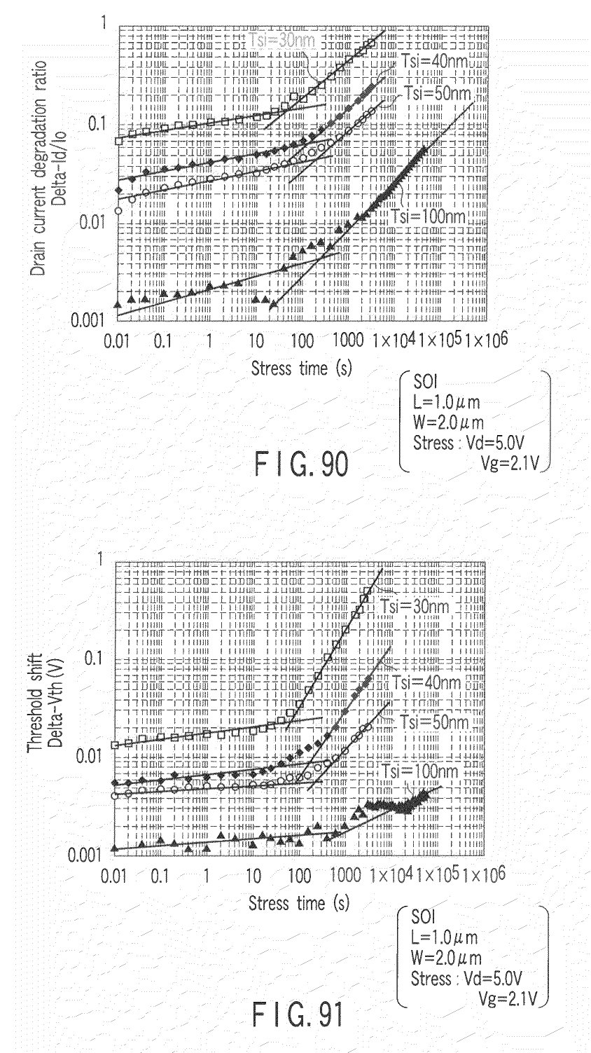

FIG. 90 shows an influence of the body film thickness Tsi on the drain current degradation ratio Delta-Id/Io caused by the hot carrier stress degradation, and FIG. 91 shows an influence of the body film thickness Tsi on the threshold shift caused by the hot carrier stress degradation. The results of FIGS. 90 and 91 were obtained under the following measurement conditions: SOI, L=1.0 μm, W=2.0 μm; and stress: Vd=5.0 V and Vg=2.1 V. As a result, in the case of the gate length L of 1.0 μm, the hot carrier stress degradation is also constrained as the body film thickness Tsi is increased, and the gradient of the second-stage degradation mode of the threshold shift becomes steeper as the body film thickness Tsi is decreased. Accordingly, from the standpoint of reliability against the hot carrier stress degradation, it is found effective to set the body film thickness Tsi larger.

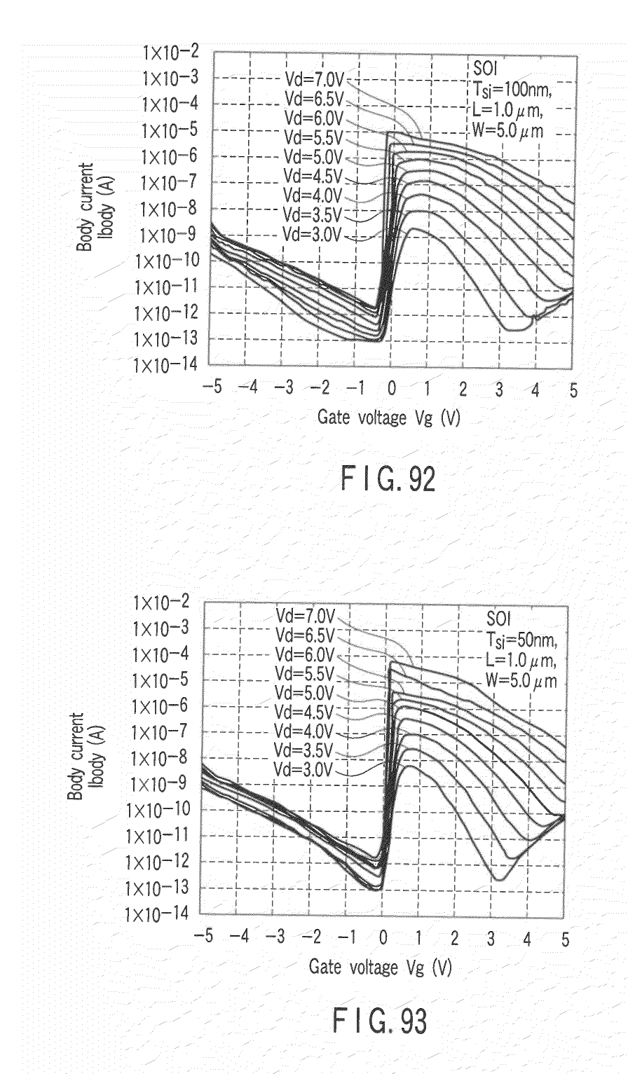

FIGS. 92 and 93 show measurement examples of a body current, Ibody that were measured by a four-terminal method. FIG. 92 shows the case of the body film thickness Tsi of 100 nm, and FIG. 93 shows the case of the body film thickness Tsi of 50 nm. The results of FIGS. 92 and 93 were obtained under the following measurement conditions: SOI, L=1.0 μm, and W=5.0 μm. The body current Ibody for the gate voltage Vg was measured when the drain voltage Vd was set in the range of 3.0 to 7.0 V with 0.5 V increments.

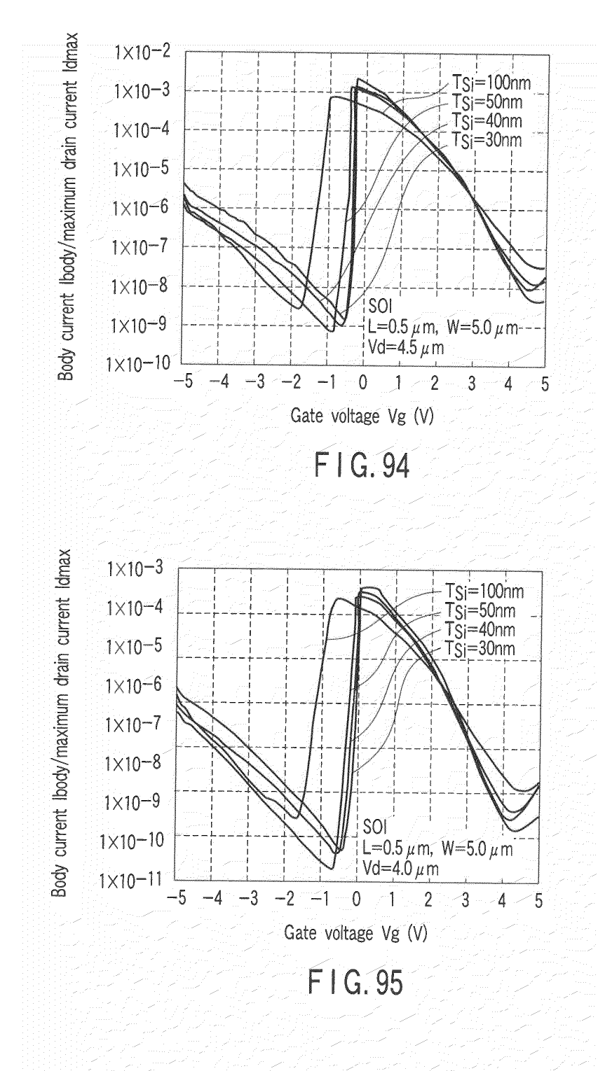

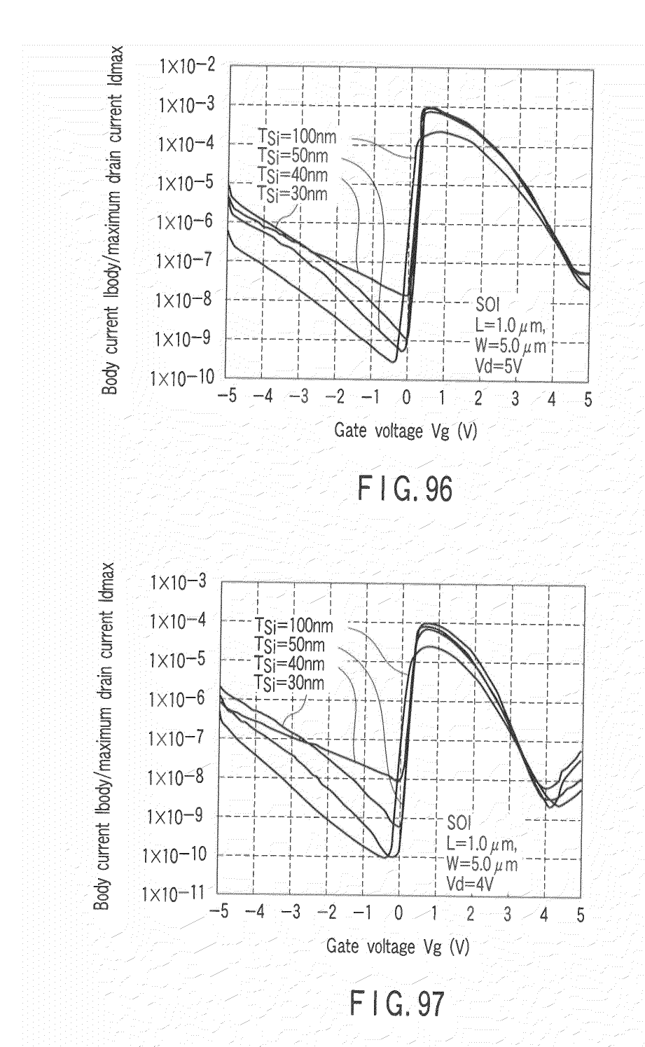

FIGS. 94 to 97 show a relationship between the body film thickness Tsi and the body current Ibody. The results of FIG. 94 were obtained under the following measurement conditions: SOI, L=0.5 μm, W=5.0 μm, and Vd=4.5 V. The results of FIG. 95 were obtained under the following measurement conditions: SOI, L=0.5 μm, W=5.0 μm; and Vd=4.0 V. The results of FIG. 96 were obtained under the following measurement conditions: SOI, L=1.0 μm, W=5.0 μm, and Vd=5.0 V. The results of FIG. 97 were obtained under the following measurement conditions: SOI, L=1.0 μm, W=5.0 μm; and Vd=4.0 V. In both the cases of L=0.5 μm and L=1.0 μm, as the body film thickness Tsi is decreased, the body current Ibody is increased although the maximum mobility μmax is slightly decreased. This indicates that holes are frequently generated at the drain connection end by the impact ionization. This tendency agrees with a tendency of the hot carrier stress degradation. That is, it is found that the impact ionization is a factor which generates the difference in hot carrier stress degradation.

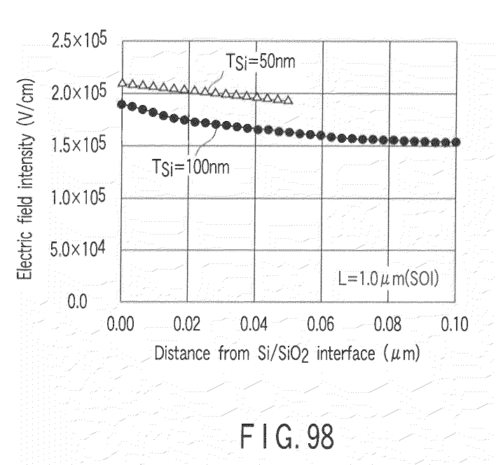

FIG. 98 shows an influence of the body film thickness Tsi on electric field intensity at a drain end obtained in the simulation. A horizontal axis of FIG. 98 indicates a distance from the interface between the silicon body (Si) and the gate insulator (SiO₂). From the result of FIG. 98, it is confirmed that the electric field intensity is strengthened when the body film thickness is decreased. That is, when the body film thickness is decreased, the impact ionization is increased to generate many hot electrons, and more hot electrons are injected into the gate insulator because of the strong electric field intensity, thereby accelerating the hot carrier stress degradation.

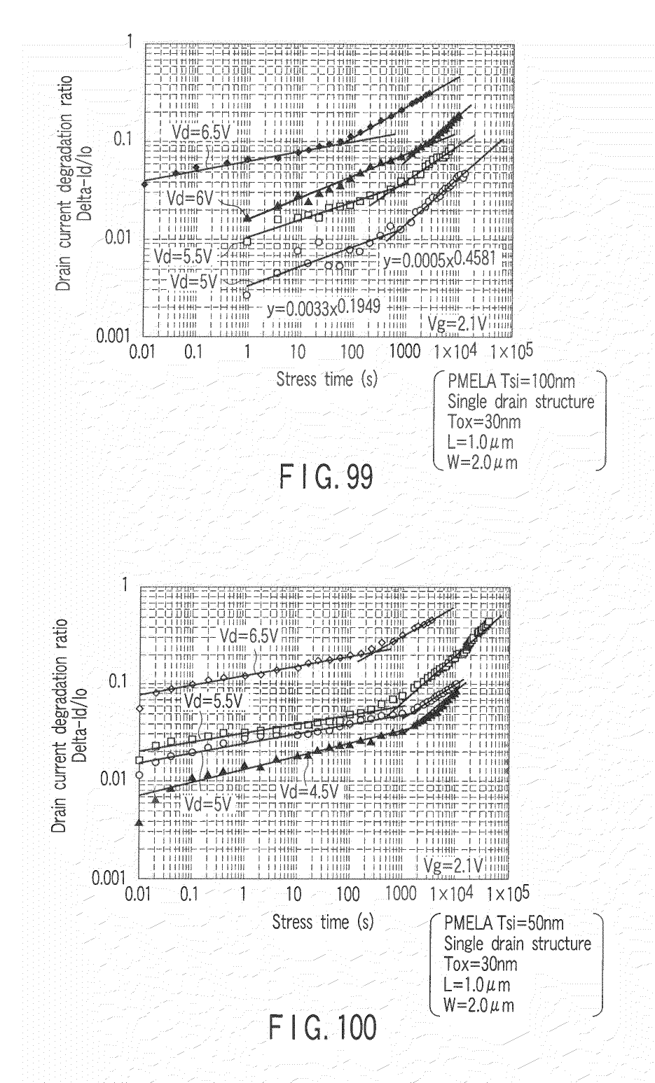

FIGS. 99 and 100 show an influence of the body film thickness Tsi on the drain current degradation ratio Delta-Id/Io caused by the hot carrier stress degradation. In FIGS. 99 and 100, the investigation was performed for the thin-film transistor in which the silicon body was not SOI but the film was obtained by the melt-recrystallization of the Phase-Modulated Excimer Laser Annealing (PMELA). The results of FIG. 99 were obtained under the following measurement conditions: PMELA, single drain structure, Tsi=100 nm, L=1.0 μm, W=2.0 μm, Tox (gate insulator thickness of SiO₂)=30 nm; and Vg=2.1 V. The results of FIG. 100 were obtained under the following measurement conditions: PMELA, single drain structure, Tsi=50 nm, L=1.0 μm, W=2.0 μm, Tox (gate insulator thickness of SiO₂)=30 nm; and Vg=2.1 V.

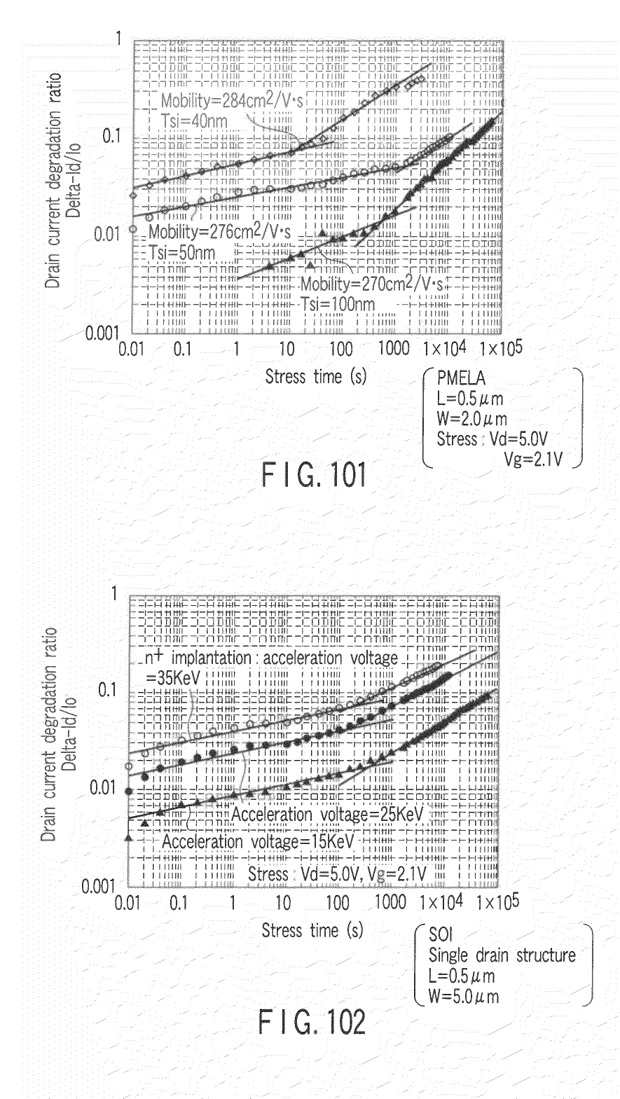

FIG. 101 shows results in which the influence of the body film thickness Tsi on the drain current degradation ratio Delta-Id/Io caused by the hot carrier stress degradation is compared under the same stress conditions. At this point, the stress condition is set at Vd=5.0 V and Vg=2.1 V. The body film thickness Tsi is set at 100, 50, 40 nm. From the result of FIG. 101, in the thin-film transistor formed by PMELA, it is also found effective to set the body film thickness Tsi larger from the standpoint of reliability against the hot carrier stress degradation.

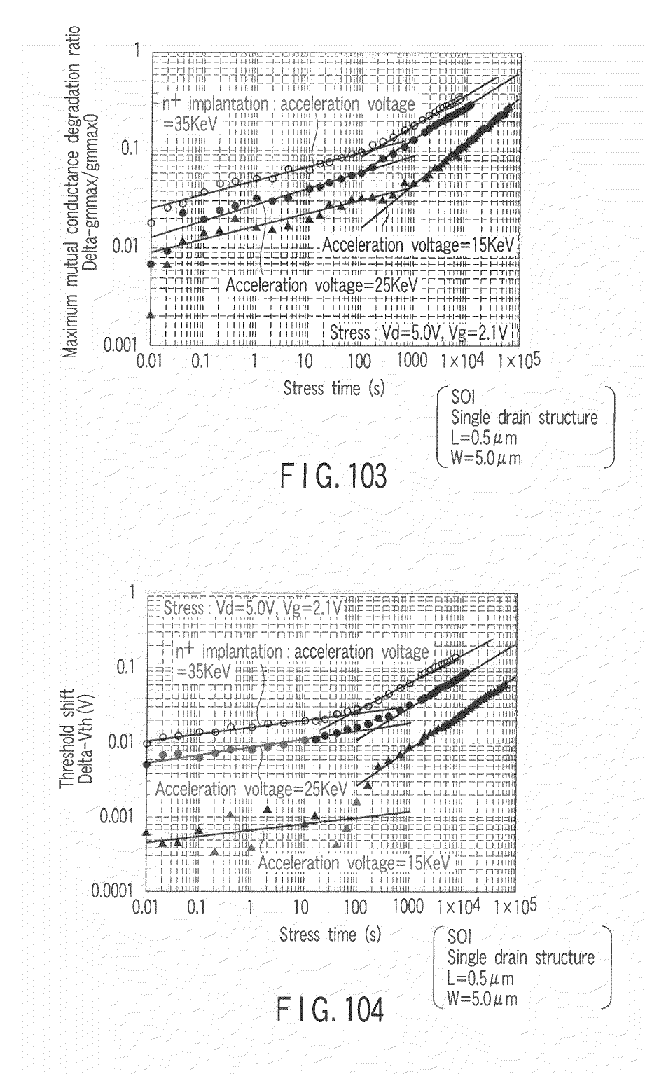

FIGS. 102 to 104 show an influence of an n⁺ junction depth on the hot carrier stress degradation. Specifically, the dependence of the drain current degradation ratio Delta-Id/Io on the n⁺ junction depth was confirmed by the result of FIG. 102, dependence of a maximum mutual conductance degradation ratio Delta-gmmax/gmmaxo on the n⁺ junction depth was confirmed by the result of FIG. 103, and dependence of a threshold shift Delta-Vth on the n⁺ junction depth was confirmed by the result of FIG. 104. The results of FIGS. 102 to 104 were obtained under the following measurement conditions: SOI, single drain structure, L=0.5 μm, W=5.0 μm; and stress: Vd=5.0 V and Vg=2.1 V. The acceleration voltage of the n⁺ implantation which determines the n⁺ junction depth was set at 35 KeV, 25 KeV, and 15 KeV. As can be seen from FIG. 102, the hot carrier stress degradation is decreased as the acceleration voltage of the n⁺ implantation is lowered to shallow the junction depth. As can be seen from FIGS. 103 and 104, from the standpoints of maximum mutual conductance degradation ratio Delta-gmmax/gmmaxo and threshold shift Delta-Vth, the hot carrier stress degradation is decreased as the acceleration voltage of the n⁺ implantation is lowered to shallow the junction depth. From the results of FIGS. 102 to 104, it is found that not only can the source-drain breakdown voltage be increased but also the reliability is enhanced against the hot carrier stress degradation by shallowing the n⁺ junction.

The influence of the n⁺ junction depth on the hot carrier stress degradation in the LDD structure will be described below. Table 1 shows the influence of the n⁺ junction depth on the drain current degradation ratio after the hot carrier stress (stress condition: Vd=5.5 V and Vg=2.1 V) is applied for 1000 seconds for the device having the LDD structure (channel length 0.5 μm, channel width 5.0 μm, and LDD length 0.2 μm) of FIG. 2. At this point, only the PTS implantation is used as the channel implantation. From the results of Table 1, it is found that the hot carrier reliability can largely be improved when the acceleration voltage is lowered to shallow the n⁺ junction depth during the n⁺ implantation.

### [Table 1]

TABLE 1

| | Acceleration | Drain current degradation |
|---|---|---|
| | voltage during n⁺ | ratio (after stress is |
| | implantation (KeV) | applied for 1000 seconds) |
| Sample A | 15 | 0.027 |
| Sample B | 25 | 0.042 |
| Sample C | 35 | 0.052 |

The influence of the channel implantation on the hot carrier stress degradation in the LDD structure will be described below. Table 2 shows the influence of the channel implantation on the drain current degradation ratio after the hot carrier stress (stress condition: Vd=5.5 V and Vg=2.1 V) is applied for 1000 seconds for the device having the LDD structure (channel length 0.5 μm, channel width 5.0 μm, and LDD length 0.2 μm) of FIG. 16. At this point, the acceleration voltage is set at 15 KeV during the n⁺ implantation. From the results of Table 2, it is found that the hot carrier reliability can largely be improved when the PTS implantation is used as the channel implantation.

### [Table 2]

TABLE 2

| | Drain current degradation |
|---|---|
| | ratio (after stress is |
| | applied for 1000 seconds) |
| Only Vth implantation | 0.042 |
| Only PTS implantation | 0.027 |
| Vth implantation + PTS | 0.035 |
| implantation | |

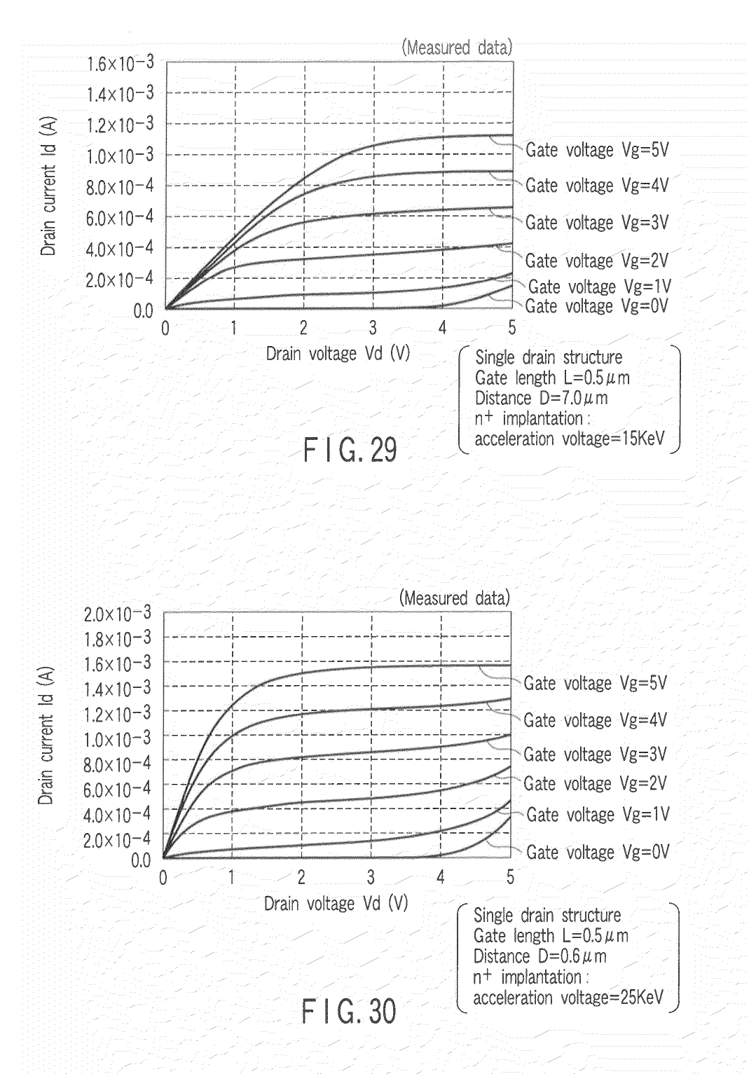

The influence of the LDD implantation on the hot carrier stress degradation in the LDD structure will be described below. Table 3 shows the influence of LDD implantation on the drain current degradation ratio after the hot carrier stress (stress condition: Vd=6 V and Vg=2.1 V) is applied for 1000 seconds for the device having the LDD structure (channel length 0.5 μm, channel width 5.0 μm, LDD length 0.2 μm, and LDD concentration=2×10¹³/cm²) of FIG. 29. At this point, the acceleration voltage is set at 15 KeV during the n⁺ implantation, and the PTS implantation is used as channel implantation. From the results of Table 3, it is found that the hot carrier reliability can largely be improved when the acceleration voltage is lowered during the LDD implantation.

### [Table 3]

TABLE 3

| Acceleration | Drain current degradation |
|---|---|
| voltage during LDD | ratio (after stress is |
| implantation (KeV) | applied for 1000 seconds) |
| 35 | 0.050 |
| 25 | 0.042 |
| 15 | 0.030 |
| 12.5 | 0.025 |
| 10 | 0.020 |

The above results are summarized as follows: as a result of the investigation on the dependence of the hot carrier stress degradation on the body film thickness Tsi, the hot carrier stress degradation is decreased as the body film thickness Tsi is increased, and it is confirmed that the body film thickness Tsi is effectively set larger from the standpoint of reliability against the hot carrier stress degradation. When the body current Ibody is measured by the four-terminal method, as the body film thickness Tsi is decreased, the body current Ibody is increased although the maximum mobility μmax is slightly decreased. This indicates that holes are frequently generated at the drain connection end by the impact ionization, and this tendency agrees with the tendency of the hot carrier stress degradation. It is also confirmed that the hot carrier stress degradation is decreased as the n⁺ implantation acceleration voltage is lowered to shallow the junction depth.

The invention is applicable to the thin-film transistor incorporated in a liquid crystal display panel, the production of the thin-film transistor, and the display apparatus in which the thin-film transistor is used.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A thin-film transistor comprising:
a semiconductor thin film which is provided on an insulating surface of a support substrate;
a gate insulator which is provided on the semiconductor thin film; and
a gate electrode layer which is formed on the semiconductor thin film with the gate insulator interposed therebetween,
wherein the semiconductor thin film includes:
a channel region which is disposed below the gate electrode layer and contains an impurity of a first conductivity type; and
source and drain regions which are disposed on both sides of the channel region and contain an impurity of a second conductivity type opposite to the first conductivity type,
the source region has an impurity concentration profile in which an impurity concentration is lowered from an interface with the gate insulator toward an interface with the support substrate in a thickness direction of the semiconductor thin film, and
the impurity concentration near the support substrate is lower than the impurity concentration near the gate insulator by a factor of 100 or more in the impurity concentration profile of the source region.

2. The thin-film transistor according to claim 1, wherein the channel region has an impurity concentration profile in which the impurity concentration is increased from the interface with the gate insulator toward the interface with the support substrate in the thickness direction of the semiconductor thin film.

3. The thin-film transistor according to claim 1, which is an n-channel type transistor in which the first conductivity type is set to a p-type while the second conductivity type is set to an n-type.

4. The thin-film transistor according to claim 3, wherein the source region has an impurity dosage of 4×10¹⁵/cm² or more.

5. The thin-film transistor according to claim 1, wherein the drain region has an impurity concentration profile which is substantially identical to the impurity concentration profile of the source region.

6. The thin-film transistor according to claim 1, wherein the gate electrode layer has a gate length of 1 μm or less along a channel between the source region and the drain region.

7. The thin-film transistor according to claim 1, further comprising:
a source electrode which is connected to the source region at a contact portion; and
a drain electrode which is connected to the drain region at a contact portion,
wherein a distance at least from the contact portion of the drain electrode to an end of the drain region adjacent to the channel region is not more than 4 μm.

8. A method of producing a thin-film transistor comprising:
providing a semiconductor thin film on an insulating surface of a support substrate;
providing a gate insulator on the semiconductor thin film;
forming a gate electrode layer on the semiconductor thin film with the gate insulator interposed therebetween;
providing, in the semiconductor thin film, a channel region which is disposed below the gate electrode layer and contains an impurity of a first conductivity type, and source and drain regions which are disposed on both sides of the channel region and contain an impurity of a second conductivity type opposite to the first conductivity type;
wherein the source region has an impurity concentration profile in which an impurity concentration is lowered from an interface with the gate insulator toward an interface with the support substrate in a thickness direction of the semiconductor thin film.

9. A display apparatus comprising:
a liquid crystal display panel; and
a drive circuit including a thin-film transistor disposed on the liquid crystal display panel,
wherein the thin-film transistor includes:
a semiconductor thin film which is provided on an insulating surface of a support substrate;
a gate insulator which is provided on the semiconductor thin film; and
a gate electrode layer which is formed on the semiconductor thin film with the gate insulator interposed therebetween,
the semiconductor thin film includes:
a channel region which is disposed below the gate electrode layer and contains an impurity of a first conductivity type; and
source and drain regions which are disposed on both sides of the channel region and contain an impurity of a second conductivity type opposite to the first conductivity type, and
the source region has an impurity concentration profile in which an impurity concentration is lowered from an interface with the gate insulator toward an interface with the support substrate in a thickness direction of the semiconductor thin film.

10. A thin-film transistor comprising:
a semiconductor thin film which is provided on an insulating surface of a support substrate;
a gate insulator which is provided on the semiconductor thin film; and
a gate electrode layer which is formed on the semiconductor thin film with the gate insulator interposed therebetween,
wherein the semiconductor thin film includes:
a channel region which is disposed below the gate electrode layer and contains an impurity of a first conductivity type;
source and drain regions which are disposed on both sides of the channel region and contain an impurity of a second conductivity type opposite to the first conductivity type; and
an LDD region which is disposed at least between the drain region and the channel region and contains an impurity of the second conductivity type,
the source region has an impurity concentration profile in which an impurity concentration is lowered from an interface with the gate insulator toward an interface with the support substrate in a thickness direction of the semiconductor thin film, and
the impurity concentration near the support substrate is lower than the impurity concentration near the gate insulator by a factor of 100 or more in the impurity concentration profile of the source region.

11. The thin-film transistor according to claim 10, which is an n-channel type transistor in which the first conductivity type is set to a p-type while the second conductivity type is set to an n-type.

12. The thin-film transistor according to claim 10, wherein the channel region has an impurity concentration profile in which the impurity concentration is increased from the interface with the gate insulator toward the interface with the support substrate in the thickness direction of the semiconductor thin film.

13. The thin-film transistor according to claim 10, further comprising:
a source electrode which is connected to the source region at a contact portion; and
a drain electrode which is connected to the drain region at a contact portion,
wherein a distance at least from the contact portion of the drain electrode to an end of the drain region adjacent to the LDD region is not more than 4 μm.

14. A method of producing a thin-film transistor comprising:
providing a semiconductor thin film on an insulating surface of a support substrate;
providing a gate insulator on the semiconductor thin film;
forming a gate electrode layer on the semiconductor thin film with the gate insulator interposed therebetween, and
providing, in the semiconductor thin film, a channel region which is disposed below the gate electrode layer and contains an impurity of a first conductivity type, source and drain regions which are disposed on both sides of the channel region and contain an impurity of a second conductivity type opposite to the first conductivity type, and an LDD region which is disposed at least between the drain region and the channel region and contains an impurity of the second conductivity type;
wherein the source region has an impurity concentration profile in which an impurity concentration is lowered from an interface with the gate insulator toward an interface with the support substrate in a thickness direction of the semiconductor thin film.

15. A display apparatus comprising:
a liquid crystal display panel; and
a drive circuit including a thin-film transistor disposed on the liquid crystal display panel,
wherein the thin-film transistor includes:
a semiconductor thin film which is provided on an insulating surface of a support substrate;
a gate insulator which is provided on the semiconductor thin film; and
a gate electrode layer which is formed on the semiconductor thin film with the gate insulator interposed therebetween,
the semiconductor thin film includes:
a channel region which is disposed below the gate electrode layer and contains an impurity of a first conductivity type;
source and drain regions which are disposed on both sides of the channel region and contain an impurity of a second conductivity type opposite to the first conductivity type; and
an LDD region which is disposed at least between the drain region and the channel region and contains an impurity of the second conductivity type,
the source region has an impurity concentration profile in which an impurity concentration is lowered from an interface with the gate insulator toward an interface with the support substrate in a thickness direction of the semiconductor thin film.

16. A thin-film transistor comprising:
a semiconductor thin film which is provided on an insulating surface of a support substrate;
a gate insulator which is provided on the semiconductor thin film; and
a gate electrode layer which is formed on the semiconductor thin film with the gate insulator interposed therebetween,
wherein the semiconductor thin film includes:
a channel region which is disposed below the gate electrode layer and contains an impurity of a first conductivity type;
source and drain regions which are disposed on both sides of the channel region and contain an impurity of a second conductivity type opposite to the first conductivity type; and
an LDD region which is disposed at least between the drain region and the channel region and contains an impurity of the second conductivity type, and
the LDD region has an impurity concentration profile in which an impurity concentration is lowered from an interface with the gate insulator toward an interface with the support substrate in a thickness direction of the semiconductor thin film.

17. The thin-film transistor according to claim 16, wherein the impurity concentration near the support substrate is lower than the impurity concentration near the gate insulator by a factor of 100 or more in the impurity concentration profile of the LDD region.

18. The thin-film transistor according to claim 16, wherein the channel region has an impurity concentration profile in which the impurity concentration is increased from the interface with the gate insulator toward the interface with the support substrate in the thickness direction of the semiconductor thin film.

19. The thin-film transistor according to claim 16, further comprising:
a source electrode which is connected to the source region at a contact portion; and
a drain electrode which is connected to the drain region at a contact portion,
wherein a distance at least from the contact portion of the drain electrode to an end of the drain region adjacent to the LDD region is not more than 4 μm.

20. The thin-film transistor according to claim 16, which is an n-channel type transistor in which the first conductivity type is set to a p-type while the second conductivity type is set to an n-type.

21. The thin-film transistor according to claim 16, wherein the impurity concentration near the support substrate is lower than the impurity concentration near the gate insulator by a factor of 1000 or more in the impurity concentration profile of the LDD region.

22. A method of producing a thin-film transistor comprising:
providing a semiconductor thin film on an insulating surface of a support substrate;
providing a gate insulator on the semiconductor thin film;
forming a gate electrode layer on the semiconductor thin film with the gate insulator interposed therebetween; and
providing, in the semiconductor thin film, a channel region which is disposed below the gate electrode layer and contains an impurity of a first conductivity type, source and drain regions which are disposed on both sides of the channel region and contain an impurity of a second conductivity type opposite to the first conductivity type, and an LDD region which is disposed at least between the drain region and the channel region and contains an impurity of the second conductivity type;
wherein the LDD region has an impurity concentration profile in which an impurity concentration is lowered from an interface with the gate insulator toward an interface with the support substrate in a thickness direction of the semiconductor thin film.

23. A display apparatus comprising:
a liquid crystal display panel; and
a drive circuit including a thin-film transistor disposed on the liquid crystal display panel,
wherein the thin-film transistor includes:
a semiconductor thin film which is provided on an insulating surface of a support substrate;
a gate insulator which is provided on the semiconductor thin film; and
a gate electrode layer which is formed on the semiconductor thin film with the gate insulator interposed therebetween,
the semiconductor thin film includes:
a channel region which is disposed below the gate electrode layer and contains an impurity of a first conductivity type;
source and drain regions which are disposed on both sides of the channel region and contain an impurity of a second conductivity type opposite to the first conductivity type and
an LDD region which is disposed at least between the drain region and the channel region and contains an impurity of the second conductivity type, and
the LDD region has an impurity concentration profile in which an impurity concentration is lowered from an interface with the gate insulator toward an interface with the support substrate in a thickness direction of the semiconductor thin film.

24. A thin-film transistor comprising:
a semiconductor thin film which is provided on an insulating surface of a support substrate;
a gate insulator which is provided on the semiconductor thin film; and
a gate electrode layer which is formed on the semiconductor thin film with the gate insulator interposed therebetween,
wherein the semiconductor thin film includes:
a channel region which is disposed below the gate electrode layer and contains an impurity of a first conductivity type;
source and drain regions which are disposed on both sides of the channel region and contain an impurity of a second conductivity type opposite to the first conductivity type; and
an LDD region which is disposed at least between the drain region and the channel region and contains an impurity of the second conductivity type,
the channel region has an impurity concentration profile in which an impurity concentration is increased from an interface with the gate insulator toward an interface with the support substrate in a thickness direction of the semiconductor thin film, and
the source region and the LDD region have impurity concentration profiles in which impurity concentrations are lowered from the interface with the gate insulator toward the interface with the support substrate in the thickness direction of the semiconductor thin film.

25. The thin-film transistor according to claim 24, wherein the impurity concentration near the support substrate is lower than the impurity concentration near the gate insulator by a factor of 100 or more in the impurity concentration profile of the source region.

26. The thin-film transistor according to claim 25, wherein the impurity concentration near the support substrate is lower than the impurity concentration near the gate insulator by a factor of 100 or more in the impurity concentration profile of the LDD region.

27. The thin-film transistor according to claim 25, wherein the impurity concentration near the support substrate is lower than the impurity concentration near the gate insulator by a factor of 1000 or more in the impurity concentration profile of the LDD region.

28. The thin-film transistor according to claim 24, wherein the drain region has an impurity concentration profile which is substantially identical to the impurity concentration profile of the source region.

29. The thin-film transistor according to claim 24, wherein the impurity concentration near the support substrate is lower than the impurity concentration near the gate insulator by a factor of 100 or more in the impurity concentration profile of the LDD region.

30. The thin-film transistor according to claim 24, wherein the impurity concentration near the support substrate is lower than the impurity concentration near the gate insulator by a factor of 1000 or more in the impurity concentration profile of the LDD region.

31. The thin-film transistor according to claim 25, wherein an impurity dosage of the LDD region ranges from 6×10¹²/cm² to 1×10¹⁴/cm² when impurity ion implantation is performed with an acceleration voltage such that the impurity concentration near the support substrate is lower than the impurity concentration near the gate insulator by a factor of 1000 to 10000.

32. The thin-film transistor according to claim 25, wherein an impurity dosage of the LDD region ranges from 1×10¹³/cm² to 1×10¹⁵/cm² when impurity ion implantation is performed with an acceleration voltage such that the impurity concentration near the support substrate is lower than the impurity concentration near the gate insulator by a factor of 10000 to 100000.

33. The thin-film transistor according to claim 32, wherein the gate electrode layer has a gate length of 1 μm or less along a channel between the source region and the drain region.

34. The thin-film transistor according to claim 33, wherein the source region has an impurity dosage of 2×10¹⁵/cm² or less.

35. The thin-film transistor according to claim 24, further comprising:
a source electrode which is connected to the source region at a contact portion; and
a drain electrode which is connected to the drain region at a contact portion,
wherein a distance at least from the contact portion of the drain electrode to an end of the drain region adjacent to the LDD region is not more than 4 μm.

36. A method of producing a thin-film transistor comprising:
providing a semiconductor thin film on an insulating surface of a support substrate;
providing a gate insulator on the semiconductor thin film;
forming a gate electrode layer on the semiconductor thin film with the gate insulator interposed therebetween; and
providing, in the semiconductor thin film, a channel region which is disposed below the gate electrode layer and contains an impurity of a first conductivity type, source and drain regions which are disposed on both sides of the channel region and contain an impurity of a second conductivity type opposite to the first conductivity type, and an LDD region which is disposed at least between the drain region and the channel region and contains an impurity of the second conductivity type;
wherein the channel region has an impurity concentration profile in which an impurity concentration is increased from an interface with the gate insulator toward an interface with the support substrate in a thickness direction of the semiconductor thin film, and
the source region and the LDD region have impurity concentration profiles in which impurity concentrations are lowered from the interface with the gate insulator toward the interface with the support substrate in the thickness direction of the semiconductor thin film.

37. A display apparatus comprising:
a liquid crystal display panel; and
a drive circuit including a thin-film transistor disposed on the liquid crystal display panel,
wherein the thin-film transistor includes:
a semiconductor thin film which is provided on an insulating surface of a support substrate;
a gate insulator which is provided on the semiconductor thin film; and
a gate electrode layer which is formed on the semiconductor thin film with the gate insulator interposed therebetween,
the semiconductor thin film includes:
a channel region which is disposed below the gate electrode layer and contains an impurity of a first conductivity type;
source and drain regions which are disposed on both sides of the channel region and contain an impurity of a second conductivity type opposite to the first conductivity type; and
an LDD region which is disposed at least between the drain region and the channel region and contains an impurity of the second conductivity type,
the channel region has an impurity concentration profile in which an impurity concentration is increased from an interface with the gate insulator toward an interface with the support substrate in a thickness direction of the semiconductor thin film, and
the source region and the LDD region have impurity concentration profiles in which impurity concentrations are lowered from the interface with the gate insulator toward the interface with the support substrate in the thickness direction of the semiconductor thin film.
